(19) United States
(12) Patent Application Publication
(10) Pub. No.: US 2026/0311745 A1
(43) Pub. Date: Oct. 8, 2026

(54) SEMICONDUCTOR DEVICE

(71) Applicant: Semiconductor Energy Laboratory Co., Ltd., Atsugi-shi, Kanagawa-ken (JP)

(72) Inventors: Yuki OKAMOTO, Ebina (JP); Yusuke KOUMURA, Atsugi (JP)

(21) Appl. No.: 19/482,334

(22) PCT Filed: Jun. 3, 2024
(86) PCT No.: PCT/IB2024/055383

§ 371 Date: Nov. 7, 2025

(30) Foreign Application Priority Data
Jun. 9, 2023 (JP) 2023-095612

(51) Int. Cl. G11C 11/4091; G11C 11/4096; G11C 11/4097; H10B 12/00; H10D 30/67; H10D 62/83

(52) U.S. Cl. CPC G11C 11/4091; G11C 11/4096; G11C 11/4097; H10B 12/33; H10B 12/482; H10B 12/488; H10B 12/50; H10D 30/6728; H10D 30/6734; H10D 62/83

(57) ABSTRACT

A novel semiconductor device is provided. The memory cell includes a first transistor and a first capacitor. A gate of the first transistor is electrically connected to a word line. One of a source and a drain of the first transistor is electrically connected to one terminal of the first capacitor. The other of the source and the drain of the first transistor is electrically connected to a gate of the second transistor and one of a source and a drain of the third transistor. One of a source and a drain of the second transistor and the other of the source and the drain of the third transistor are electrically connected to the second sensing circuit through a bit line. The second sensing circuit has a function of outputting first data corresponding to a potential of the bit line. The memory circuit has a function of retaining second data corresponding to the number of times the memory cell is accessed. The input/output circuit has a function of, in accordance with the second data, determining whether to invert or not to invert the first data and outputting the first data.

### TECHNICAL FIELD

One embodiment of the present invention relates to a semiconductor device.

Note that one embodiment of the present invention is not limited to the above technical field. The technical field of one embodiment of the invention disclosed in this specification and the like relates to an object, a method, a driving method, or a manufacturing method. One embodiment of the present invention relates to a process, a machine, manufacture, or a composition of matter. Specific examples of the technical field of one embodiment of the present invention disclosed in this specification and the like include a semiconductor device, a display apparatus, a light-emitting apparatus, a power storage device, an optical device, an imaging device, a lighting device, an arithmetic device, a control device, a memory device, an input device, an output device, an input/output device, a signal processing device, an arithmetic processing device, an electronic computer, an electronic device, driving methods thereof, and manufacturing methods thereof.

### BACKGROUND ART

In recent years, semiconductor devices have been developed and mainly used in LSIs, CPUs, memories, and the like, for example. A CPU is an aggregation of semiconductor elements; the CPU includes a semiconductor integrated circuit formed into a chip by processing a semiconductor wafer, and is provided with an electrode that is a connection terminal.

For example, a semiconductor circuit (IC chip) of an LSI, a CPU, a memory, or the like is mounted on a circuit board (e.g., a printed wiring board) to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display apparatus). A silicon-based semiconductor material is widely known as a material of a semiconductor thin film that can be used for the transistor, and an oxide semiconductor has been attracting attention as another material.

It is known that a transistor using an oxide semiconductor has an extremely low off-state current in a non-conduction state. For example, Patent Document 1 discloses a low-power CPU or the like utilizing a feature of a low off-state current of the transistor using an oxide semiconductor. For another example, Patent Document 2 discloses a memory device that can retain stored contents for a long time by utilizing a feature of a low off-state current of the transistor using an oxide semiconductor, a low-power memory that has a reduced frequency of data refresh by utilizing the memory device, and the like.

In recent years, demand for an integrated circuit with higher density has risen with reductions in size and weight of electronic devices. In addition, the productivity of a semiconductor device including an integrated circuit is desired to be increased. For example, Patent Document 3 and Non-Patent Document 1 disclose a technique for achieving an integrated circuit with higher density by making a plurality of memory cells overlap with each other by stacking a first transistor using an oxide semiconductor film and a second transistor using an oxide semiconductor film.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473

### Non-Patent Document

[Non-Patent Document 1] M. Oota et. al., “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device or the like having a novel structure. Another object of one embodiment of the present invention is to provide a semiconductor device or the like having a novel structure, which functions as a memory device utilizing retention of charge corresponding to data and in which the data reading speed can be increased. Another object of one embodiment of the present invention is to provide a semiconductor device or the like having a novel structure, which functions as a memory device utilizing retention of charge corresponding to data and in which the record density of memory cells retaining charge can be increased. Another object of one embodiment of the present invention is to provide a semiconductor device or the like having a novel structure, which functions as a memory device utilizing retention of charge corresponding to data and has low power consumption. Another object of one embodiment of the present invention is to provide a semiconductor device or the like having a novel structure, which functions as a memory device utilizing retention of charge corresponding to data and can have a smaller size. Another object of one embodiment of the present invention is to provide a semiconductor device or the like having a novel structure, which functions as a memory device utilizing retention of charge corresponding to data and from which highly reliable data is read.

Note that the description of the above objects does not preclude the existence of other objects. One embodiment of the present invention does not necessarily achieve all the above objects. Objects other than the objects listed above are apparent from the description of the specification, the drawings, the claims, and the like and can be derived from the description of the specification, the drawings, the claims, and the like.

### Means for Solving the Problems

(1)

One embodiment of the present invention is a semiconductor device including a memory cell, a first sensing circuit, a second sensing circuit, an input/output circuit, and a memory circuit. The memory cell includes a first transistor and a first capacitor. The first sensing circuit includes a second transistor and a third transistor. A gate of the first transistor is electrically connected to a word line. One of a source and a drain of the first transistor is electrically connected to one terminal of the first capacitor. The other of the source and the drain of the first transistor is electrically connected to a gate of the second transistor and one of a source and a drain of the third transistor. One of a source and a drain of the second transistor and the other of the source and the drain of the third transistor are electrically connected to the second sensing circuit through a bit line. The second sensing circuit has a function of outputting first data corresponding to a potential of the bit line. The memory circuit has a function of retaining second data corresponding to the number of times the memory cell is accessed. The input/output circuit has a function of, in accordance with the second data, determining whether to invert or not to invert the first data and outputting the first data.

(2)

In (1) above, the memory circuit may have a function of inverting the second data every time the memory cell is accessed. The input/output circuit may have a function of outputting an exclusive disjunction of the first data and the second data.

(3)

In (1) or (2) above, the second sensing circuit may include a fourth transistor. The input/output circuit may include a fifth transistor. The memory circuit may include a sixth transistor. Each of the first transistor to the third transistor may include an oxide semiconductor in a channel formation region. Each of the fourth transistor to the sixth transistor may include silicon in a channel formation region.

(4)

In (1) or (2) above, the memory cell may be provided over the first sensing circuit, and the first sensing circuit may be provided over the second sensing circuit.

(5)

One embodiment of the present invention is a semiconductor device including a first memory cell, a second memory cell, a first sensing circuit, a second sensing circuit, a third sensing circuit, a fourth sensing circuit, and an input/output circuit. The first memory cell includes a first transistor and a first capacitor. The second memory cell includes a seventh transistor and a second capacitor. The first sensing circuit includes a second transistor and a third transistor. The third sensing circuit includes an eighth transistor and a ninth transistor. A gate of the first transistor and a gate of the seventh transistor are electrically connected to a word line. One of a source and a drain of the first transistor is electrically connected to one terminal of the first capacitor. The other of the source and the drain of the first transistor is electrically connected to a gate of the second transistor and one of a source and a drain of the third transistor. One of a source and a drain of the second transistor and the other of the source and the drain of the third transistor are electrically connected to the second sensing circuit through a first bit line. One of a source and a drain of the seventh transistor is electrically connected to one terminal of the second capacitor. The other of the source and the drain of the seventh transistor is electrically connected to a gate of the eighth transistor and one of a source and a drain of the ninth transistor. One of a source and a drain of the eighth transistor and the other of the source and the drain of the ninth transistor are electrically connected to the fourth sensing circuit through a second bit line. The second sensing circuit has a function of outputting first data corresponding to a potential of the first bit line. The fourth sensing circuit has a function of outputting second data corresponding to a potential of the second bit line. The input/output circuit has a function of, in accordance with the second data, determining whether to invert or not to invert the first data and outputting the first data.

(6)

In (5) above, the input/output circuit may have a function of outputting an exclusive disjunction of the first data and the second data.

(7)

In (5) or (6) above, the second sensing circuit may include a fourth transistor. The input/output circuit may include a fifth transistor. The fourth sensing circuit may include a tenth transistor. The first transistor to the third transistor and the seventh transistor to the ninth transistor may each include an oxide semiconductor in a channel formation region. Each of the fourth transistor, the fifth transistor, and the tenth transistor may include silicon in a channel formation region.

(8)

In (5) or (6) above, the first memory cell may be provided over the first sensing circuit. The first sensing circuit may be provided over the second sensing circuit. The second memory cell may be provided over the third sensing circuit. The third sensing circuit may be provided over the fourth sensing circuit.

### Effect of the Invention

One embodiment of the present invention can provide a semiconductor device or the like having a novel structure. Another embodiment of the present invention can provide a semiconductor device or the like having a novel structure, which functions as a memory device utilizing retention of charge corresponding to data and in which the data reading speed can be increased. Another embodiment of the present invention can provide a semiconductor device or the like having a novel structure, which functions as a memory device utilizing retention of charge corresponding to data and in which the record density of memory cells retaining charge can be increased. Another embodiment of the present invention can provide a semiconductor device or the like having a novel structure, which functions as a memory device utilizing retention of charge corresponding to data and has low power consumption. Another embodiment of the present invention can provide a semiconductor device or the like having a novel structure, which functions as a memory device utilizing retention of charge corresponding to data and can have a smaller size. Another embodiment of the present invention can provide a semiconductor device or the like having a novel structure, which functions as a memory device utilizing retention of charge corresponding to data and from which highly reliable data is read.

Note that the descriptions of the above effects do not preclude the existence of other effects. One embodiment of the present invention does not necessarily achieve all the above effects. Effects other than the effects listed above are apparent from the description of the specification, the drawings, the claims, and the like and can be derived from the description of the specification, the drawings, the claims, and the like.

### BRIEF DESCRIPTION OF THE DRAWINGS

FIG. 1 is a block diagram illustrating a structure example of a semiconductor device.

FIG. 2 is a circuit diagram illustrating a structure example of a semiconductor device.

FIG. 3 is a timing chart showing an operation example of a semiconductor device.

FIG. 4 is a timing chart showing an operation example of a semiconductor device.

FIG. 5 is a timing chart showing an operation example of a semiconductor device.

FIG. 6 is a circuit diagram illustrating a structure example of a semiconductor device.

FIG. 7 is a block diagram illustrating a structure example of a semiconductor device.

FIG. 8 is a circuit diagram illustrating a structure example of a semiconductor device.

FIG. 9A and FIG. 9B are schematic views each illustrating a structure example of a memory device.

FIG. 10 is a block diagram illustrating a structure example of a memory device.

FIG. 11A and FIG. 11B are circuit diagrams each illustrating a structure example of a memory device.

FIG. 12 is a schematic diagram illustrating a structure example of a memory device.

FIG. 13 is a diagram illustrating a structure example of a semiconductor device.

FIG. 14A to FIG. 14C are diagrams each illustrating a structure example of a semiconductor device.

FIG. 15A to FIG. 15C are diagrams each illustrating a structure example of a semiconductor device.

FIG. 16A and FIG. 16B are diagrams each illustrating a structure example of a semiconductor device.

FIG. 17A and FIG. 17B are top views each illustrating an example of a layout of a semiconductor device.

FIG. 18 is a top view illustrating an example of a layout of a semiconductor device.

FIG. 19 is a block diagram illustrating a CPU.

FIG. 20A and FIG. 20B are each a perspective view of a semiconductor device.

FIG. 21A and FIG. 21B are each a perspective view of a semiconductor device.

FIG. 22A to FIG. 22H are diagrams each illustrating an example of a circuit structure of a memory cell.

FIG. 23A and FIG. 23B are diagrams each illustrating a hierarchy of a variety of memory devices.

FIG. 24A and FIG. 24B are diagrams each illustrating an example of an electronic component.

FIG. 25A and FIG. 25B are diagrams each illustrating an example of an electronic device.

FIG. 25C to FIG. 25E are diagrams each illustrating an example of a large computer.

FIG. 26 is a diagram illustrating an example of a device for space.

FIG. 27 is a diagram illustrating an example of a storage system that can be used in a data center.

### MODE FOR CARRYING OUT THE INVENTION

In this specification and the like, a semiconductor device refers to a device that utilizes semiconductor characteristics, and means a circuit including a semiconductor element (e.g., a transistor or a diode) or a device including the circuit, for example. The semiconductor device also means any device that can function by utilizing semiconductor characteristics. For example, an integrated circuit including a semiconductor element, a chip provided with an integrated circuit, an electronic component including a packaged chip, and an electronic device provided with an electronic component are examples of a semiconductor device. For example, a display apparatus, a light-emitting apparatus, a power storage device, an optical device, an imaging device, a lighting device, an arithmetic device, a control device, a memory device, an input device, an output device, an input/output device, a signal processing device, an electronic computer, an electronic device, and the like themselves might be semiconductor devices, or might include semiconductor devices.

Embodiments are described below with reference to the drawings. Note that the embodiments can be implemented in many different modes. Thus, it will be readily understood by those skilled in the art that the modes and details can be changed in various ways without departing from the spirit and scope thereof. Thus, the present invention should not be interpreted as being limited to the description in the embodiments.

In this specification and the like, one embodiment of the present invention can be constituted by appropriately combining a structure described in an embodiment with any of the structures described in the other embodiments. In addition, in the case where a plurality of structures are described in one embodiment, the structures can be combined with each other as appropriate to constitute one embodiment of the present invention.

As for the drawings illustrating the embodiments, in the structures of the invention, the same reference numerals are used in common for the same portions or portions having similar functions in different drawings, and repeated description thereof is omitted in some cases. Furthermore, for example, the same hatching pattern is used for the portions having similar functions throughout the drawings, and the portions are not especially denoted by reference numerals in some cases. Moreover, some components are omitted in a perspective view or a top view (also referred to as a “plan view”), for example, for easy understanding of the drawings in some cases. For example, some hidden lines might also be omitted in the drawings. For example, a hatching pattern or the like might be omitted in the drawings.

In the drawings, the size, the layer thickness, or the region is exaggerated for clarity in some cases. Thus, the drawings are not limited to the drawings with the shown size, aspect ratio, and the like, for example. Note that the drawings schematically show ideal examples, and embodiments of the present invention are not limited to shapes, values, and the like shown in the drawings, for example. For example, in the actual manufacturing process, a layer, a resist mask, or the like might be unintentionally reduced in size by treatment such as etching, which is not shown in the drawings in some cases for easy understanding. For example, in the actual circuit operation, a fluctuation in voltage, current, or the like might be caused by noise, difference in timing, or the like, which is not shown in some cases for easy understanding.

In this specification, the drawings, and the like, components are classified on the basis of the functions, and shown as elements independent of one another in some cases. However, such components are sometimes hard to classify functionally, and there are a case where one component is associated with a plurality of functions and a case where a plurality of components are associated with one function. Accordingly, the component is not limited to that described in this specification, the drawings, and the like and can be explained with another term as appropriate depending on the situation.

In this specification, the drawings, and the like, when a plurality of components are denoted by the same reference numerals, and in particular need to be distinguished from each other, an identification sign such as “A”, “b”, “_1”, “[n]”, or “[m, n]” is sometimes added to the reference numerals, for example. When matters common to a plurality of components with identification signs are described or they do not need to be distinguished from each other, no identification sign is added in some cases.

Note that in this specification and the like, a “conduction state” or an “on state” of a transistor refers to a state where a source and a drain of the transistor can be regarded as being electrically short-circuited or a state where a current can be made to flow between the source and the drain. For example, the “conduction state” or the “on state” refers to a state where a voltage between a gate and a source is higher than a threshold voltage in an n-channel transistor, a state where a voltage between a gate and a source is lower than a threshold voltage in a p-channel transistor, or the like in some cases. A “non-conduction state”, a “cutoff state”, or an “off state” of a transistor refers to a state where a source and a drain of the transistor can be regarded as being electrically disconnected. For example, the “non-conduction state”, the “cutoff state”, or the “off state” refers to a state where a voltage between a gate and a source is lower than a threshold voltage in an n-channel transistor, a state where a voltage between a gate and a source is higher than a threshold voltage in a p-channel transistor, or the like in some cases.

In this specification and the like, a “gate voltage” refers to a voltage between a gate and a source, a “drain voltage” refers to a voltage between a drain and a source, and a “back gate voltage” refers to a voltage between a back gate and a source in some cases. In addition, a “drain current” refers to a current flowing between a drain and a source in some cases. The terms “high gate voltage,” “high drain voltage,” “high back gate voltage,” and the like of an n-channel transistor can be replaced with the terms “low gate voltage,” “low drain voltage,” “low back gate voltage,” and the like of a p-channel transistor, respectively, as appropriate in some cases. The terms “low gate voltage,” “low drain voltage,” “low back gate voltage,” and the like of an n-channel transistor can be replaced with the terms “high gate voltage,” “high drain voltage,” “high back gate voltage,” and the like of a p-channel transistor, respectively, as appropriate in some cases.

In this specification and the like, “off-state current” of a transistor refers to a drain current of the transistor in the off state unless otherwise specified. Note that in this specification and the like, an off-state current and a current flowing between a gate and a source/drain (also referred to as a gate leakage current) are sometimes referred to as a leakage current.

### EMBODIMENT 1

A semiconductor device of one embodiment of the present invention will be described with reference to drawings. At least part of the semiconductor device of one embodiment of the present invention can be used for a memory device, for example.

### Structure Example 1 of Semiconductor Device

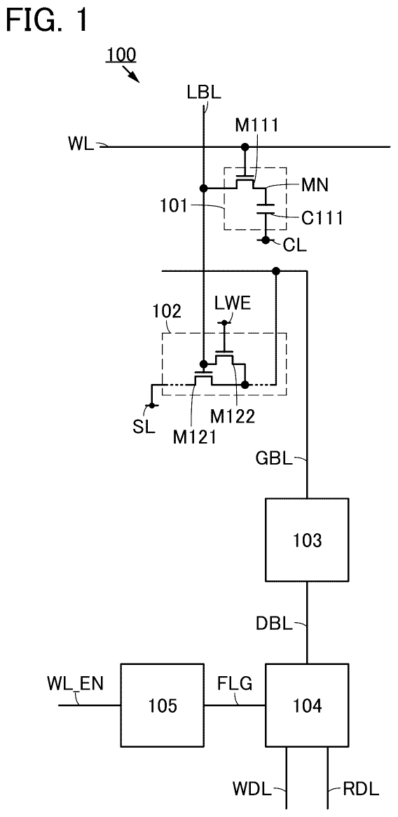

FIG. 1 is a block diagram illustrating a structure example of a semiconductor device 100 of one embodiment of the present invention.

As illustrated in FIG. 1, the semiconductor device 100 includes a memory cell 101, a primary sensing circuit 102, a secondary sensing circuit 103, an input/output circuit 104, and a memory circuit 105.

The memory cell 101 is electrically connected to a wiring WL functioning as a word line. The memory cell 101 is electrically connected to the primary sensing circuit 102 through a wiring LBL functioning as a local bit line. The primary sensing circuit 102 is electrically connected to the secondary sensing circuit 103 through a wiring GBL functioning as a global bit line. The secondary sensing circuit 103 is electrically connected to the input/output circuit 104 through a wiring DBL functioning as a data bit line. The input/output circuit 104 is electrically connected to each of a wiring RDL to which data output to the outside of the semiconductor device 100 is supplied and a wiring WDL to which data input from the outside of the semiconductor device 100 is supplied. The input/output circuit 104 is electrically connected to the memory circuit 105 through a wiring FLG to which flag data is supplied. The memory circuit 105 is electrically connected to a wiring WL_EN to which a signal serving as a trigger for updating the flag data is supplied.

Note that in this specification and the like, the primary sensing circuit 102 is referred to as a first sensing circuit and the secondary sensing circuit 103 is referred to as a second sensing circuit in some cases.

The memory cell 101 includes a transistor M111 and a capacitor C111. One of a source and a drain of the transistor M111 is electrically connected to one terminal of the capacitor C111. The other of the source and the drain of the transistor M111 is electrically connected to the wiring LBL. A gate of the transistor M111 is electrically connected to the wiring WL. The other terminal of the capacitor C111 is electrically connected to a wiring CL. Note that a wiring to which the one of the source and the drain of the transistor M111 and the one terminal of the capacitor C111 are electrically connected to each other is referred to as a wiring MN in the description in some cases.

The memory cell 101 can retain binary data when the level of a potential corresponding to the amount of charge accumulated in the wiring MN is made to correspond to “1” or “0”. Note that ternary or higher-level data may be stored, for example. In the case where data is read from the memory cell 101, the transistor M111 is brought into a conduction state so that charge accumulated in the wiring MN can be extracted to the wiring LBL. In the case where data is written to the memory cell 101, the transistor M111 is brought into a conduction state so that a potential corresponding to the data can be supplied from the wiring LBL to the wiring MN.

Note that when data is read from the memory cell 101, the charge accumulated in the wiring MN is extracted to the wiring LBL, whereby the potential of the wiring MN is changed. That is, destructive reading in which the retained data is destroyed is performed. Thus, data needs to be written again (also referred to as write back) to the memory cell 101 after data reading is performed.

The primary sensing circuit 102 includes a transistor M121 and a transistor M122. A gate of the transistor M121 and one of a source and a drain of the transistor M122 are electrically connected to the wiring LBL. One of a source and a drain of the transistor M121 and the other of the source and the drain of the transistor M122 are electrically connected to the wiring GBL. The other of the source and the drain of the transistor M121 is electrically connected to a wiring SL. A gate of the transistor M122 is electrically connected to a wiring LWE.

The primary sensing circuit 102 has a function of changing the potential of the wiring GLB in accordance with potential of the wiring LBL in the case where data is read from the memory cell 101. For example, the primary sensing circuit 102 has a function of changing the potential of the wiring GLB by supplying current corresponding to the potential of the wiring LBL from the wiring GBL to the wiring SL through the transistor M121. Additionally, the primary sensing circuit 102 has a function of transmitting the potential of the wiring GBL to the wiring LBL in the case where writing of data and writing back of data to the memory cell 101 are performed. For example, the primary sensing circuit has a function of supplying a potential corresponding to the data from the wiring GBL to the wiring LBL through the transistor M122.

The secondary sensing circuit 103 has a function of, in accordance with the potential of the wiring GBL, outputting the potential corresponding to the data to the wiring DBL in the case where data is read from the memory cell 101. The secondary sensing circuit 103 has a function of supplying the potential corresponding to the data to the wiring GBL in the case where data is written and written back to the memory cell 101.

The input/output circuit 104 has a function of, after data is read from the memory cell 101, outputting read data supplied from the secondary sensing circuit 103 through the wiring DBL to the outside of the semiconductor device 100 through the wiring RDL. In that case, the input/output circuit 104 has a function of, in accordance with flag data supplied from the memory circuit 105 through the wiring FLG, determining whether to invert or not to invert the read data. The input/output circuit 104 has a function of, before data is written to the memory cell 101, supplying write data input from the outside of the semiconductor device 100 through the wiring WDL to the secondary sensing circuit 103 through the wiring DBL. In that case, the input/output circuit 104 has a function of, in accordance with the flag data supplied from the memory circuit 105 through the wiring FLG, determining whether to invert or not to invert the write data.

The memory circuit 105 has a function of retaining flag data and outputting the flag data to the wiring FLG. In addition, the memory circuit 105 has a function of updating the flag data using a signal supplied to the wiring WL_EN as a trigger. Here, a signal which is synchronized with the signal supplied to the wiring WL is supplied to the wiring WL_EN. Accordingly, the memory circuit 105 has a function of retaining flag data corresponding to the number of times the memory cell 101 is accessed (that is, the number of times data reading or data writing is performed) and outputting the flag data to the wiring FLG.

Here, in the semiconductor device 100, with a structure in which the primary sensing circuit 102 is included as described above, data reading speed can be increased even when the capacitance of the capacitor C111 included in the memory cell 101 is small. Accordingly, the layout area of the memory cell 101 (also referred to as the occupation area in some cases) can be reduced. Therefore, in the case of including a plurality of memory cells 101, the surface density (also referred to as the record density) can be increased.

In one embodiment of the present invention, an n-channel transistor can be used as each of the transistor M111, the transistor M121, and the transistor M122 in the semiconductor device 100. An n-channel transistor has a higher on-state current than a p-channel transistor. Thus, in the memory cell 101 and the primary sensing circuit 102, the data reading speed, the data writing back speed, and the data writing speed can be increased. Note that a p-channel transistor may be used for at least part of the transistor M111, the transistor M121, and the transistor M122.

Here, in the primary sensing circuit 102, in order to increase the data reading speed, it is preferable that an n-channel transistor be used as the transistor M121 and an operation be performed so that current flows from the wiring GBL to the wiring SL.

In that case, at the time of reading data, the higher the potential of the wiring LBL is, the larger the current flowing from the wiring GBL to the wiring SL becomes, whereby the potential of the wiring GBL becomes low. Alternatively, the lower the potential of the wiring LBL is, the smaller the current flowing from the wiring GBL to the wiring SL becomes, whereby the potential of the wiring GBL becomes high. That is, in the case where data “1” is read from the memory cell 101, data “0” of the secondary sensing circuit 103 is output, and then data “0” is written back to the memory cell 101. In the case where data “0” is read from the memory cell 101, data “1” of the secondary sensing circuit 103 is output, and then data “1” is written back to the memory cell 101. That is, when data reading and data writing are performed, data retained in the memory cell 101 is inverted.

Accordingly, every time data reading and data writing are performed, data retained in the memory cell 101 is alternately inverted and not inverted from the original data in the semiconductor device 100 and a state of not being inverted from the original data stored. That is, for example, in the case where the number of times data reading and data writing are performed is an odd number, data in a state of being inverted from the original data in the secondary sensing circuit 103 is output, and in the case of being an even number, data in a state of not being inverted from the original data in the secondary sensing circuit 103 is output.

In that case, in the case where the data in a state of being inverted from the original data in the secondary sensing circuit 103 is output, the data may be inverted in the input/output circuit 104 and output to the outside of the semiconductor device 100. In the case where data in a state of not being inverted from the original data in the secondary sensing circuit 103 is output, the data may be output to the outside of the semiconductor device 100 without being inverted in the input/output circuit 104.

In view of the above, in the memory circuit 105, flag data indicating whether the number of times of reading data and writing back data are performed (that is, the number of times the memory cell 101 is accessed) is an odd number or an even number is retained, and in the input/output circuit 104, whether to invert or not to invert read data supplied from the secondary sensing circuit 103 is determined in accordance with the flag data and output to the outside of the semiconductor device 100. That is, for example, in the memory circuit 105, every time reading of data and writing back of data are performed (that is, every time the memory cell 101 is accessed), flag data may be inverted, and in the input/output circuit 104, an exclusive disjunction of the read data and the flag data may be subjected to an arithmetic operation and output to the semiconductor device 100.

With such a structure, regardless of whether data retained in the memory cell 101 is inverted from the original data or not, the same logic data as the original data can be output to the outside of the semiconductor device 100. That is, the semiconductor device 100 can operate properly.

Here, in the semiconductor device of one embodiment of the present invention, for example, data output from the secondary sensing circuit 103 during data reading is not necessarily inverted when being written back. Thus, for example, a circuit for inversion at the time of writing back is not necessarily provided between the primary sensing circuit 102 and the secondary sensing circuit 103. Accordingly, for example, delay time due to the circuit does not occur, whereby the data reading speed, the data writing back speed, and the data writing speed can be increased. For example, the increase of the layout area due to the circuit does not occur, whereby the record density of the memory device including the semiconductor device can be increased.

As a transistor included in each of the memory cell 101, the primary sensing circuit 102, the secondary sensing circuit 103, the input/output circuit 104, and the memory circuit 105 included in the semiconductor device 100, for example, a transistor including a single crystal semiconductor, a polycrystalline semiconductor, a microcrystalline semiconductor, or an amorphous semiconductor in a channel formation region can be employed. Furthermore, as the semiconductor, for example, a compound semiconductor (e.g., silicon germanium or gallium arsenide), an oxide semiconductor, or the like as well as a single element semiconductor whose main component is a single element (e.g., silicon or germanium) can be used.

Various kinds of transistors can be used as the transistors. For example, a MOS field-effect transistor, a junction field-effect transistor, a bipolar transistor, or the like can be used.

A transistor with any of a variety of structures can be used as each of the transistors. For example, transistors with various structures such as a top-gate type (e.g., a planar type and a staggered type), a bottom-gate type (e.g., an inverted planar type and an inverted staggered type), a dual-gate type (a structure in which gates are provided on both sides of (e.g., above and below) a channel formation region), a FIN-type, and a TRI-GATE type structures can be used. For example, a vertical transistor (a transistor whose channel length direction is in the vertical direction (also referred to as a height direction or a direction perpendicular to a formation surface)) can be used.

Note that in the transistor included in each of the memory cell 101, the primary sensing circuit 102, the secondary sensing circuit 103, the input/output circuit 104, and the memory circuit 105, semiconductors including the channel formation regions of the transistors may include the same material or different materials. The transistors may have the same structure or different structures.

In one embodiment of the present invention, as a transistor included in each of the secondary sensing circuit 103, the input/output circuit 104, and the memory circuit 105, a Si transistor (a transistor including silicon in a channel formation region) can be employed. Thus, a CMOS circuit (e.g., a circuit that operates complementarily, a CMOS logic gate, a CMOS logic circuit, or the like) formed by electrically connecting a gate of an n-channel Si transistor and a gate of a p-channel Si transistor can be used for each of the secondary sensing circuit 103, the input/output circuit 104, and the memory circuit 105, for example.

In one embodiment of the present invention, as a transistor included in each of the memory cell 101 and the primary sensing circuit 102, an OS transistor (a transistor including an oxide semiconductor in a channel formation region) can be employed.

An OS transistor features an extremely low off-state current because the band gap of the oxide semiconductor where the channel is formed is greater than or equal to 2 eV. The off-state current value per micrometer of channel width of an OS transistor in a room-temperature environment can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor in a room-temperature environment is higher than or equal to 1 fA (1×10⁻¹⁵ A) and lower than or equal to 1 pA (1×10⁻¹² A). Thus, the off-state current of an OS transistor is lower than that of a Si transistor by approximately ten orders of magnitude. Thus, for example, in the case where a wiring electrically connected to one of a source and a drain of the OS transistor is floating, charge accumulated in the wiring can be retained for a long period. When a memory cell is formed using an OS transistor, data written to the memory cell can be retained for a long period, for example.

The off-state current of an OS transistor hardly increases even in a high-temperature environment. Specifically, the off-state current hardly increases even at an environment temperature higher than or equal to room temperature and lower than or equal to 200° C. Furthermore, the on-state current of an OS transistor is unlikely to decrease even in a high-temperature environment. Meanwhile, the on-state current of a Si transistor decreases in a high-temperature environment. That is, an OS transistor has a higher on-state current than a Si transistor in a high-temperature environment. In an OS transistor, the ratio between on-state current and off-state current is large even at an environmental temperature higher than or equal to 125° C. and lower than or equal to 150° C.; thus, an excellent switching operation can be performed. Accordingly, a semiconductor device including an OS transistor achieves a stable operation and high reliability even in a high-temperature environment.

Moreover, the OS transistor has high source-drain breakdown voltage (also referred to as drain breakdown voltage). Accordingly, a semiconductor device including an OS transistor achieves a stable operation and high reliability even when being driven with high voltage.

Here, a structure in which an OS transistor is used as the transistor M111 in the memory cell 101 is referred to as a DOSRAM (registered trademark) in some cases. The DOSRAM is an abbreviation for a Dynamic Oxide Semiconductor RAM (Random Access Memory). Since an OS transistor having an extremely low off-state current is used in the DOSRAM, data can be stored for a long time. That is, data once written can be stored for a long period, and thus the frequency of data refresh can be decreased. In addition, the electrostatic capacitance of the cell capacitor (the C111) can be reduced, so that the cell size can be reduced. Thus, the use of the DOSRAM can reduce power consumption of a semiconductor device and a memory device including the DOSRAM and increase the recording density thereof.

Note that data writing to the memory cell using the OS transistor and data reading therefrom are performed by charging or discharging of charge; thus, a substantially unlimited number of times of data writing or data reading are possible. Unlike a magnetic memory, a resistive random access memory, or the like, the memory cell using the OS transistor has no structure change at the atomic level and thus exhibits high rewrite endurance. Furthermore, unlike in a flash memory, unstableness due to an increase in electron trap centers is not observed in the memory cell using the OS transistor even when writing is repeated; thus, the memory cell using the OS transistor is excellent in stability.

The memory cell using the OS transistor can be freely placed over a silicon substrate or the like where a Si transistor is provided, for example; thus, integration can be easily achieved. Furthermore, the OS transistor used in the memory cell can be manufactured with a manufacturing apparatus similar to that for the Si transistor and thus can be manufactured at low cost.

In one embodiment of the present invention, in the semiconductor device 100, a Si transistor can be used for each of the secondary sensing circuit 103, the input/output circuit 104, and the memory circuit 105, and an OS transistor can be used for each of the memory cell 101 and the primary sensing circuit 102. Thus, the primary sensing circuit 102 is provided over the secondary sensing circuit 103 and the memory cell 101 is provided over the primary sensing circuit 102. Accordingly, the record density of the memory device including the semiconductor device 100 can be increased.

In one embodiment of the present invention, a vertical transistor can be used in the memory cell 101 in the semiconductor device 100. This can reduce the layout area of the memory cell 101. In other words, the record density of the memory device including the semiconductor device 100 can be increased.

In one embodiment of the present invention, in the semiconductor device 100, a planar transistor can be used for the primary sensing circuit 102. Thus, the data reading speed in the primary sensing circuit 102 can be increased. Accordingly, the data reading speed of the memory device including the semiconductor device 100 can be increased.

Note that structural examples of transistors that can be used in the semiconductor device 100 will be described later in Embodiment 2.

### SPECIFIC EXAMPLE

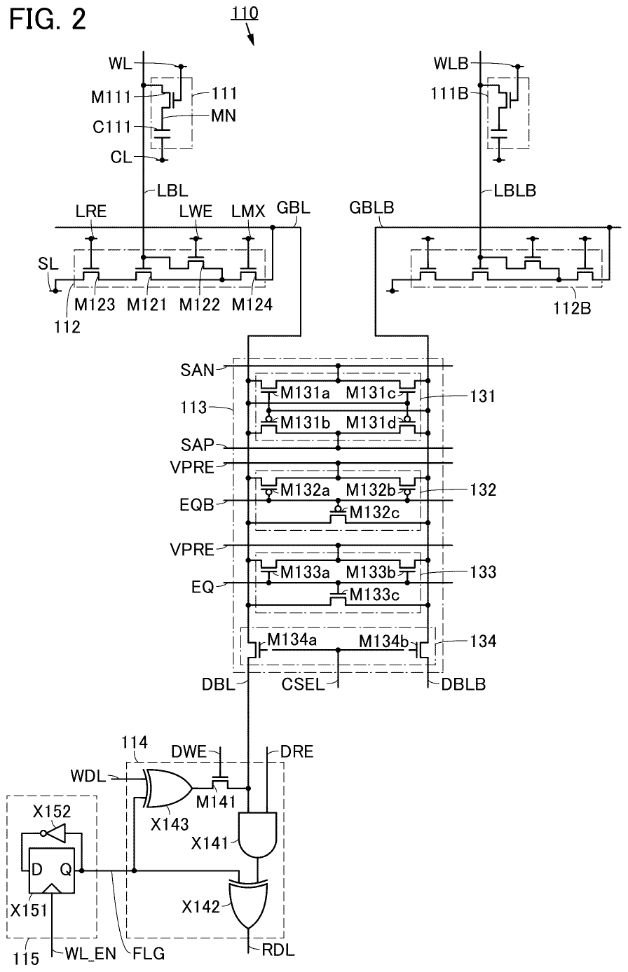

FIG. 2 is a circuit diagram showing a structure example of a semiconductor device 110 of one embodiment of the present invention. The semiconductor device 110 is a specific structure example when the above-described semiconductor device 100 is used for the memory device.

As illustrated in FIG. 2, the semiconductor device 110 includes a memory cell 111, a memory cell 111B, a primary sensing circuit 112, a primary sensing circuit 112B, a secondary sensing circuit 113, an input/output circuit 114, and a memory circuit 115.

Here, the structure of the semiconductor device 110 corresponds to that of the above-described semiconductor device 100. That is, the memory cell 111 corresponds to the memory cell 101, the primary sensing circuit 112 corresponds to the primary sensing circuit 102, the secondary sensing circuit 113 corresponds to the secondary sensing circuit 103, the input/output circuit 114 corresponds to the input/output circuit 104, and the memory circuit 115 corresponds to the memory circuit 105. Therefore, the above description can be referred to as appropriate.

The memory cell 111 includes the transistor M111 and the capacitor C111. One of a source and a drain of the transistor M111 is electrically connected to one terminal of the capacitor C111. The other of the source and the drain of the transistor M111 is electrically connected to the wiring LBL. The gate of the transistor M111 is electrically connected to the wiring WL. The other terminal of the capacitor C111 is electrically connected to the wiring CL. Note that a wiring where the one of the source and the drain of the transistor M111 and the one terminal of the capacitor C111 are electrically connected to each other is referred to as the wiring MN in some cases.

The transistor M111 has a function of a switch. An n-channel transistor can be used as the transistor M111, for example.

The memory cell 111 can retain binary data when the level of the potential corresponding to the amount of charge accumulated in the wiring MN is made to correspond to “1” or “0”. Note that ternary or higher-level data may be stored, for example. In the case where data is read from the memory cell 111, the transistor M111 is brought into a conduction state so that charge accumulated in the wiring MN can be extracted to the wiring LBL. In the case where data is written to the memory cell 111, the transistor M111 is brought into a conduction state so that a potential corresponding to the data can be supplied from the wiring LBL to the wiring MN.

The primary sensing circuit 112 includes the transistor M121, the transistor M122, a transistor M123, and a transistor M124. The gate of the transistor M121 and one of the source and the drain of the transistor M122 are electrically connected to the wiring LBL. One of a source and a drain of the transistor M121 and the other of the source and the drain of the transistor M122 is electrically connected to one of a source and a drain of the transistor M124. The other of the source and the drain of the transistor M124 is electrically connected to the wiring GBL. The other of the source and the drain of the transistor M121 is electrically connected to the one of a source and a drain of the transistor M123. The other of the source and the drain of the transistor M123 is electrically connected to the wiring SL. The gate of the transistor M122 is electrically connected to the wiring LWE. A gate of the transistor M123 is electrically connected to a wiring LRE. A gate of the transistor M124 is electrically connected to a wiring LMX.

The transistor M121 has a function of supplying current between the source and the drain in accordance with the potential of the wiring LBL. Each of the transistor M122, the transistor M123, and the transistor M124 functions as a switch. For each of the transistor M121, the transistor M122, the transistor M123, and the transistor M124, an n-channel transistor can be used.

The primary sensing circuit 112 has a function of changing the potential of the wiring GBL by supplying the current corresponding to the potential of the wiring LBL from the wiring GBL to the wiring SL through the transistor M124, the transistor M121, and the transistor M123. In addition, the primary sensing circuit 112 has a function of transmitting the potential of the wiring GBL to the wiring LBL through the transistor M124 and the transistor M122.

Furthermore, the primary sensing circuit 112 has a function of changing the potential of the gate of the transistor M121 to a potential corresponding to the threshold voltage of the transistor M121 by discharging charge accumulated in the gate of the transistor M121 to the wiring SL through the transistor M122, the transistor M121, and the transistor M123. With this function, the primary sensing circuit 112 can perform correction so as to reduce the influence of the threshold voltage of the transistor M121. By performing such a correction, for example, even in the case where the semiconductor device 110 includes a plurality of the primary sensing circuit 112 and variations of the threshold voltage among the transistors M121 occur, influence to the data reading can be reduced. Thus, the reliability of the semiconductor device 110 can be improved.

The secondary sensing circuit 113 includes an amplifier circuit 131, a precharge circuit 132, a precharge circuit 133, and a switch circuit 134. Each of the amplifier circuit 131, the precharge circuit 132, the precharge circuit 133, and the switch circuit 134 is electrically connected to the wiring GBL and the wiring GBLB. The switch circuit 134 is electrically connected to the wiring DBL and a wiring DBLB.

The secondary sensing circuit 113 has a function of reading data, writing back data, and writing data with respect to the memory cell 111.

The amplifier circuit 131 has a function of outputting a potential corresponding to one of binary data to the wiring GBL and outputting a potential corresponding to the other of the binary data to the wiring GBLB when a predetermined potential is supplied to each of a wiring SAP and a wiring SAN.

Specifically, the amplifier circuit 131 includes a transistor M131a, a transistor M131b, a transistor M131c, and a transistor M131d. One of a source and a drain of the transistor M131a is electrically connected to the wiring GBL. One of a source and a drain of the transistor M131b is electrically connected to the wiring GBL. One of a source and a drain of the transistor M131c is electrically connected to the wiring GBLB. One of a source and a drain of the transistor M131d is electrically connected to the wiring GBLB. The other of the source and the drain of the transistor M131a and the other of the source and the drain of the transistor M131c are electrically connected to the wiring SAN. The other of the source and the drain of the transistor M131b and the other of the source and the drain of the transistor M131d are electrically connected to the wiring SAP. A gate of the transistor M131a and a gate of the transistor M131b are electrically connected to the wiring GBLB. A gate of the transistor M131c and a gate of the transistor M131d are electrically connected to the wiring GBL. The transistor M131a and the transistor M131c are n-channel transistors. The transistor M131b and the transistor M131d are p-channel transistors. That is, it can be said that the amplifier circuit 131 includes an inverter loop formed by an inverter of the transistor M131a and the transistor M131b and an inverter of the transistor M131c and the transistor M131d.

The precharge circuit 132 has a function of precharging the wiring GBL and the wiring GBLB with a potential supplied to a wiring VPRE in accordance with a signal supplied to a wiring EQB.

Specifically, the precharge circuit 132 includes a transistor M132a, a transistor M132b, and a transistor M132c. One of a source and a drain of the transistor M132a is electrically connected to the wiring GBL. One of a source and a drain of the transistor M132b is electrically connected to the wiring GBLB. The other of the source and the drain of the transistor M132a and the other of the source and the drain of the transistor M132b are electrically connected to the wiring VPRE. One of a source and a drain of the transistor M132c is electrically connected to the wiring GBL. The other of the source and the drain of the transistor M132c is electrically connected to the wiring GBLB. A gate of the transistor M132a, a gate of the transistor M132b, and a gate of the transistor M132c are electrically connected to the wiring EQB. The transistor M132a, the transistor M132b, and the transistor M132c are p-channel transistors.

The precharge circuit 133 has a function of precharging the wiring GBL and the wiring GBLB with a potential supplied to the wiring VPRE, in accordance with a signal supplied to a wiring EQ.

Specifically, the precharge circuit 133 includes a transistor M133a, a transistor M133b, and a transistor M133c. One of a source and a drain of transistor M133a is electrically connected to the wiring GBL. One of a source and a drain of the transistor M133b is electrically connected to the wiring GBLB. The other of the source and the drain of the transistor M133a and the other of the source and the drain of the transistor M133b are electrically connected to the wiring VPRE. One of a source and a drain of the transistor M133c is electrically connected to the wiring GBL. The other of the source and the drain of the transistor M133c is electrically connected to the wiring GBLB. A gate of the transistor M133a, a gate of the transistor M133b, and a gate of the transistor M133c are electrically connected to the wiring EQ. The transistor M133a, the transistor M133b, and the transistor M133c are n-channel transistors.

The switch circuit 134 has a function of establishing or interrupting electrical continuity between the wiring pair of the wiring GBL and the wiring GBLB and the wiring pair of the wiring DBL and the wiring DBLB in accordance with a signal supplied to a wiring CSEL.

Specifically, the switch circuit 134 includes a transistor M134a and a transistor M134b. One of a source and a drain of the transistor M134a is electrically connected to the wiring GBL. The other of the source and the drain of the transistor M134a is electrically connected to the wiring DBL. One of a source and a drain of the transistor M134b is electrically connected to the wiring GBLB. The other of the source and the drain of the transistor M134b is electrically connected to the wiring DBLB. A gate of the transistor M134a and a gate of the transistor M134b are electrically connected to the wiring CSEL. The transistor M134a and the transistor M134b are n-channel transistors.

The memory cell 111B and the primary sensing circuit 112B have structures similar to those of the memory cell 111 and the primary sensing circuit 112, respectively. Thus, for the description of the memory cell 111B and the primary sensing circuit 112B, the description of the memory cell 111 and the primary sensing circuit 112 can be referred to as appropriate by replacing the wiring GBL, the wiring LBL, and the wiring WL with the wiring GBLB, the wiring LBLB, and the wiring WLB, respectively. Accordingly, the secondary sensing circuit 113 has a function of reading data, writing back data, and writing data to the memory cell 111B.

Here, in the semiconductor device 110, for example, in the case of performing data reading or data writing on the memory cell 111 among the two memory cells (the memory cell 111 and the memory cell 111B), a signal that brings the transistor M111 included in the memory cell 111 into a conduction state may be supplied to the wiring WL, and a signal that brings the transistor M111 included in the memory cell 111B into a non-conduction state may be supplied to the wiring WLB.

The input/output circuit 114 includes a transistor M141, a logical product (AND) circuit X141, an exclusive disjunction (XOR) circuit X142, and an XOR circuit X143. One input terminal of the AND circuit X141 is electrically connected to the wiring DBL. The other input terminal of the AND circuit X141 is electrically connected to a wiring DRE. An output terminal of the AND circuit X141 is electrically connected to one input terminal of the XOR circuit X142. An output terminal of the XOR circuit X142 is electrically connected to a wiring RDL. The other input terminal of the XOR circuit X142 is electrically connected to a wiring FLG. One of a source and a drain of the transistor M141 is electrically connected to the wiring DBL. A gate of the transistor M141 is electrically connected to a wiring DWE. The other of the source and the drain of the transistor M141 is electrically connected to the output terminal of the XOR circuit X143. One input terminal of the XOR circuit X143 is electrically connected to the wiring WDL. The other input terminal of the XOR circuit X143 is electrically connected to the wiring FLG.

The transistor M141 has a function of a switch. An n-channel transistor can be used as the transistor M141. For each of the AND circuit X141, the XOR circuit X142, and the XOR circuit X143, a logic gate (an AND gate and an XOR gate) prepared in a standard circuit library can be employed.

The memory circuit 115 includes a D flip-flop (D-FF) circuit X151 and a logical NOT (NOT) circuit X152. An input terminal of the D-FF circuit X151 is electrically connected to an output terminal of the NOT circuit X152. An output terminal of the D-FF circuit X151 is electrically connected to an input terminal of the NOT circuit X152 and the wiring FLG.A clock terminal of the D-FF circuit X151 is electrically connected to the wiring WL_EN.

For the D-FF circuit X151, a flip-flop circuit prepared in a standard circuit library can be employed. A positive edge-triggered D flip-flop can be used, for example. For the NOT circuit X152, a logic gate (NOT gate (also referred to as an inverter)) prepared in a standard circuit library can be employed. That is, it can be said that the memory circuit 115 includes a T flip-flop (T-FF) in which data output to the wiring FLG is inverted using a signal input from the wiring WL_EN as a trigger.

Note that a structure of the above-described semiconductor device 110 is an example, and the semiconductor device of one embodiment of the present invention can have a structure in which the structure of the semiconductor device 110 is changed as appropriate.

For example, a p-channel transistor may be used as appropriate as a transistor functioning as a switch (e.g., the transistor M141) among transistors included in the semiconductor device 110.

Furthermore, a data sensing circuit may be provided between the wiring DBL and the wiring DBLB, for example. Accordingly, data input/output speed to/from the outside of the semiconductor device 110 can be increased. A structure example of the data sensing circuit is described below.

Furthermore, for example, the structure is not limited to that of the memory circuit 115; as other structure examples, structures similar to that of the memory cell 111, the primary sensing circuit 112, and the secondary sensing circuit 113 may be employed. Another structure example of the memory circuit 115 is described below.

### OPERATION EXAMPLE

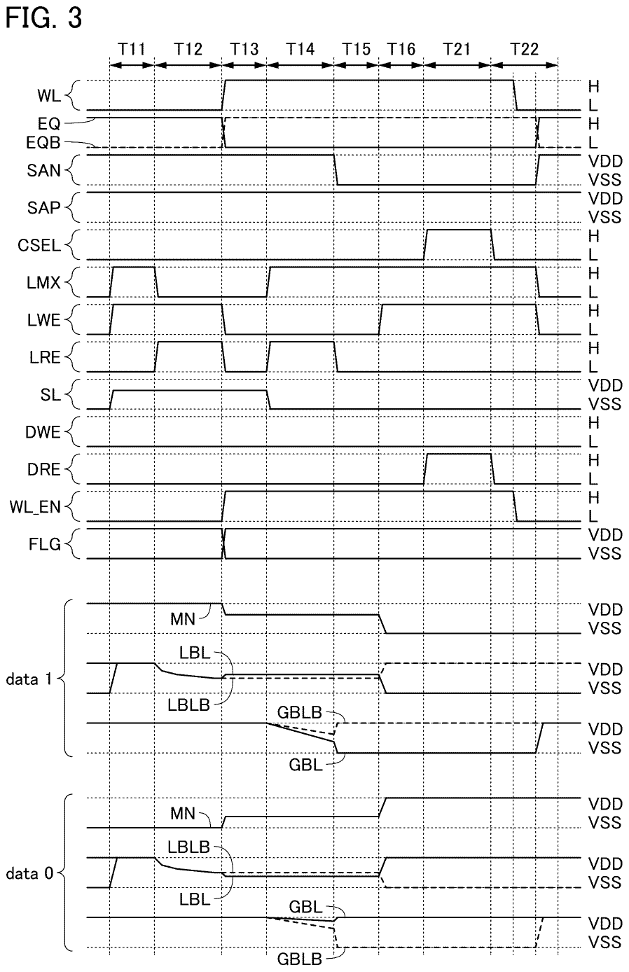

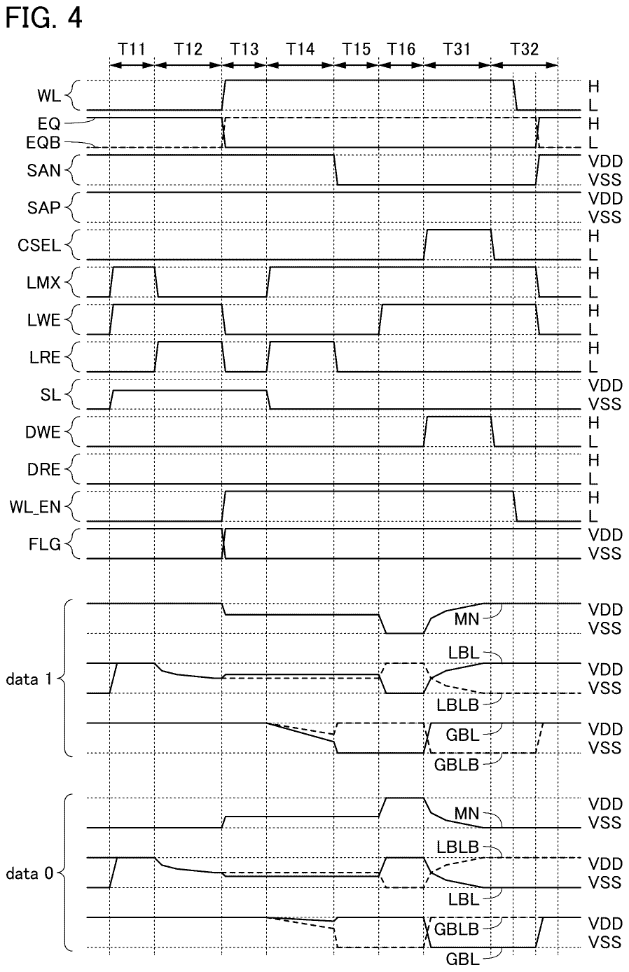

FIG. 3 and FIG. 4 are each a timing chart showing an operation example of the semiconductor device 110 illustrated in FIG. 2. FIG. 3 shows an operation example in the case where data retained in the memory cell 111 is read out to the secondary sensing circuit 113 and the data is output to the outside of the semiconductor device 110. FIG. 4 shows an operation example in the case where data is input from the outside of the semiconductor device 110 and the data is written to the memory cell 111.

Note that in the following description, a potential corresponding to “1” of binary data is a potential VDD that is a high power supply potential, and a potential corresponding to “0” of binary data is a potential VSS that is a low power supply potential. A difference between the potential VDD and the potential VSS is larger than the threshold voltage of a transistor. Note that the potential VSS may be a ground potential, for example. The potential of the signal is the potential H or the potential L. The potential H is a potential which, when supplied to a gate of an n-channel transistor, brings the transistor into a conduction state and, when supplied to a gate of a p-channel transistor, brings the transistor into a non-conduction state. The potential L is a potential which, when supplied to a gate of an n-channel transistor, brings the transistor into a non-conduction state and, when supplied to a gate of a p-channel transistor, brings the transistor into a conduction state. The potential H can be, for example, a potential equal to or higher than the potential VDD. The potential L can be, for example, a potential equal to or lower than the potential VSS.

Note that the potentials H are not necessarily the same among a plurality of signals and the potentials L are not necessarily the same among a plurality of signals. The potentials H may be different and the potentials L may be different among the plurality of signals in accordance with a threshold voltage of a transistor supplied with the signal.

In the description of the operation, loads on a wiring (parasitic capacitance and parasitic resistance), for example, sometimes generate a rise time and a fall time at the time of potential change. Furthermore, for example, two different operations that appear to occur at the same timing do not necessarily occur at exactly the same timing. The operations can be sometimes considered to occur at the same timing even though a signal delay in a wiring or the like causes a slight time lag between the operations, for example.

Although the lengths of periods in a timing chart are sometimes shown to be the same, the lengths of the periods may be different from one another.

The timing chart shown in each of FIG. 3 and FIG. 4 illustrates the states of signals (the potential H or the potential L) supplied to the wiring WL, the wiring LMX, the wiring LWE, the wiring LRE, the wiring EQ, the wiring EQB, the wiring CSEL, the wiring DWE, the wiring DRE, and the wiring WL_EN in operation periods. The potentials supplied to the wiring SL, the wiring SAP, and the wiring SAN are also shown. In addition, a change in the potential of the wiring FLG is illustrated. Changes in the potentials of the wiring MN, the wiring LBL, the wiring LBLB, the wiring GBL, and the wiring GBLB in the case where data “1” is read or written (data 1) and the case where data “0” is read or written (data 0) are also shown.

First, with use of the timing chart shown in FIG. 3, an operation example in the case where data retained in the memory cell 111 is read out to the secondary sensing circuit 113 and the data is output to the outside of the semiconductor device 110 is described.

Period T11 to Period T12 are periods in which the threshold voltage of the transistor M121 is corrected in the primary sensing circuit 112. Period T13 to Period T15 are periods in which data is read out from the memory cell 111 to the secondary sensing circuit 113. Period T16 is a period in which data is written back to the memory cell 111. Period T21 to Period T22 are periods in which data read by the secondary sensing circuit 113 is output to the outside of the semiconductor device 110 through the input/output circuit 114.

Note that in the following description of the operation, the potential VDD is supplied to the wiring VPRE. Any fixed potential (e.g., the potential VSS) is supplied to the wiring CL. The potential L is supplied to the wiring WLB.

Immediately before Period T11, the potential L is supplied to each of the wiring WL, the wiring LMX, the wiring LWE, and the wiring LRE. A predetermined potential (e.g., the potential VSS) is supplied to the wiring SL. The potential H is supplied to the wiring EQ, and the potential L is supplied to the wiring EQB. The potential L is supplied to the wiring CSEL. The potential VDD is supplied to each of the wiring SAP and the wiring SAN. The potential L is supplied to each of the wiring DWE and the wiring DRE. The potential L is supplied to the wiring WL_EN. The potential of the wiring FLG is the potential VDD or the potential VSS. At this time, each of the wiring GBL and the wiring GBLB is precharged with the potential VDD. Each of the wiring LBL and the wiring LBLB is floating and has the potential VDD or the potential VSS. In addition, the wiring MN of the memory cell 111 retains the potential VDD (a potential corresponding to data “1”) or the potential VSS (a potential corresponding to data “0”). Note that in the following description, the immediately preceding state is maintained unless otherwise specified.

In Period T11, the potential H is supplied to the wiring LMX and the wiring LWE. Then, each of the wiring LBL and the wiring LBLB is precharged with the potential VDD. In addition, the potential of the wiring SL becomes a predetermined potential between the potential VDD and the potential VSS. The predetermined potential affects the amount of current flowing through the transistor M121 during the operation in Period T14 described later. Thus, the predetermined potential is determined such that the current amount can become an appropriate value.

In Period T12, the potential L is supplied to the wiring LMX, and the potential H is supplied to the wiring LRE. Then, the potentials of the wiring LBL and the wiring LBLB are decreased to “the potential of the wiring SL+the threshold voltage of the transistor M121” by the discharging to the wiring SL through the transistors M121 included in the primary sensing circuit 112 and the primary sensing circuit 112B.

In Period T13, the potential L is supplied to the wiring LWE and the wiring LRE. Then, each of the wiring LBL and the wiring LBLB becomes floating. Accordingly, potentials corresponding to the threshold voltages of the transistors M121 included in the primary sensing circuit 112 and the primary sensing circuit 112B are retained in the wiring LBL and the wiring LBLB, respectively. Accordingly, correction is performed such that the amount of current flowing through the transistors M121 during the operation in Period T14 described later is not affected by the threshold voltages of the transistors M121. Such correction can reduce the effect on data reading even when the threshold voltages of the transistors M121 vary. Accordingly, the reliability of the semiconductor device 110 can be improved.

In Period T13, the potential L is supplied to the wiring EQ, and the potential H is supplied to the wiring EQB. This stops precharging of the wiring GBL and the wiring GBLB. Thus, each of the wiring GBL and the wiring GBLB becomes floating.

In addition, in Period T13, the potential H is supplied to the wiring WL. Then, charge sharing is performed between the wiring LBL and the wiring MN. Thus, the potential of the wiring LBL changes in accordance with data retained in the memory cell 111 (i.e., in accordance with the potential retained in the wiring MN). Accordingly, the potential of the wiring LBL becomes equal to the potential of the wiring MN.

Specifically, for example, in the case where the data retained in the memory cell 111 is “1” (i.e., the potential VDD is retained in the wiring MN), the potential H is supplied to the wiring WL, so that the potential of the wiring LBL increases and the potential of the wiring MN decreases. Accordingly, the potential of the wiring LBL becomes equal to the potential of the wiring MN. Alternatively, for example, in the case where the data retained in the memory cell 111 is “0” (i.e., the potential VSS is retained in the wiring MN), the potential H is supplied to the wiring WL, so that the potential of the wiring LBL decreases and the potential of the wiring MN increases. Accordingly, the potential of the wiring LBL becomes equal to the potential of the wiring MN.

Meanwhile, in Period T13, the potential L is still supplied to the wiring WLB. That is, charge sharing by the wiring LBLB is not performed. Thus, the potential of the wiring LBL does not change.

Note that the potential of the wiring MN is changed by charge sharing. That is, data retained in the memory cell 111 is destroyed. That is, destructive reading is performed. Thus, data is written back by the operation in Period T16 described later.

In addition, in Period T13, the potential H is supplied to the wiring WL_EN. Then, the flag data retained in the memory circuit 115 is inverted. Thus, the potential of the wiring FLG is changed from the potential VSS to the potential VDD or from the potential VDD to the potential VSS.

In Period T14, the potential H is supplied to the wiring LMX and the wiring LRE. In addition, the same potential as the potential immediately before Period T11 (e.g., the potential VSS) is supplied to the wiring SL. Then, current flows through the transistor M121 included in the primary sensing circuit 112B and the transistor M121 included in the primary sensing circuit 112 in accordance with the potentials of the wiring LBL and the wiring LBLB. Accordingly, the potentials of the wiring GBL and the wiring GBLB gradually decrease. At this time, the difference between the potential of the wiring LBL and the potential of the wiring LBLB causes a difference between the amount of current flowing through the transistor M121 included in the primary sensing circuit 112 and the amount of current flowing through the transistor M121 included in the primary sensing circuit 112B. This difference in the current amount corresponds to the potential of the wiring LBL changed due to charge sharing in the above-described operation in Period T13. That is, the speed at which the potential of the wiring GBL decreases is changed in accordance with the potential of the wiring LBL. Thus, the potential of the wiring LBL can be converted into a potential difference between the wiring GBL and the wiring GBLB.

Specifically, for example, in the case where the data retained in the memory cell 111 is “1”, the amount of current flowing through the transistor M121 included in the primary sensing circuit 112 is larger than the amount of current flowing through the transistor M121 included in the primary sensing circuit 112B. Thus, the speed at which the potential of the wiring GBL decreases is higher than the speed at which the potential of the wiring GBLB decreases. This makes the potential of the wiring GBL lower than the potential of the wiring GBLB. Alternatively, in the case where the data stored in the memory cell 111 is “0”, for example, the amount of current flowing through the transistor M121 included in the primary sensing circuit 112 is smaller than the amount of current flowing through the transistor M121 included in the primary sensing circuit 112B. Thus, the speed at which the potential of the wiring GBL decreases is lower than the speed at which the potential of the wiring GBLB decreases. This makes the potential of the wiring GBL higher than the potential of the wiring GBLB.

In Period T15, the potential L is supplied to the wiring LRE. The potential VSS is also applied to the wiring SAN. Then, by the operation of the amplifier circuit 131, the potential difference between the wiring GBL and the wiring GBLB generated by the above-described operation in Period T14 is amplified. Thus, the potentials of the wiring GBL and the wiring GBLB are each determined to be either the potential VDD or the potential VSS. That is, the data retained in the memory cell 111 is read by the secondary sensing circuit 113.

Specifically, in the case where the data retained in the memory cell 111 is “1”, for example, the potential of the wiring GBL becomes the potential VSS and the potential of the wiring GBLB becomes the potential VDD. That is, data read to the wiring GBL by the secondary sensing circuit 113 becomes “0”. Alternatively, in the case where the data retained in the memory cell 111 is “0”, for example, the potential of the wiring GBL becomes the potential VDD and the potential of the wiring GBLB becomes the wiring VSS. That is, data read to the wiring GBL by the secondary sensing circuit 113 becomes “1”.

In Period T16, the potential H is supplied to the wiring LWE. Then, an operation of writing back data to the memory cell 111 is performed. That is, the potential of the wiring LBL becomes equal to the potential of the wiring GBL determined by the operation in Period T15. Furthermore, the potential is written back to the memory cell 111.

Specifically, in the case where the data retained in the memory cell 111 is “1”, for example, the potential of the wiring GBL determined by the operation in Period T15 is the potential VSS. Accordingly, the potential of the wiring LBL becomes the potential VSS. Furthermore, the potential VSS is written back to the memory cell 111. That is, the data retained in the memory cell 111 is inverted from “1” to “0”. Alternatively, in the case where the data retained in the memory cell 111 is “0”, for example, the potential of the wiring GBL determined by the operation in Period T15 is the potential VDD. Accordingly, the potential of the wiring LBL becomes the potential VDD. Furthermore, the potential VDD is written back to the memory cell 111. That is, the data retained in the memory cell 111 is inverted from “0” to “1”.

In Period T21, the potential His supplied to the wiring CSEL and the wiring DRE. Then, the potential of the wiring GBL determined by the operation in Period T15 is supplied to the wiring DBL. In addition, the potential corresponding to the arithmetic result of an exclusive disjunction of the potential of the wiring DBL (i.e., the data read by the secondary sensing circuit 113) and the potential of the wiring FLG (i.e., the flag data retained in the memory circuit 115) is supplied to the wiring RDL and then output to the outside of the semiconductor device 110.

In Period T22, the potential L is supplied to the wiring CSEL and the wiring DRE. Then, the potential L is supplied to the wiring WL and the wiring WL_EN. After that, the potential L is supplied to the wiring LWE, the wiring LMX, and the wiring EQB, the potential H is supplied to the wiring EQ, and the potential VDD is supplied to the wiring SAN. Accordingly, the operation of reading out the data retained in the memory cell 111 to the secondary sensing circuit 113 and outputting the data to the outside of the semiconductor device 110 is completed.

Here, every time the above operation is repeated in the semiconductor device 110, the data retained in the memory cell 111 is alternately inverted and not inverted from the original data stored in the semiconductor device 110; the data output to the outside of the semiconductor device 110 has the same logic as the original data. The details will be described with reference to a truth table in Table 1.

Next, with use of the timing chart shown in FIG. 4, an operation example in the case where data is input from the outside of the semiconductor device 110 and the data is written to the memory cell 111 is described.

Since the operation example in Period T11 to Period T16 is similar to that described above, description thereof are omitted. Period T31 to Period T32 are periods in which data input from the outside of the semiconductor device 110 is supplied to the secondary sensing circuit 113 through the input/output circuit 114 and the data is written to the memory cell 111.

In Period T31, the potential H is supplied to the wiring CSEL and the wiring DWE. Then, the potential corresponding to the arithmetic result of an exclusive disjunction of the potential of the wiring WDL (i.e., the data input from the outside of the semiconductor device 110) and the potential of the wiring FLG (i.e., the flag data retained in the memory circuit 115) is supplied to the wiring DBL. Furthermore, the potential of the wiring DBL is written to the memory cell 111 through the wiring GBL and the wiring LBL.

In Period T32, the potential L is supplied to the wiring CSEL and the wiring DWE. Next, the potential L is supplied to the wiring WL and the wiring WL_EN. After that, the potential L is supplied to the wiring LWE, the wiring LMX, and the wiring EQB, the potential H is supplied to the wiring EQ, and the potential VDD is supplied to the wiring SAN. Accordingly, the operation of inputting data from the outside of the semiconductor device 110 and writing the data to the memory cell 111 is completed.

Next, in the semiconductor device 110, a change in the state of the semiconductor device 110 (i.e., the potential of each wiring or the like) due to repetition of the operations described above in FIG. 3 and FIG. 4 will be described.

Table 1 is a truth table showing changes in the potentials of the wirings of the semiconductor device 110.

TABLE 1

| | | Data | MN | GBL | DBL | RDL | WDL | FLG |
|---|---|---|---|---|---|---|---|---|
| | Initial | 0 | 0 | — | — | — | — | 0 |
| S11 | T11-16 | 0 | 1 | 1 | — | — | — | 1 |
| | T21-22 | 0 | 1 | 1 | 1 | 0 | — | 1 |
| S12 | T11-16 | 0 | 0 | 0 | — | — | — | 0 |
| | T21-22 | 0 | 0 | 0 | 0 | 0 | — | 0 |
| S13 | T11-16 | 0 | 1 | 1 | — | — | — | 1 |
| | T31-32 | 1 | 0 | 0 | 0 | — | 1 | 1 |
| S14 | T11-16 | 1 | 1 | 1 | — | — | — | 0 |
| | T21-22 | 1 | 1 | 1 | 1 | 1 | — | 0 |
| S15 | T11-16 | 1 | 0 | 0 | — | — | — | 1 |
| | T21-22 | 1 | 0 | 0 | 0 | 1 | — | 1 |
| S16 | T11-16 | 1 | 1 | 1 | — | — | — | 0 |
| | T31-32 | 0 | 0 | 0 | 0 | — | 0 | 0 |
| S17 | T11-16 | 0 | 1 | 1 | — | — | — | 1 |
| | T21-22 | 0 | 1 | 1 | 1 | 0 | — | 1 |

The truth table shown in Table 1 shows the state of the potential of each of the wiring MN, the wiring GBL, the wiring DBL, the wiring RDL, the wiring WDL, and the wiring FLG in the case where the semiconductor device 110 operates from Step S11 to Step S17; the state is shown as “1” (indicating the potential VDD), “0” (indicating the potential VSS), or “-” (indicating the undefined potential).

In Step S11, reading and outputting of data (Period T11 to Period T16 and Period T21 to Period T22 shown in FIG. 3) are performed. In Step S12, reading and outputting of data is performed again. In Step S13, inputting and writing of data (Period T11 to Period T16 and Period T31 to Period T32 shown in FIG. 4) are performed. In Step S14, reading and outputting of data are performed. In Step S15, reading and outputting of data are performed again. In Step S16, inputting and writing of data are performed. In Step S17, reading and outputting of data are performed.

Note that Table 1 shows the states of the potentials after the operation in Period T11 to Period T16 (T11-16), the states of the potentials after the operation in Period T21 to Period T22 (T21-22), and the states of the potentials after the operation in Period T31 to Period T32 (T31-32).

In the initial state (Initial), the original data (Data) stored in the semiconductor device 110 is “0”. At this time, the data retained in the memory cell 111 (i.e., the potential of the wiring MN) is “0” and the flag data retained in the memory circuit 115 (i.e., the potential of the wiring FLG) is “0”.

In Step S11, data is read out from the memory cell 111 and the original data “0” is output to the outside of the semiconductor device 110. First, by the operation in Period T11 to Period T16, the wiring GBL becomes “1” and the wiring MN is inverted from “0” to “1”. That is, the data retained in the memory cell 111 is brought into a state of being inverted from the original data. In addition, the wiring FLG is inverted from “0” to “1”. Next, the wiring DBL becomes “1” by the operation in Period T21 to Period T22. Furthermore, the wiring RDL becomes “0” (i.e., an exclusive disjunction of “1” of the wiring DBL and “1” of the wiring FLG). That is, the wiring RDL has the same logic as the original data “0”.

In Step S12, data is read out from the memory cell 111 and the original data “0” is output to the outside of the semiconductor device 110. First, by the operation in Period T11 to Period T16, the wiring GBL becomes “0” and the wiring MN is inverted from “1” to “0”. That is, the data retained in the memory cell 111 is brought into a state of not being inverted from the original data. In addition, the wiring FLG is inverted from “1” to “0”. Next, the wiring DBL becomes “0” by the operation in Period T21 to Period T22. Furthermore, the wiring RDL becomes “0” (i.e., an exclusive disjunction of “0” of the wiring DBL and “0” of the wiring FLG). That is, the wiring RDL has the same logic as the original data “0”.

In Step S13, data “1” is input from the outside of the semiconductor device 110 and written to the memory cell 111. First, by the operation in Period T 11 to Period T16, the wiring GBL becomes “1” and the wiring MN is inverted from “0” to “1”. In addition, the wiring FLG is inverted from “0” to “1”. Next, by the operation in Period T31 to Period T32, the wiring DBL becomes “0” (i.e., an exclusive disjunction of “1” of the wiring WDL and “1” of the wiring FLG). Furthermore, the wiring GBL and the wiring MN become “0”. At this time, the original data is “1”. That is, the data retained in the memory cell 111 is brought into a state of being inverted from the original data.

In Step S14, data is read out from the memory cell 111 and the original data “1” is output to the outside of the semiconductor device 110. First, by the operation in Period T11 to Period T16, the wiring GBL becomes “1” and the wiring MN is inverted from “0” to “1”. That is, the data retained in the memory cell 111 is brought into a state of not being inverted from the original data. In addition, the wiring FLG is inverted from “1” to “0”. Next, the wiring DBL becomes “1” by the operation in Period T21 to Period T22. Furthermore, the wiring RDL becomes “1” (i.e., an exclusive disjunction of “1” of the wiring DBL and “0” of the wiring FLG). That is, the wiring RDL has the same logic as the original data “1”.

In Step S15, data is read out from the memory cell 111 and the original data “1” is output to the outside of the semiconductor device 110. First, by the operation in Period T11 to Period T16, the wiring GBL becomes “0” and the wiring MN is inverted from “1” to “0”. That is, the data retained in the memory cell 111 is brought into a state of being inverted from the original data. In addition, the wiring FLG is inverted from “0” to “1”. Next, the wiring DBL becomes “0” by the operation in Period T21 to Period T22. Furthermore, the wiring RDL becomes “1” (i.e., an exclusive disjunction of “0” of the wiring DBL and “1” of the wiring FLG). That is, the wiring RDL has the same logic as the original data “1”.

In Step S16, data “0” is input from the outside of the semiconductor device 110 and written to the memory cell 111. First, by the operation in Period T 11 to Period T16, the wiring GBL becomes “1” and the wiring MN is inverted from “0” to “1”. In addition, the wiring FLG is inverted from “1” to “0”. Next, by the operation in Period T31 to Period T32, the wiring DBL becomes “0” (i.e., an exclusive disjunction of “0” of the wiring WDL and “0” of the wiring FLG). Furthermore, the wiring GBL and the wiring MN become “0”. At this time, the original data is “0”. That is, the data retained in the memory cell 111 is brought into a state of not being inverted from the original data.

In Step S17, data is read out from the memory cell 111 and the original data “0” is output to the outside of the semiconductor device 110. First, by the operation in Period T11 to Period T16, the wiring GBL becomes “1” and the wiring MN is inverted from “0” to “1”. That is, the data retained in the memory cell 111 is brought into a state of being inverted from the original data. In addition, the wiring FLG is inverted from “0” to “1”. Next, the wiring DBL becomes “1” by the operation in Period T21 to Period T22. Furthermore, the wiring RDL becomes “0” (i.e., an exclusive disjunction of “1” of the wiring DBL and “1” of the wiring FLG). That is, the wiring RDL has the same logic as the original data “0”.

As described above, in the semiconductor device 110, data having the same logic as the original data can be output to the outside of the semiconductor device 110 regardless of whether or not the data retained in the memory cell 111 is inverted from the original data. That is, the semiconductor device 110 can operate correctly.

One embodiment of the present invention is not limited to the above operation example.

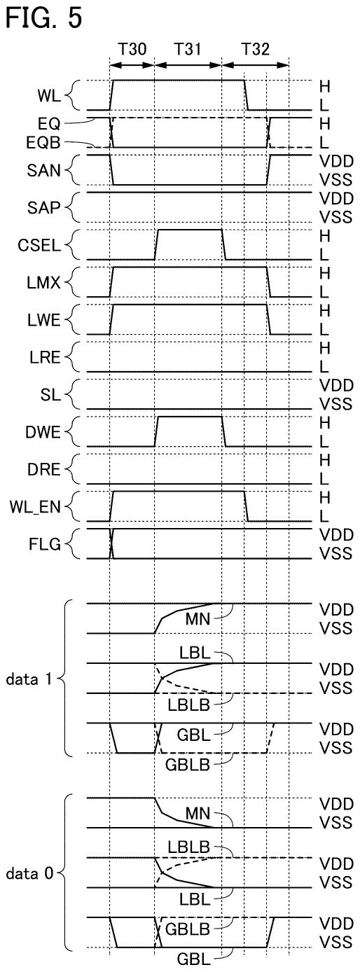

FIG. 5 is a timing chart showing another operation example at the time of inputting and writing data. In the timing chart shown in FIG. 5, the operation in Period T30 is performed instead of the operation in Period T11 to Period T16 in the timing chart shown in FIG. 4.

FIG. 5 shows the case where data “1” is written (data 1) and the case where data “0” is written (data 0). In addition, the case where the data retained in the memory cell 111 is “1” and the case where the data retained in the memory cell 111 is “0” before data writing is performed are also shown.

In Period T30, the potential H is supplied to the wiring WL, the wiring WL_EN, the wiring LWE, the wiring LMX, and the wiring EQB, the potential L is supplied to the wiring EQ, and the potential VSS is supplied to the wiring SAN.

As described above, the semiconductor device 110 of one embodiment of the present invention can operate at a timing changed as appropriate.

### VARIATION EXAMPLE

As described above, one embodiment of the present invention can have a structure in which a data sensing circuit is provided between the wiring DBL and the wiring DBLB in the semiconductor device 110.

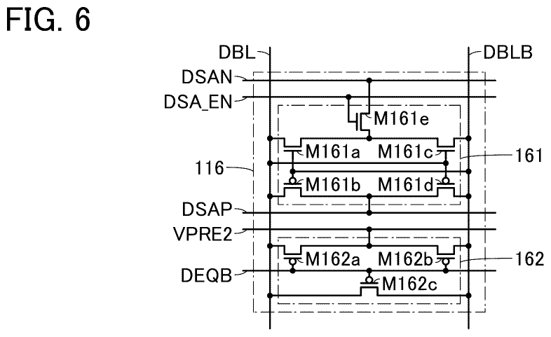

FIG. 6 is a circuit diagram illustrating a structure example of a data sensing circuit 116.

The data sensing circuit 116 includes an amplifier circuit 161 and a precharge circuit 162. Each of the amplifier circuit 161 and the precharge circuit 162 is electrically connected to the wiring DBL and the wiring DBLB.

The amplifier circuit 161 has a function of outputting a potential corresponding to one of binary data to the wiring DBL and outputting a potential corresponding to the other of the binary data to the wiring DBLB when a predetermined potential is supplied to a wiring DSAP and a wiring DSAN.

Specifically, the amplifier circuit 161 includes a transistor M161a, a transistor M161b, a transistor M161c, a transistor M161d, and a transistor M161e. One of a source and a drain of the transistor M161a is electrically connected to the wiring DBL. One of a source and a drain of the transistor M161b is electrically connected to the wiring DBL. One of a source and a drain of the transistor M161c is electrically connected to the wiring DBLB. One of a source and a drain of the transistor M161d is electrically connected to the wiring DBLB. The other of the source and the drain of the transistor M161a and the other of the source and the drain of the transistor M161c are each electrically connected to one of a source and a drain of the transistor M161e. The other of the source and the drain of the transistor M161e is electrically connected to the wiring DSAN. The other of the source and the drain of the transistor M161b and the other of the source and the drain of the transistor M161d are each electrically connected to the wiring DSAP. A gate of the transistor M161a and a gate of the transistor M161b are each electrically connected to the wiring DBLB. A gate of the transistor M161c and a gate of the transistor M161d are each electrically 20 connected to the wiring DBL. A gate of the transistor M161e is electrically connected to a wiring DSA_EN. The transistor M161a, the transistor M161c, and the transistor M161e are n-channel transistors. The transistor M161b and the transistor M161d are p-channel transistors. In other words, it can be said that the amplifier circuit 161 includes an inverter loop formed by an inverter of the transistor M161a and the transistor M161b and an inverter of the transistor M161c and the transistor M161d.

The precharge circuit 162 has a function of precharging the wiring DBL and the wiring DBLB with the potential supplied to a wiring VPRE2, in accordance with a signal supplied to a wiring DEQB.

Specifically, the precharge circuit 162 includes a transistor M162a, a transistor M162b, and a transistor M162c. One of a source and a drain of the transistor M162a is electrically connected to the wiring DBL. One of a source and a drain of the transistor M162b is electrically connected to the wiring DBLB. The other of the source and the drain of the transistor M162a and the other of the source and the drain of the transistor M162b are electrically connected to the wiring VPRE2. One of a source and a drain of the transistor M162c is electrically connected to the wiring DBL. The other of the source and the drain of the transistor M162c is electrically connected to the wiring DBLB. A gate of the transistor M162a, a gate of the transistor M162b, and a gate of the transistor M162c are electrically connected to the wiring DEQB. The transistor M162a, the transistor M162b, and the transistor M162c are p-channel transistors.

### Structure Example 2 of Semiconductor Device

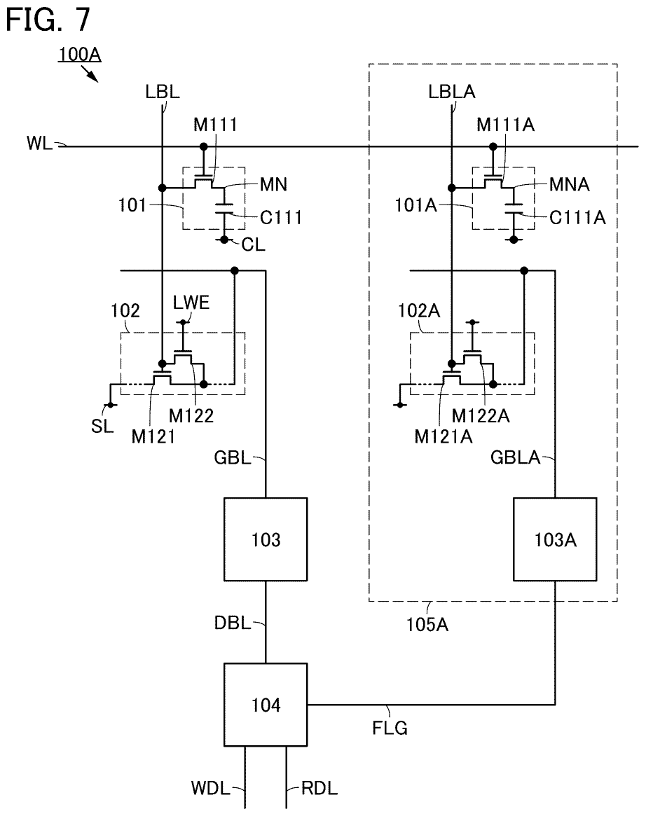

FIG. 7 is a block diagram illustrating a structure example of a semiconductor device 100A of one embodiment of the present invention.

The semiconductor device 100A illustrated in FIG. 7 is a variation example of the above-described semiconductor device 100 and includes a memory circuit 105A instead of the memory circuit 105.

The memory circuit 105A includes a memory cell 101A, a primary sensing circuit 102A, and a secondary sensing circuit 103A. The memory cell 101A, the primary sensing circuit 102A, and the secondary sensing circuit 103A have a structure similar to that of the memory cell 101, the primary sensing circuit 102, and the secondary sensing circuit 103, respectively. That is, a transistor M111A, a transistor M121A, a transistor M122A, a capacitor C111A, a wiring MNA, a wiring LBLA, and a wiring GBLA correspond to the transistor M111, the transistor M121, the transistor M122, the capacitor C111, the wiring MN, the wiring LBL, and the wiring GBL, respectively.

Note that in this specification and the like, the memory cell 101 is referred to as a first memory cell and the memory cell 101A is referred to as a second memory cell in some cases. In some cases, the primary sensing circuit 102A is referred to as a third sensing circuit and the secondary sensing circuit 103A may be referred to as a fourth sensing circuit.

In the memory circuit 105A, the transistor M111A included in the memory cell 101A is electrically connected to the wiring WL. The secondary sensing circuit 103A is electrically connected to the wiring FLG.

In the semiconductor device 100A, at the time of reading and writing back data retained in the memory cell 101, reading and writing of data retained in the memory cell 101A are also performed. That is, when the data retained in the memory cell 101 is inverted by reading and writing back of the data, the data retained in the memory cell 101A is also inverted. Thus, the data retained in the memory cell 101A can be used as the flag data.

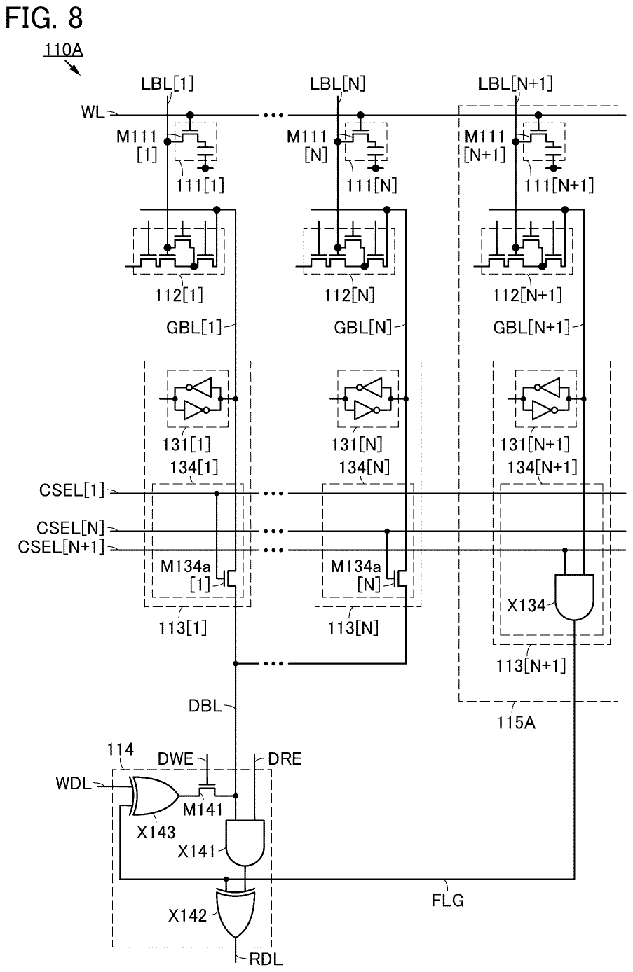

FIG. 8 is a circuit diagram showing a structure example of a semiconductor device 110A of one embodiment of the present invention. The semiconductor device 110A is a specific structure example in the case where the semiconductor device 100A is used for a memory device.

As illustrated in FIG. 8, the semiconductor device 110A includes N (N is an integer greater than or equal to 2) memory cells 111 (a memory cell 111[1] and a memory cell 111[N] are selectively illustrated), N primary sensing circuits 112 (a primary sensing circuit 112[1] and a primary sensing circuit 112[N] are selectively illustrated), N secondary sensing circuits 113 (a secondary sensing circuit 113[1] and a secondary sensing circuit 113[N] are selectively illustrated), the input/output circuit 114, and a memory circuit 115A.

Each of the memory cell 111[1] to the memory cell 111[N] has a structure similar to that of the memory cell 111 included in the above-described semiconductor device 110. Each of the primary sensing circuit 112[1] to the primary sensing circuit 112[N] has a structure similar to that of the primary sensing circuit 112 included in the above-described semiconductor device 110.

Each of the secondary sensing circuit 113[1] to the secondary sensing circuit 113[N] has a structure similar to that of the secondary sensing circuit 113 included in the above-described semiconductor device 110. The input/output circuit 114 has a structure similar to that of the input/output circuit 114 included in the above-described semiconductor device 110. That is, each of the wiring LBL[1] to the wiring LBL[N] corresponds to the wiring LBL, and each of the wiring GBL[1] to the wiring GBL[N] corresponds to the wiring GBL.

Note that FIG. 8 illustrates an amplifier circuit 131[1] and an amplifier circuit 131[N] (corresponding to the amplifier circuit 131 and illustrated here using circuit symbols of inverters), and a switch circuit 134[1] and a switch circuit 134[N] (corresponding to the switch circuit 134), as part of the secondary sensing circuit 113[1] and the secondary sensing circuit 113[N].

In the semiconductor device 110A, a gate of each of a transistor M111[1] to a transistor M111[N] (corresponding to the transistor M111) is electrically connected to the wiring WL. One of a source and a drain of each of a transistor M134a[1] to a transistor M134a[N] (corresponding to the transistor M134a) is electrically connected to each of the wiring GBL[1] to the wiring GBL[N], the other of the source and the drain of each of the transistor M134a[1] to the transistor M134a[N] is electrically connected to the wiring DBL, and a gate of each of the transistor M134a[1] to the transistor M134a[N] is electrically connected to each of a wiring CSEL[1] to a wiring CSEL[N].

The memory circuit 115A includes a memory cell 111[N+1], a primary sensing circuit 112[N+1], and a secondary sensing circuit 113[N+1]. The secondary sensing circuit 113[N+1] includes an amplifier circuit 131[N+1] and a switch circuit 134[N+1]. The switch circuit 134[N+1] includes an AND circuit X134.

The memory cell 111[N+1] has a structure similar to that of the memory cell 111[1] or the like. The primary sensing circuit 112[N+1] has a structure similar to that of the primary sensing circuit 112[1] or the like. The amplifier circuit 131[N+1] has a structure similar to that of the amplifier circuit 131[1] or the like. That is, a wiring LBL[N+1] corresponds to the wiring LBL[1] or the like, and GBL[N+1] corresponds to the wiring GBL[1] or the like.

In the semiconductor device 110A, a gate of a transistor M111[N+1] (corresponding to the transistor M111[1] or the like) is electrically connected to the wiring WL. One input terminal of the AND circuit X134 is electrically connected to the wiring GBL[N+1], the other input terminal of the AND circuit X134 is electrically connected to a wiring CSEL[N+1], and an output terminal of the AND circuit X134 is electrically connected to the wiring FLG. As the AND circuit X134, an AND gate prepared in a standard circuit library can be used.

When the semiconductor device 110A operates as in the timing charts shown in FIG. 3 and FIG. 4, the flag data can be retained in the memory cell 111[N+1] included in the memory circuit 115A.

That is, when the data retained in each of the memory cell 111[1] to the memory cell 111[N] is inverted by reading and writing back data shown in Period T11 to Period T16, the data retained in the memory cell 111[N+1] is also inverted. Thus, the data retained in the memory cell 111[N+1] can be used as the flag data.

After that, at the time of outputting data shown in Period T21 to Period T22, the potential H is supplied to any one of the wiring CSEL[1] to the wiring CSEL[N] and the potential H is supplied to the wiring CSEL[N+1]. Then, the potential of any one of the wiring GBL[1] to the wiring GBL[N] is supplied to the wiring DBL, and the potential of the wiring GBL[N+1] is supplied to the wiring FLG. Furthermore, the potential corresponding to the arithmetic result of an exclusive disjunction of the potential of the wiring DBL (i.e., the read data) and the potential of the wiring FLG (i.e., the flag data) is supplied to the wiring RDL and output to the outside of the semiconductor device 110A.

At the time of inputting and writing data shown in Period T31 to Period T32, the potential H is supplied to any one of the wiring CSEL[1] to the wiring CSEL[N] and the potential H is supplied to the wiring CSEL[N+1]. Then, the potential corresponding to the arithmetic result of an exclusive disjunction of the potential of the wiring WDL (i.e., data input from the outside of the semiconductor device 110A) and the potential supplied from the wiring GBL[N+1] to the wiring FLG (i.e., the flag data) is supplied to the wiring DBL. Furthermore, the potential of the wiring DBL is written to any one of the memory cell 111[1] to the memory cell 111[N+1] through any one of the wiring GBL[1] to the wiring GBL[N].

As described above, in the semiconductor device 110A, data having the same logic as the original data can be output to the outside of the semiconductor device 110A regardless of whether or not the data retained in each of the memory cell 111[1] to the memory cell 111[N] is inverted from the original data. That is, the semiconductor device 100A can operate correctly.

That is, the semiconductor device 110A can be regarded as including N memory cells 111 that retain data and one memory cell 111 that retains flag data.

Note that the structure of the semiconductor device 110A is an example, and the semiconductor device of one embodiment of the present invention can have a structure obtained by changing the structure of the semiconductor device 110A as appropriate.

For example, the switch circuit 134[N+1] may have a structure in which the AND circuit X134 and the wiring CSEL[N+1] are not included and the wiring GBL is directly connected to the wiring FLG.

### Structure Example of Memory Device

A memory device 700 of one embodiment of the present invention will be described. At least part of the semiconductor device 100, the semiconductor device 110, the semiconductor device 100A, the semiconductor device 110A, and the like described above can be used as the memory device 700.

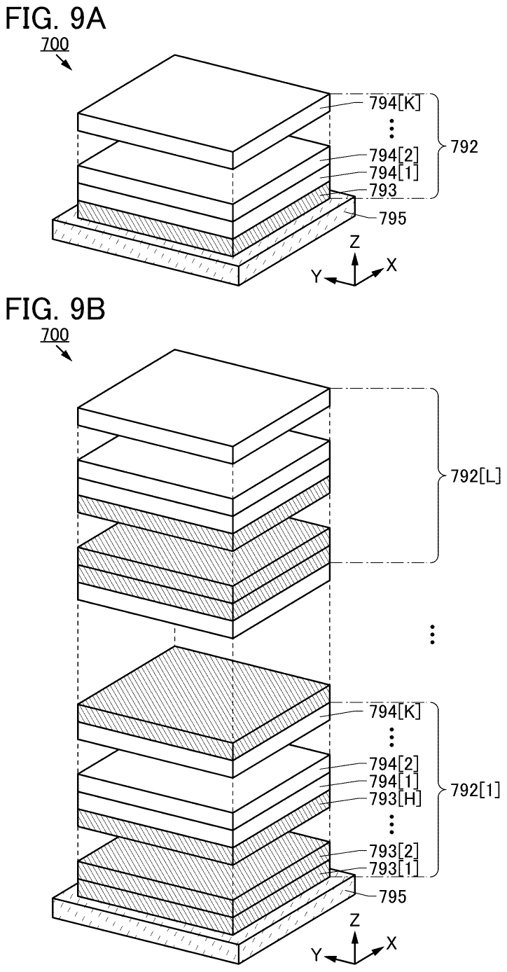

FIG. 9A and FIG. 9B are schematic views each illustrating an example of a layer structure of the memory device 700.

As illustrated in FIG. 9A, the memory device 700 includes a layer 795 and a layer 792. The layer 792 includes a layer 793 and a plurality of layers 794 (a layer 794[1] to 794[K] (K is an integer greater than or equal to 2)). Note that a structure including one layer 794 may be employed.

The layer 793 is stacked over the layer 795. The layer 794[1] to the layer 794[K] are stacked over the layer 793.

Note that in the case where the semiconductor device 100 is used for the memory device 700 as one embodiment of the present invention, for example, a structure can be employed in which the layer 795 is provided with the secondary sensing circuit 103, the input/output circuit 104, and the memory circuit 105, the layer 793 is provided with the primary sensing circuit 102, and the layer 794[1] to the layer 794[K] are provided with memory cells 101. In the case where the semiconductor device 100A is used for the memory device 700 as one embodiment of the present invention, for example, the semiconductor device 100A can have a structure in which the layer 795 is provided with the secondary sensing circuit 103, the input/output circuit 104, and the secondary sensing circuit 103A included in the memory circuit 105A, the layer 793 is provided with the primary sensing circuit 102 and the primary sensing circuit 102A included in the memory circuit 105A, and the layer 794[1] to the layer 794[K] are provided with the memory cells 101 and the memory cells 101A included in the memory circuit 105A.

Note that in the following description, the X direction, the Y direction, and the Z direction are defined for easy understanding of the positional relationship of components. The X direction, the Y direction, and the Z direction are perpendicular to each other. The Z direction refers to a direction in which the layer 793 and the layer 794[1] to the layer 794[K] are stacked over the layer 795. Thus, the X direction and the Y direction are directions along the respective surfaces of the layer 795, the layer 793, and the layer 794[1] to the layer 794[K].

The layer 795 can be provided in an insulating substrate or a semiconductor substrate including a variety of materials.

In one embodiment of the present invention, a structure can be employed in which the layer 795 is provided in a substrate including silicon, for example. That is, a structure can be employed in which a Si transistor (a transistor including silicon in a channel formation region) is provided in the layer 795. Thus, for example, in the layer 795 in one embodiment of the present invention, by electrically connecting a gate of an n-channel Si transistor and a gate of a p-channel Si transistor, a CMOS circuit (e.g., a circuit that operates complementarily, a CMOS logic gate, a CMOS logic circuit, or the like) can be formed.

Each of the layer 793 and the layer 794[1] to the layer 794[K] can include any of a variety of materials such as a conductor, a semiconductor, and an insulator, for example. Each of the layer 793 and the layer 794[1] to the layer 794[K] can be provided with a variety of elements such as a capacitor and a transistor, for example.

Note that a semiconductor layer including a channel formation region of a transistor provided in the layer 793 and semiconductor layers including channel formation regions of transistors provided in the layer 794[1] to the layer 794[K] may include the same material or different materials. The transistor provided in the layer 793 and the transistors provided in the layer 794[1] to the layer 794[K] may have the same structure or different structures.

In one embodiment of the present invention, for example, OS transistors can be provided in the layer 793 and the layer 794[1] to the layer 794[K].

In one embodiment of the present invention, for example, as the structure of the OS transistor, a structure can be employed in which a planar transistor is provided in the layer 793 and vertical transistors are provided in the layer 794[1] to the layer 794[K].

A vertical transistor has a structure that can easily reduce the area to be occupied (the footprint) as compared with a planar transistor. Furthermore, a vertical transistor has a structure in which the channel width is easily increased while the channel length is small; thus, a reduction in on-state resistance (an increase in on-state current) can be easily achieved. Thus, when the memory cell 101 or the like in one embodiment of the present invention is formed using, for example, a vertical transistor, the cell area (cell size) of the memory cell can be reduced.

Since a planar transistor has a structure that can easily increase the channel length as compared with a vertical transistor, the structure can easily reduce a short-channel effect such as drain-induced barrier lowering (DIBL), for example. That is, a transistor with the structure can easily have favorable saturation (the change in drain current with respect to drain voltage is small in a saturation region of the transistor). Thus, in one embodiment of the present invention, when the primary sensing circuit 102 or the like is formed using, for example, a planar transistor, the characteristics of the primary sensing circuit can be improved.

Note that a structure may be employed in which a vertical transistor is provided in the layer 793, for example. As another example, a structure may be employed in which planar transistors are provided in the layer 794[1] to the layer 794[K].

Although not illustrated, the memory device 700 may have a structure in which a wiring layer is provided as appropriate between each of the layer 795, the layer 793, and the layer 794[1] to the layer 794[K]. The wiring layer can be provided with a wiring for electrically connecting various elements, for example.

As illustrated in FIG. 9B, the memory device 700 may have a structure in which a plurality of layers 793 (a layer 793[1] to a layer 793[H] (H is an integer greater than or equal to 2)) are included and the layer 793[1] to the layer 793[H] are stacked. The memory device 700 may have a structure which includes a plurality of layers 792 (a layer 792[1] to a layer 792[L] (L is an integer greater than or equal to 2)) and in which the layer 792[1] to the layer 792[L] are stacked.

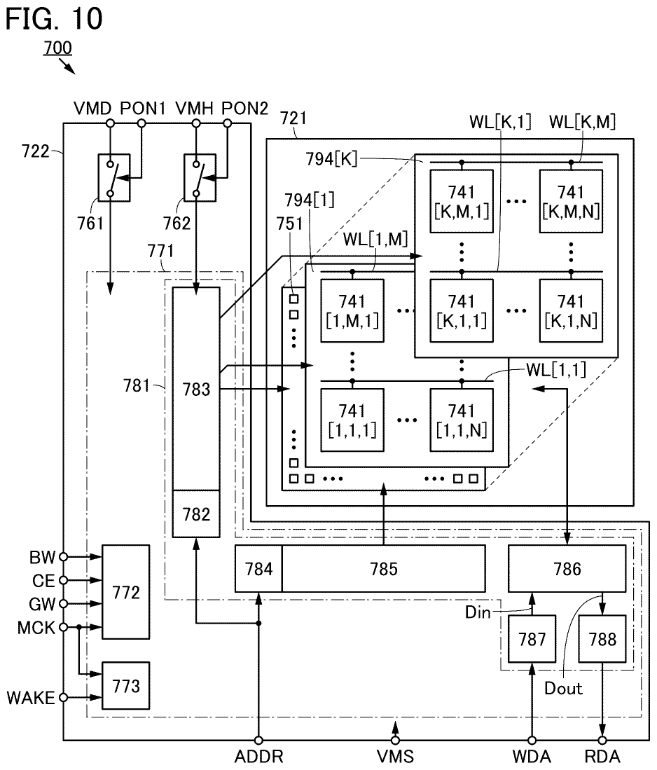

FIG. 10 is a block diagram illustrating a structure example of the memory device 700.

The memory device 700 illustrated in FIG. 10 includes a memory cell array 721 and a driver circuit 722.

The memory array 721 includes a plurality of secondary sensing circuits 751, a plurality of primary sensing circuits 731 (not illustrated), and a plurality of memory cells 741.

In one embodiment of the present invention, the secondary sensing circuits 751 are placed in the layer 795, and the plurality of memory cells 741 are placed in the layer 794[1] to the layer 794[K] as described above.

The plurality of memory cells 741 are placed in a three-dimensional matrix of K layers×M rows×N columns (K, M, and N are each an integer greater than or equal to 1).

Note that FIG. 10 selectively illustrates the memory cell 741[1,1,1] in the first layer, the first row, and the first column, the memory cell 741[1,1,N] in the first layer, the first row, and the N-th column, the memory cell 741[1,M,1] in the first layer, the M-th row, and the first column, the memory cell 741[K,1,1] in the K-th layer, the first row, and the first column, the memory cell 741[K,1,N] in the K-th layer, the first row, and the N-th column, the memory cell 741[K,M,1] in the K-th layer, the M-th row, and the first column, and the memory cell 741[K,M,N] in the K-th layer, the M-th row, and the N-th column.

In addition, FIG. 10 illustrates a wiring WL[1,1] electrically connected to the N memory cells 741 in the first layer and the first row, a wiring WL[1,M] electrically connected to the N memory cells 741 in the first layer and the M-th row, a wiring WL[K,1] electrically connected to the N memory cells 741 in the K-th layer and the first row, and a wiring WL[K,M] electrically connected to the N memory cells 741 in the K-th layer and the M-th row.

The driver circuit 722 includes a power switch 761, a power switch 762, and a peripheral circuit 771. The peripheral circuit 771 includes a peripheral circuit 781, a control circuit 772, and a voltage generation circuit 773.

In one embodiment of the present invention, the driver circuit 722 is placed in the layer 795, for example. Thus, a Si transistor can be used in the driver circuit 722, for example. Note that at least part of the driver circuit 722 can be placed in the layer 793 and the layer 794[1] to the layer 794[K].

Note that for example, in the case where the semiconductor device 100 is used in the memory device 700 as one embodiment of the present invention, the secondary sensing circuit 751 corresponds to the secondary sensing circuit 103, the primary sensing circuit 731 corresponds to the primary sensing circuit 102, and the memory cell 741 corresponds to the memory cell 101. The input/output circuit 104 and the memory circuit 105 may be provided in part of the peripheral circuit 781. In the case where the semiconductor device 100A is used in the memory device 700 as one embodiment of the present invention, for example, the memory circuit 105A may be provided in part of the memory array 721. That is, a structure may be employed in which the plurality of memory cells 741 are arranged in a matrix including N+1 columns in the memory array 721 (i.e., one column is added) so that the memory cells 741 in the N+1-th column retain flag data.

Signals are supplied to a terminal BW, a terminal CE, a terminal GW, a terminal MCK, a terminal WAKE, a terminal ADDR, a terminal WDA, a terminal PON1, and a terminal PON2 from the outside of the memory device 700, for example. Furthermore, for example, a signal is output from a terminal RDA to the outside of the memory device 700.

For example, a clock signal is supplied to the terminal MCK. Control signals are supplied to the terminal BW, the terminal CE, and the terminal GW. A chip enable signal is supplied to the terminal CE. A global write enable signal is supplied to the terminal GW. A byte write enable signal is supplied to the terminal BW. An address signal is supplied to the terminal ADDR. The write data is supplied to the terminal WDA. The read data is supplied to the terminal RDA. Power gating control signals are supplied to the terminal PON1 and the terminal PON2. Note that the signals supplied to the terminal PON1 and the terminal PON2 may be generated in the control circuit 772, for example.

The control circuit 772 has a function of controlling the operation of the memory device 700. The control circuit 772 has a function of performing a logic operation of the signals supplied to the terminal CE, the terminal GW, and the terminal BW to determine an operation mode (e.g., a writing operation or a reading operation) of the memory device 700, for example. The control circuit 772 also has a function of generating a signal for controlling the peripheral circuit 781 so that the operation mode is executed.

The voltage generation circuit 773 has a function of generating a given potential for operating the driver circuit 722. The voltage generation circuit 773 has a function of generating a given potential in response to the input of a clock signal supplied to the terminal MCK in accordance with the signal supplied to the terminal WAKE, for example. To the terminal WAKE, a signal for controlling whether the clock signal supplied to the terminal MCK is input to the voltage generation circuit 773 is supplied, for example.

The peripheral circuit 781 has a function of writing and reading data to and from the memory cells 741. The peripheral circuit 781 has a function of generating a variety of signals for controlling the operation of the memory cell 741, the primary sensing circuit 731, and the secondary sensing circuit 751, for example. The peripheral circuit 781 includes a row decoder 782, a column decoder 784, a row driver 783, a column driver 785, a data driver 786, an input circuit 787, and an output circuit 788.

The row decoder 782 and the column decoder 784 have a function of decoding an address signal supplied to the terminal ADDR. The row decoder 782 has a function of specifying a row to be accessed. In addition, the row decoder 782 has a function of specifying a layer to be accessed. The column decoder 784 has a function of specifying a column to be accessed. The row driver 783 has a function of selecting the row and the layer specified by the row decoder 782 and supplying a desired signal to the corresponding memory cells 741, the secondary sensing circuit 751, and the like, for example. The column driver 785 has a function of selecting the column specified by the column decoder 784 and supplying a desired signal to the corresponding secondary sensing circuit 751 or the like, for example.

The data driver 786 has a function of writing and reading data to and from the memory cells 741 selected by the row driver and the column driver. The input circuit 787 has a function of retaining data supplied to the terminal WDA from the outside of the memory device 700. Data (data Din) retained in the input circuit 787 is written to the memory cells 741 through the data driver 786. Data stored in the memory cells 741 is read out to the output circuit 788 through the data driver 786. The output circuit 788 has a function of retaining the read data (data Dout). In addition, the output circuit 788 has a function of outputting the retained data from the terminal RDA to the outside of the memory device 700.

The power switch 761 has a function of controlling whether a potential supplied to a terminal VMD is supplied to the peripheral circuit 771. The power switch 762 has a function of controlling whether a potential supplied to a terminal VMH is supplied to the row driver 783. Here, for example, a high power supply potential (e.g., the potential VDD) for operating the driver circuit 722 is supplied to the terminal VMD, and a low power supply potential (e.g., the potential VSS) is supplied to a terminal VMS. For example, a high power supply potential (e.g., the potential H) for operating the memory cells 741, the secondary sensing circuit 751, and the like is supplied to the terminal VMH. The power switch 761 is controlled to be in the conduction state or the non-conduction state by the signal supplied to the terminal PON1. The power switch 762 is controlled to be in the conduction state or the non-conduction state by the signal supplied to the terminal PON2.

Note that circuits and terminals are selected as appropriate in the driver circuit 722. Another circuit and another terminal may be added as appropriate.

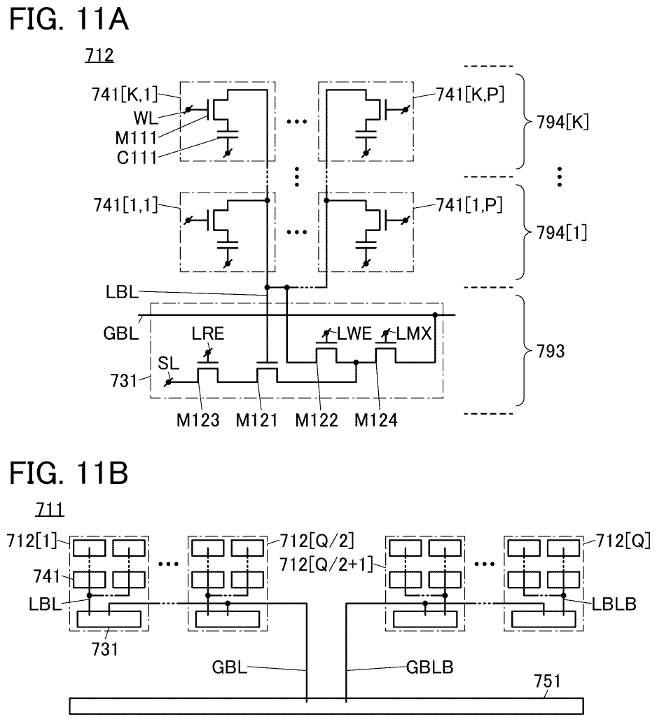

FIG. 11A is a circuit diagram of a memory unit 712 including one primary sensing circuit 731, a plurality of memory cells 741, and the wiring LBL.

In the memory unit 712, P (P is an integer greater than or equal to 1) memory cells 741 are placed in each of the K layers, the layer 794[1] to the layer 794[K]. That is, the memory unit 712 includes K×P memory cells 741.

FIG. 11A selectively illustrates the memory cell 741[1,1] and the memory cell 741[1,P] placed in the first layer (the layer 794[1]), and the memory cell 741[K,1] and the memory cell 741[K,P] placed in the K-th layer (the layer 794[K]). Note that the memory cells 741 arranged in the first layer are collectively referred to as a memory cell 741[1] and the memory cells 741 arranged in the K-th layer are collectively referred to as a memory cell 741[K] in some cases.

FIG. 11B is a circuit diagram of a memory block 711 including one secondary sensing circuit 751, a plurality of memory units 712, the wiring GBL, and the wiring GBLB.

In the memory block 711, Q (Q is an even number greater than or equal to 2) memory units 712 are arranged. That is, the memory block 711 includes K×P×Q memory cells 741.

FIG. 11B selectively illustrates a memory unit 712[1] and a memory unit 712[Q/2] which are electrically connected to the wiring GBL, and a memory unit 712[Q/2+1] and a memory unit 712[Q] which are electrically connected to the wiring GBLB.

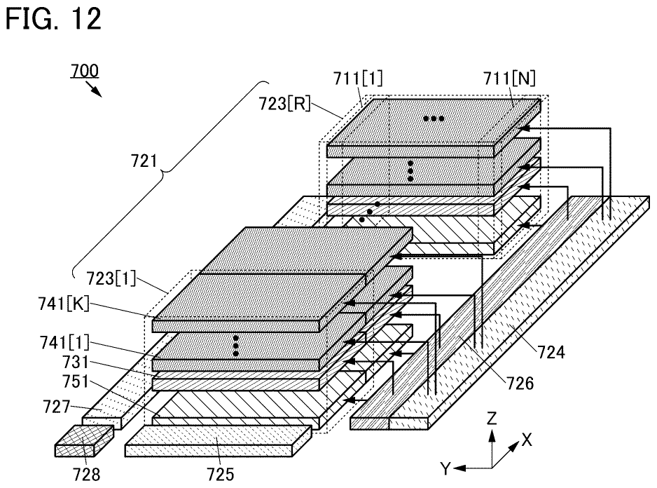

FIG. 12 is a schematic diagram illustrating an example of the placement of components included in the memory device 700.

In the memory device 700 illustrated in FIG. 12, the memory array 721 includes R (R is an integer greater than or equal to 1) memory subarrays 723 arranged in the column direction (X direction), and one memory subarray 723 includes N memory blocks 711 arranged in the row direction (Y direction).

Note that FIG. 12 selectively illustrates three memory subarrays 723, two (the memory subarray 723[1] and the memory subarray 723[R]) of which are surrounded by dashed lines. In addition, two memory blocks 711 (a memory block 711[1] and a memory block 711[N]) are selectively surrounded by dashed lines.

That is, the memory device 700 includes K×P×Q×R×N memory cells 741 placed in a three-dimensional matrix of K layers×M rows (P×Q×R rows)×N columns in the memory array 721. Since the memory device 700 includes R×N secondary sensing circuits 751, massively parallel reading of data stored in the memory array 721 can be performed by simultaneous access to the plurality of secondary sensing circuits 751.

In the memory device 700, a word line driver 724, a column driver 725, a sense amplifier driver 726, a data driver 727, and a memory controller 728 are placed in the layer 795 around the memory array 721.

Here, for example, the word line driver 724 and the sense amplifier driver 726 correspond to the row driver 783; the column driver 725 corresponds to the column driver 785; the data driver 727 corresponds to the data driver 786, the input circuit 787, and the output circuit 788; and the memory controller 728 corresponds to the control circuit 772 and the voltage generation circuit 773.

Although not illustrated, the memory device 700 can include a layer selection driver that is placed in the layer 793 and the layer 794[1] to the layer 794[K] over the word line driver 724. The layer selection driver can have a function of supplying a signal generated by the word line driver 724 to a given layer.

The semiconductor device according to one embodiment of the present invention is not limited to the semiconductor devices described in this embodiment. At least part of the structure examples, the operation examples, the drawings corresponding thereto, and the like described in this embodiment as an example can be combined as appropriate with the other structure examples, the other operation examples, the other drawings, the other embodiments, and the like described in this specification and the like.

### EMBODIMENT 2

In this embodiment, structure examples of a transistor and a capacitor that can be used in the semiconductor device described in the above-described Embodiment 1 are described.

### Structure Example of Transistor and Capacitor

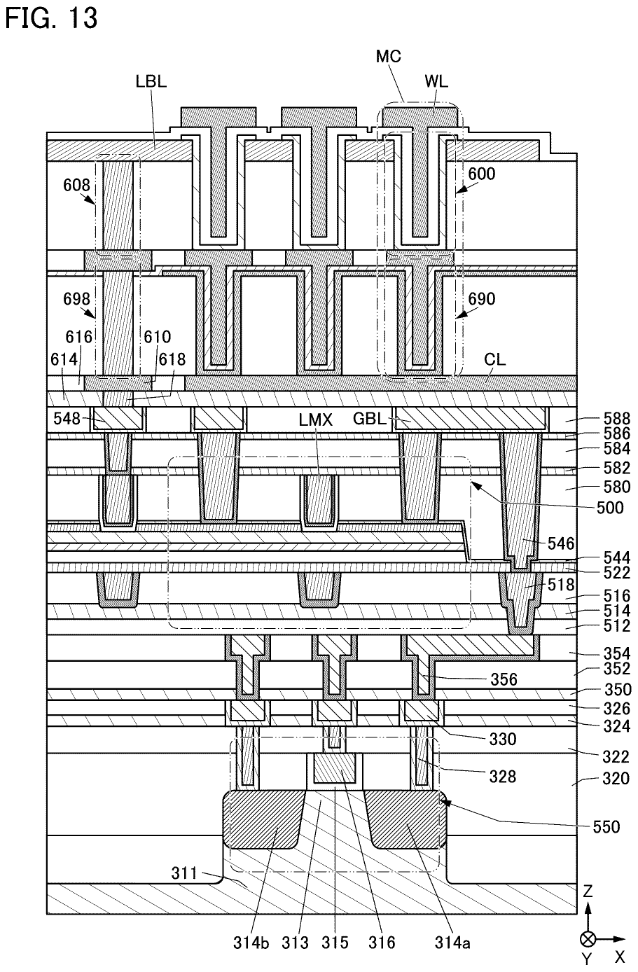

FIG. 13 is a cross-sectional view of a semiconductor device including a transistor 550, a transistor 500, a transistor 600, and a capacitor 690. Note that FIG. 13 is a cross-sectional view of the transistor 550 in the channel length direction (shown as the X direction).

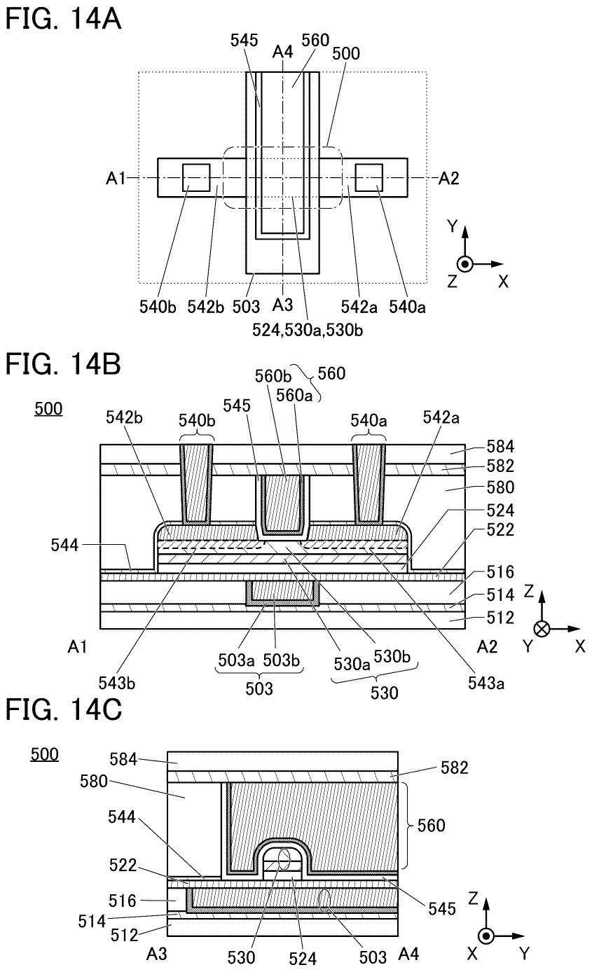

FIG. 14A is a top view of the transistor 500. Here, FIG. 14B is a cross-sectional view of a portion indicated by dashed-dotted line A1-A2 in FIG. 14A and is also a cross-sectional view of the transistor 500 in the channel length direction (shown as the X direction). FIG. 14C is a cross-sectional view of a portion indicated by dashed-dotted line A3-A4 in FIG. 14A and is also a cross-sectional view of the transistor 500 in the channel width direction (shown as the Y direction). Note that for clarity of the drawing, some components are omitted in the top view of FIG. 14A.

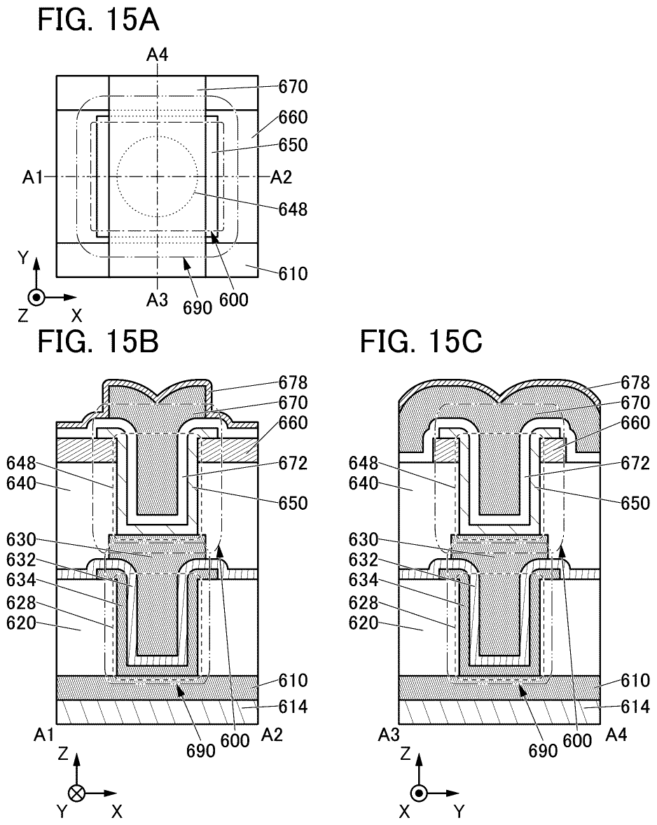

FIG. 15A is a top view of a semiconductor device including the transistor 600 and the capacitor 690. FIG. 15B is a cross-sectional view of a portion indicated by the dashed-dotted line A1-A2 in FIG. 15A. FIG. 15C is a cross-sectional view of a portion indicated by the dashed-dotted line A3-A4 in FIG. 15A. Note that some components are omitted in the top view in FIG. 15A for clarity of the drawing.

As illustrated in FIG. 13, the transistor 500 is provided above the transistor 550. The transistor 600 and the capacitor 690 are provided above the transistor 550 and the transistor 500.

The transistor 500 is connected to the transistor 550 through a conductor 328, a conductor 330, a conductor 356, a conductor 518, a conductor 546, and the like.

The transistor 600 is electrically connected to the transistor 500 through a via 608 and a via 698. Each of the via 608 and the via 698 is formed using a conductor having a function of a plug or a wiring.

Note that FIG. 13 illustrates a structure in which two transistors 500 share one island-shaped oxide (an oxide 530 illustrated in FIG. 14B and the like). In other words, part of the one island-shaped oxide functions as a channel formation region of one of the transistors 500, and another part thereof functions as a channel formation region of the other of the transistors 500. A source of one of the transistors 500 and a drain of the other of the transistors 500 are shared. Alternatively, a drain of one of the transistors 500 and a source of the other of the transistors 500 are shared. With such a structure, the area occupied by the transistor 500 can be smaller than that in the case where the two transistors 500 are independently provided. Note that three or more transistors may share one island-shaped oxide.

Note that in one embodiment of the present invention, the transistor 550, the transistor 500, the transistor 600, and the capacitor 690 can be used in the semiconductor device 100, the semiconductor device 110, the semiconductor device 100A, the semiconductor device 110A, and the like described above in Embodiment 1. That is, for example, the transistor 550 can be used for the secondary sensing circuit 113, the input/output circuit 114, the memory circuit 115, and the like, the transistor 500 can be used for the primary sensing circuit 112 and the like, and the transistor 600 and the capacitor 690 (memory cell MC) can be used for the memory cell 111 and the like. Note that FIG. 13 illustrates portions corresponding to the semiconductor device 110 (the wiring WL, the wiring CL, the wiring LBL, the wiring GBL, and the wiring LMX), for example.

### [Transistor 550]

As illustrated in FIG. 13, the transistor 550 is provided over a substrate 311 and includes a conductor 316 functioning as a gate electrode, an insulator 315 functioning as a gate insulating film, a semiconductor region 313 functioning as a channel formation region, a low-resistance region 314a functioning as one of a source region and a drain region, and a low-resistance region 314b functioning as the other of the source region and the drain region.

Note that the transistor 550 may be either a p-channel transistor or an n-channel transistor. For example, by electrically connecting a gate of the n-channel transistor 550 and a gate of the p-channel transistor 550, a CMOS circuit (e.g., a circuit that operates complementarily, a CMOS logic gate, or a CMOS logic circuit) can be formed.

Note that for example, the transistor 550 can have what is called a Fin-type structure in which the side surface in the channel width direction and the top surface of the semiconductor region 313 that is part of the substrate 311 are covered with the conductor 316 with the insulator 315 therebetween. Thus, the effective channel width is increased, whereby the on-state characteristics of the transistor 550 can be improved. In addition, contribution of an electric field of a gate electrode can be increased, so that the off-state characteristics of the transistor 550 can be improved.

The transistor 550 preferably includes a semiconductor such as a silicon-based semiconductor, further preferably includes single crystal silicon in a region of the semiconductor region 313 where a channel is formed, a region in the vicinity thereof, the low-resistance region 314a functioning as one of the source region and the drain region, the low-resistance region 314b functioning as the other of the source region and the drain region, and the like, for example. Alternatively, the transistor 550 may be formed using a material including germanium, silicon germanium, gallium arsenide, gallium aluminum arsenide, or the like, for example. Alternatively, the transistor 550 may include silicon whose effective mass is controlled by applying stress to the crystal lattice and thereby changing the lattice spacing. Alternatively, the transistor 550 may be a high electron mobility transistor (HEMT) using gallium arsenide, gallium aluminum arsenide, or the like, for example.

The low-resistance region 314a and the low-resistance region 314b include an element that imparts n-type conductivity, such as arsenic or phosphorus, or an element that imparts p-type conductivity, such as boron, for example, in addition to a semiconductor material used for the semiconductor region 313.

As the conductor 316, a semiconductor material such as silicon including the element that imparts n-type conductivity, such as arsenic or phosphorus, or the element that imparts p-type conductivity, such as boron, can be used, for example. Alternatively, a conductive material such as a metal material, an alloy material, or a metal oxide material can be used, for example.

Note that since the work function depends on the material of a conductor, the threshold voltage of the transistor can be adjusted by selecting the material of the conductor.

A material such as titanium nitride or tantalum nitride is preferably used as the conductor 316, for example. Furthermore, in order to ensure both conductivity and embeddability, it is preferable to use stacked layers of metal materials such as tungsten and aluminum. It is particularly preferable to use tungsten in stacked layers in terms of heat resistance.

An insulator 320, an insulator 322, an insulator 324, and an insulator 326 are sequentially stacked and provided to cover the transistor 550.

It is preferable to use silicon oxide, silicon oxynitride, silicon nitride oxide, silicon nitride, aluminum oxide, aluminum oxynitride, aluminum nitride oxide, or aluminum nitride as the insulator 320, the insulator 322, the insulator 324, and the insulator 326, for example. It is particularly preferably to use silicon oxide or silicon oxynitride in terms of thermal stability.

In this specification and the like, silicon oxynitride refers to a material that has a higher oxygen content than a nitrogen content, and silicon nitride oxide refers to a material that has a higher nitrogen content than an oxygen content. Moreover, in this specification and the like, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by the transistor 550 or the like provided below the insulator 322. For example, the top surface of the insulator 322 may be planarized by planarization treatment using a chemical mechanical polishing (CMP) method or the like to improve planarity.

In addition, as the insulator 324, it is preferable to use an insulator having a barrier property that prevents diffusion of impurities such as hydrogen from the substrate 311, the transistor 550, or the like into a region where the transistor 500 is provided.

As the insulator having a barrier property against hydrogen, silicon nitride formed by a CVD method can be used, for example. Furthermore, a metal oxide such as aluminum oxide, hafnium oxide, or tantalum oxide can be used, for example.

Here, for example, diffusion of hydrogen into a semiconductor element including an oxide semiconductor, such as the transistor 500, degrades the characteristics of the semiconductor element in some cases. Thus, an insulator that inhibits diffusion of hydrogen is preferably used between the transistor 500 and the transistor 550. The insulator that inhibits hydrogen diffusion is specifically an insulator from which a small amount of hydrogen is released.

The dielectric constant of the insulator 326 is preferably lower than that of the insulator 324. For example, the relative permittivity of the insulator 326 is preferably lower than 4, further preferably lower than 3. In addition, the relative permittivity of the insulator 326 is, for example, preferably lower than or equal to 0.7 times, further preferably lower than or equal to 0.6 times the relative permittivity of the insulator 326. When a material with a low dielectric constant is used for an interlayer film, parasitic capacitance generated between wirings can be reduced.

A conductor (e.g., a conductor 328 and a conductor 330) is embedded in the insulator 320, the insulator 322, the insulator 324, and the insulator 326.

The conductor 328 and the conductor 330 each have a function of a plug or a wiring.

In this specification and the like, a plurality of structures of conductors functioning as plugs or wirings are collectively denoted by the same reference numeral in some cases. Furthermore, a wiring and a plug may be a single component. That is, part of a conductor functions as a wiring in some cases and part of a conductor functions as a plug in other cases.

For each of the plugs or the wirings (e.g., the conductor 328, the conductor 330, and the like), a single layer or stacked layers of a conductive material such as a metal material, an alloy material, a metal nitride material, or a metal oxide material can be used, for example.

It is particularly preferable to use, as each of the plugs or wiring, a high-melting-point material that has both heat resistance and conductivity. As such a material, tungsten, molybdenum, copper, or the like can be used, for example. Furthermore, as each of the plugs or wirings, a low-resistance conductive material that can reduce wiring resistance is preferably used. As such a material, aluminum, copper, or the like can be used, for example.

A wiring layer may be provided over the insulator 326 and the conductor 330. For example, in FIG. 13, an insulator 350, an insulator 352, and an insulator 354 are sequentially stacked and provided. Furthermore, a conductor 356 is embedded in the insulator 350, the insulator 352, and the insulator 354.

The conductor 356 functions as a plug or a wiring. The conductor 356 can be formed using a material similar to those for the conductor 328, the conductor 330, or the like, for example. It is particularly preferable to use a conductor having a barrier property against hydrogen.

As the insulator 350, the insulator 352, and the insulator 354, materials similar to those of the insulator 324, the insulator 322, the insulator 326, and the like can be used, for example. It is particularly preferable to use an insulator having a barrier property against hydrogen.

Here, the conductor having a barrier property against hydrogen is formed in an opening included in the insulator 350 having a barrier property against hydrogen. With this structure, the transistor 550 and the transistor 500 can be separated by the conductor having a barrier property against hydrogen. Thus, diffusion of hydrogen from the transistor 550 into the transistor 500 can be inhibited.

For the conductor having a barrier property against hydrogen, tantalum nitride or the like may be used, for example. Stacked layers of tantalum nitride and tungsten, which has high conductivity, may be used. When the conductor is stacked layers of tantalum nitride and tungsten, the conductor can inhibit diffusion of hydrogen while the conductivity as a wiring is ensured.

In other words, when the conductor 356 is stacked layers of tantalum nitride and tungsten, the conductor 356 can inhibit diffusion of hydrogen from the transistor 550 while the conductivity as a wiring is ensured. In that case, the tantalum nitride layer of the conductor 356 having a barrier property against hydrogen is preferably in contact with the insulator 350 having a barrier property against hydrogen.

Note that although a wiring layer including the conductor 356 is described here, there is no limitation thereto. No wiring layer including the conductor 356 may be provided, or two or more wiring layers that are similar to the wiring layer including the conductor 356 may be provided.

Note that the transistor 550 illustrated in FIG. 13 is an example and the structure is not limited thereto.

### [Transistor 500]

Next, a structure of the transistor 500 provided over the insulator 354 is described with reference to FIG. 13 and FIG. 14A to FIG. 14C.

As illustrated in FIG. 13, an insulator 512, an insulator 514, and an insulator 516 are provided to be stacked in this order over the insulator 354.

An insulator having a barrier property against oxygen, hydrogen, or the like is preferably used for any of the insulator 512, the insulator 514, and the insulator 516.

For example, for the insulator 514, it is preferable to use an insulator having a barrier property that prevents diffusion of impurities such as hydrogen from the substrate 311, a region where the transistor 550 is provided, or the like into a region where the transistor 500 is provided. Thus, a material similar to that for the insulator 324 or the like can be used for the insulator 514, for example.

As the insulator having a barrier property against hydrogen, a metal oxide such as aluminum oxide, hafnium oxide, or tantalum oxide is preferably used, for example.

Aluminum oxide especially has a high barrier property against both oxygen and impurities such as hydrogen and water. Accordingly, aluminum oxide can prevent entry of impurities such as hydrogen and water into the transistor 500 during and after the manufacturing of the transistor, and can inhibit release of oxygen from the oxide included in the transistor 500. Thus, aluminum oxide is suitably used for a protective film of the transistor 500.

Using a material with a relatively low permittivity for the insulator 512 and the insulator 516 can reduce the parasitic capacitance generated between wirings. For the insulator 512 and the insulator 516, a material similar to that for the insulator 326 or the like can be used, for example.

A conductor 518, a conductor included in the transistor 500 (e.g., a conductor 503 illustrated in FIG. 14B or the like), and the like are embedded in the insulator 512, the insulator 514, and the insulator 516, for example.

The conductor 518 has a function of a plug or a wiring. The conductor 518 can be formed using a material similar to those for the conductor 328, the conductor 330, and the like, for example.

In particular, the conductor 518 in a region in contact with the insulator 514 is preferably a conductor having a barrier property against both oxygen and impurities such as hydrogen and water. With such a structure, the transistor 550 and the transistor 500 can be separated by a conductor having a barrier property against both oxygen and impurities such as hydrogen and water; thus, diffusion of hydrogen from the transistor 550 into the transistor 500 can be inhibited.

The transistor 500 is provided above the insulator 516.

As illustrated in FIG. 14B and FIG. 14C, the transistor 500 includes the conductor 503 placed to be embedded in the insulator 514 and the insulator 516, an insulator 522 placed over the insulator 516 and the conductor 503, an insulator 524 placed over the insulator 522, an oxide 530a placed over the insulator 524, an oxide 530b placed over the oxide 530a, a conductor 542a and a conductor 542b placed apart from each other over the oxide 530b, an insulator 580 that is placed over the conductor 542a and the conductor 542b and is provided with an opening formed to overlap with a region between the conductor 542a and the conductor 542b, an insulator 545 placed along the opening, and a conductor 560 placed on a formation surface of the insulator 545.

Note that the oxide 530a and the oxide 530b are sometimes collectively referred to as an oxide 530. In addition, the conductor 542a and the conductor 542b are sometimes collectively referred to as a conductor 542.

The oxide 530 has a function of a semiconductor film including a channel formation region of the transistor 500.

The conductor 503 is placed to overlap with the oxide 530 and the conductor 560.

Here, the conductor 503 preferably includes a conductor 503a provided to be in contact with the insulator 514 and the insulator 516 and a conductor 503b provided to be embedded inside the conductor 503a. An insulator 544 is preferably placed between the insulator 580 and the oxide 530a, the oxide 530b, the conductor 542a, and the conductor 542b. The conductor 560 preferably includes a conductor 560a provided inside the insulator 545 and a conductor 560b provided to be embedded inside the conductor 560a. An insulator 582 is preferably placed over the insulator 580, the conductor 560, and the insulator 545.

Although the transistor 500 illustrated in FIG. 14B and FIG. 14C has a structure in which two layers of the conductor 503a and the conductor 503b are stacked as the conductor 503, one embodiment of the present invention is not limited thereto. For example, the conductor 503 may have a single-layer structure or a stacked-layer structure of three or more layers.

Although end portions of the conductor 542a and the conductor 542b and end portions of the oxide 530 are aligned with each other in the illustrated structure, there is not limitation thereto. For example, the conductor 542a and the conductor 542b may extend beyond the end portions of the oxide 530.

Although the oxide 530 having a structure in which two layers of the oxide 530a and the oxide 530b are stacked is illustrated, the oxide 530 is not limited thereto. For example, the oxide 530 may have a single-layer structure or a stacked-layer structure of three or more layers.

Although the conductor 560 having a structure in which two layers of the conductor 560a and the conductor 560b are stacked is illustrated, the conductor 560 is not limited thereto.

For example, the conductor 560 may have a single-layer structure or a stacked-layer structure of three or more layers.

Here, in the transistor 500, the conductor 560 has a function of a gate electrode, the insulator 545 has a function of a gate insulating film, and the conductor 542a and the conductor 542b each have a function of one or the other of a source electrode and a drain electrode.

As described above, the conductor 560 is formed to be embedded in an opening formed in a region that is of the insulator 580 and sandwiched between the conductor 542a and the conductor 542b (the opening is also referred to as an opening of the insulator 580 in some cases). Thus, the placement of the conductor 560, the conductor 542a, and the conductor 542b with respect to the opening of the insulator 580 is selected in a self-aligned manner. That is, in the transistor 500, the gate electrode can be placed between the source electrode and the drain electrode in a self-aligned manner. With this structure, the conductor 560 can be formed without an alignment margin. Hence, the area occupied by the transistor 500 can be reduced. Accordingly, miniaturization and high integration of the semiconductor device can be achieved.

Since the conductor 560 is formed in the region between the conductor 542a and the conductor 542b in a self-aligned manner, the conductor 560 does not have a region overlapping with the conductor 542a or the conductor 542b. Thus, parasitic capacitance formed between the conductor 560 and each of the conductor 542a and the conductor 542b can be reduced. Thus, the switching speed of the transistor 500 can be improved. Accordingly, frequency characteristics of the semiconductor device can be improved.

A shorter gate length of the transistor 500 is required for miniaturization of the semiconductor device, but in that case it is necessary to prevent a reduction in the conductivity of the conductor 560. When the conductor 560 is made thick to achieve this, the conductor 560 might have a shape with a high aspect ratio. Providing the conductor 560 such that the conductor 560 is embedded in the opening of the insulator 580 enables the conductor 560 having a shape with a high aspect ratio to be formed without collapsing during the process.

Here, the conductor 560 has a function of a first gate (also simply referred to as a top gate) electrode and the conductor 503 has a function of a second gate (also referred to a back gate) electrode, in some cases. In that case, the insulator 545 has a function of a first gate insulating film, and the insulator 522 and the insulator 524 have a function of a second gate insulating film.

As described above, the conductor 503 is placed to overlap with the oxide 530 and the conductor 560. Thus, when a potential is applied to the conductor 560 and the conductor 503, an electric field generated from the conductor 560 and an electric field generated from the conductor 503 are connected, so that the channel formation region formed in the oxide 530 can be covered.

In that case, in the transistor 500, by changing a potential applied to the conductor 503 independently of a potential applied to the conductor 560, the threshold voltage of the transistor 500 can be controlled, for example. In particular, when a negative potential is applied to the conductor 503, the threshold voltage of the transistor 500 can be increased, and the off-state current can be reduced. Thus, for example, by applying a negative potential to the conductor 503, a drain current at the time when the potential applied to the conductor 560 is 0 V (sometimes referred to as a cutoff current) can be reduced.

In this specification and the like, a transistor structure in which a channel formation region is electrically surrounded by an electric field of a gate electrode is referred to as a surrounded channel (S-channel) structure. The S-channel structure disclosed in this specification and the like can be regarded as having a structure different from a Fin-type structure or a planar structure. Meanwhile, the S-channel structure disclosed in this specification and the like can be regarded as a kind of a Fin-type structure or a kind of a planar structure. In this specification and the like, a Fin-type structure refers to a structure in which at least two surfaces (specifically, two surfaces, three surfaces, four surfaces, or the like) of a channel are covered with a gate electrode. With the use of a Fin-type structure and an S-channel structure, a transistor with high resistance to a short-channel effect can be obtained. In other words, a transistor in which a short-channel effect is unlikely to occur can be obtained.

When the transistor has the above-described S-channel structure, the channel formation region can be electrically surrounded by an electric field of a gate electrode. Since the S-channel structure is a structure with the channel formation region electrically surrounded by an electric field of a gate electrode, the S-channel structure is, in a sense, equivalent to a GAA (Gate All Around) structure or an LGAA (Lateral Gate All Around) structure. When the transistor has an S-channel structure, a GAA structure, or an LGAA structure, the channel formation region that is formed at the interface between the semiconductor film and the gate insulating film or in the vicinity of the interface can be formed in the entire bulk of the semiconductor film. Accordingly, the density of current flowing through the transistor can be improved, which can be expected to improve the on-state current of the transistor or increase the field-effect mobility of the transistor.

In addition, the conductor 503 has a structure similar to that of the conductor 518; as described above, the conductor 503a is formed in contact with the insulator 514 and the insulator 516, and the conductor 503b is formed on the inner side.

As the conductor 503a, a conductive material having a barrier property against impurities such as hydrogen (e.g., at least one of a hydrogen atom, a hydrogen molecule, and the like), water, and copper (a conductive material having a function of inhibiting diffusion of the impurities; i.e., a conductive material through which the impurities do not easily pass) is preferably used, for example. As the conductor 503a, a conductive material having a barrier property against oxygen (e.g., at least one of an oxygen atom, an oxygen molecule, and the like) (a conductive material having a function of inhibiting diffusion of oxygen; i.e., a conductive material through which oxygen does not easily pass) is preferably used. That is, the conductor 503a preferably has a barrier property against either one or all of the above impurities and the above oxygen.

When the conductor 503a has a barrier property against oxygen as described above, a reduction in the conductivity of the conductor 503b due to oxidation can be inhibited, for example. Thus, the conductor 503 can also have a function of a wiring.

In that case, a conductive material having high conductivity is preferably used as the conductor 503b. For example, a conductive material including tungsten, copper, or aluminum as its main component can be used.

Here, as the insulator in contact with the oxide 530, an insulator that includes oxygen more than oxygen in the stoichiometric composition is preferably used. Such oxygen is easily released from the insulator by heating. In this specification and the like, oxygen released by heating is sometimes referred to as “excess oxygen”.

The insulator 524 is in contact with the oxide 530. Thus, a region including excess oxygen (also referred to as an “excess-oxygen region”) is preferably formed in the insulator 524.

When such an insulator including excess oxygen is provided to be in contact with the oxide 530, oxygen vacancies (also referred to as V_{O}) in the oxide 530 can be reduced and the reliability of the transistor 500 can be increased.

In the oxide 530, defects of oxygen vacancies which hydrogen enters in the oxide 530 (hereinafter, sometimes referred to as V_{O}H) serve as donors and generate electrons serving as carriers in some cases. In other cases, bonding of part of hydrogen to oxygen bonded to a metal atom generates electrons serving as carriers. Thus, a transistor using an oxide semiconductor that includes a large amount of hydrogen is likely to have normally-on characteristics. Moreover, hydrogen in an oxide semiconductor is easily transferred by a stress such as heat or an electric field, for example; thus, a large amount of hydrogen in an oxide semiconductor might reduce the reliability of a transistor. In one embodiment of the present invention, V_{O}H in the oxide 530 is preferably reduced as much as possible so that the oxide 530 becomes a highly purified intrinsic or substantially highly purified intrinsic oxide.

It is important to remove impurities such as hydrogen and water in an oxide semiconductor (this treatment is also referred to as “dehydration” or “dehydrogenation treatment”) and to compensate for oxygen vacancies by supplying oxygen to the oxide semiconductor (this treatment is also referred to as “oxygen adding treatment”) in order to obtain an oxide semiconductor whose V_{O}H is sufficiently reduced. For example, when an oxide semiconductor with sufficiently reduced impurities such as V_{O}H is used for a channel formation region of a transistor, stable electrical characteristics can be given.

Moreover, in the case where the insulator 524 includes an excess-oxygen region, the insulator 522 preferably has a barrier property against oxygen. When the insulator 522 has a barrier property against oxygen, diffusion of oxygen included in the oxide 530 to the insulator 516 side can be inhibited, for example. Furthermore, for example, the conductor 503 can be inhibited from reacting with oxygen included in the insulator 524, the oxide 530, and the like.

Here, it is preferable in a transistor using an oxide semiconductor in a semiconductor film that a channel formation region of the transistor include fewer oxygen vacancies or have a lower concentration of impurities (e.g., concentration of hydrogen, nitrogen, a metal element, and the like) than a source region and a drain region. In addition, in some cases, V_{O}H is formed with hydrogen in the vicinity of an oxygen vacancy and an electron serving as a carrier is generated; therefore, it is also preferable that the amount of V_{O}H be small. Hence, the channel formation region of the transistor is a high-resistance region having a low carrier concentration. Accordingly, the channel formation region of the transistor can be regarded as an i-type (intrinsic) or substantially i-type region.

The source region and the drain region of the transistor preferably include more oxygen vacancies, include more V_{O}H, or have a higher impurity concentration than the channel formation region. Thus, the source region and the drain region of the transistor are n-type regions that have a higher carrier concentration and a lower resistance than the channel formation region.

The metal oxide used as the oxide semiconductor preferably has a band gap of 2 eV or higher, further preferably 2.5 eV or higher. With the use of a metal oxide having a wide band gap as the oxide semiconductor, the off-state current of the transistor can be reduced.

As the insulator 522, an insulator of a high dielectric constant (high-k) material (a material with a high relative permittivity) is preferably used.

As miniaturization and high integration of transistors progress, a problem such as gate leakage current sometimes arises because of a thin gate insulating film, for example. When a high-k material is used as an insulator functioning as a gate insulating film, a gate potential during transistor operation can be reduced while the physical thickness is maintained.

As the insulator functioning as a gate insulating film, it is preferable to use a single layer or stacked layers of an insulator including aluminum oxide, hafnium oxide, an oxide including aluminum and hafnium (hafnium aluminate), tantalum oxide, zirconium oxide, lead zirconate titanate (PZT), strontium titanate (SrTiO₃), or barium strontium titanate (BST), for example.

An insulator including an oxide of one or both of aluminum and hafnium may be used since it is an insulator having a barrier property against oxygen and impurities. Aluminum oxide, hafnium oxide, an oxide including aluminum and hafnium (hafnium aluminate), or the like is preferably used as the insulator, for example.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators having been subjected to nitriding treatment may be used. Stacked layers in which silicon oxide, silicon oxynitride, or silicon nitride is stacked over these insulators may be used.

In the case where the insulator 522 is formed using such a material, the insulator 522 can function as an insulator that inhibits release of oxygen from the oxide 530 and mixing of impurities such as hydrogen from the periphery of the transistor 500 into the oxide 530.

Although the transistor 500 illustrated in FIG. 14B and FIG. 14C has a structure in which two layers of the insulator 522 and the insulator 524 are stacked as the second gate insulating film, there is no limitation thereto. For example, a single-layer structure or a stacked-layer structure of three or more layers may be employed. In that case, either a structure in which the same materials are stacked or a structure in which different materials are stacked may be employed.

In the transistor 500, a metal oxide functioning as an oxide semiconductor is used as the oxide 530 including a channel formation region. As the oxide semiconductor, a single layer or stacked layers of a metal oxide can be used.

The metal oxide preferably includes at least one of indium and zinc. The metal oxide preferably includes indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin.

It is particularly preferable that an oxide including indium (In), gallium (Ga), and zinc (Zn) (also referred to as “IGZO”) be used as the metal oxide. Alternatively, an oxide including indium (In), aluminum (A1), and zinc (Zn) (also referred to as “IAZO”) may be used. Further alternatively, an oxide including indium (In), aluminum (A1), gallium (Ga), and zinc (Zn) (also referred to as “IAGZO”) may be used. Further alternatively, an oxide including indium (In), tin (Sn), and zinc (Zn) (also referred to as “ITZO (registered trademark)”) may be used. Further alternatively, an oxide including indium (In), gallium (Ga), zinc (Zn), and tin (Sn) (also referred to as “IGZTO”) may be used.

When the metal oxide is an In-M-Zn oxide, the proportion of the number of In atoms is preferably higher than or equal to the proportion of the number of M atoms in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof.

The proportion of the number of In atoms may be lower than the proportion of the number of M atoms in the In-M-Zn oxide. Examples of the atomic ratio of the metal elements in such an In-M-Zn oxide include In:M:Zn=1:3:2 or a composition in the neighborhood thereof and In:M:Zn=1:3:4 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where the content ratio of each element is as follows: Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where the content ratio of each element is as follows: Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where the content ratio of each element is as follows: Ga is greater than 0.1 and less than or equal to 2 and Zn is greater than 0.1 and less than or equal to 2 with In being 1.

In the case where stacked metal oxides are used, for example, a three-layer stacked structure in which a metal oxide where the atomic ratio of metal elements is In:Ga:Zn=1:1:1 is a first layer, a metal oxide where the atomic ratio of metal elements is In:Zn=4:1 is a second layer, and a metal oxide where the atomic ratio of metal elements is In:Ga:Zn=1:1:1 is a third layer can be employed. Note that the band gaps of the first-layer and third-layer metal oxides are preferably larger than the band gap of the second-layer metal oxide. With this structure, the main current path can be the second-layer metal oxide, so that what is called a buried channel structure can be obtained.

A sputtering method or an atomic layer deposition (ALD) method can be used for forming the metal oxide. In the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

The oxide semiconductor preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single crystal oxide semiconductor. As the oxide semiconductor, the CAAC-OS or the nc-OS is preferably used, and the CAAC-OS is particularly preferably used.

The CAAC-OS preferably includes a plurality of layered crystal regions and the c-axis is preferably aligned in a normal direction of a surface where the CAAC-OS is deposited. For example, the oxide semiconductor preferably includes layered crystals parallel to the formation surface. With this structure, the layered crystals of the oxide semiconductor are formed parallel to the channel length direction of the transistor, so that the on-state current of the transistor can be increased.

In the oxide 530, the oxide 530a is provided under the oxide 530b. This can inhibit diffusion of impurities into the oxide 530b from the components formed below the oxide 530a.

The oxide 530 preferably has a plurality of oxide layers that differ in the atomic ratio of metal atoms. Specifically, the atomic ratio of the element M to the constituent elements in the metal oxide used as the oxide 530a is preferably higher than the atomic ratio of the element M to the constituent elements in the metal oxide used as the oxide 530b. In addition, the atomic ratio of the element M to In in the metal oxide used as the oxide 530a is preferably higher than the atomic ratio of the element M to In in the metal oxide used as the oxide 530b. Furthermore, the atomic ratio of In to the element Min the metal oxide used as the oxide 530b is preferably higher than the atomic ratio of In to the element Min the metal oxide used as the oxide 530a.

The energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gradually changes at a junction portion of the oxide 530a and the oxide 530b. In other words, the energy level of the conduction band minimum at the junction portion of the oxide 530a and the oxide 530b continuously changes or is continuously connected. To change the energy level gradually, the density of defect states in a mixed layer formed at an interface between the oxide 530a and the oxide 530b may be made low.

Specifically, when the oxide 530a and the oxide 530b include a common element (as a main component) in addition to oxygen, a mixed layer with a low density of defect states can be formed. For example, in the case where the oxide 530b is an In—Ga—Zn oxide, an In—Ga—Zn oxide, a Ga—Zn oxide, gallium oxide, or the like may be used as the oxide 530a.

At this time, the oxide 530b serves as a main carrier path. When the oxide 530a has the above-described structure, the density of defect states at the interface between the oxide 530a and the oxide 530b can be made low. Thus, the influence of interface scattering on carrier conduction is small, and the transistor 500 can have an increased on-state current.

The conductor 542a and the conductor 542b functioning as the source electrode and the drain electrode are provided over the oxide 530b.

For the conductor 542a and the conductor 542b, for example, it is possible to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy including any of these metal elements as its component; an alloy including a combination of these metal elements; or the like. For example, it is particularly preferable to use tantalum nitride, titanium nitride, a nitride including titanium and aluminum, a nitride including tantalum and aluminum, ruthenium oxide, ruthenium nitride, an oxide including strontium and ruthenium, an oxide including lanthanum and nickel, or the like, which are each a conductive material that is not easily oxidized or a material that maintains its conductivity even after absorbing oxygen. Moreover, in terms of having a barrier property against oxygen, hydrogen, and the like, a metal nitride film of tantalum nitride or the like is preferably used, for example.

Although the transistor 500 illustrated in FIG. 14B and FIG. 14C has a structure in which the conductor 542a and the conductor 542b have a single-layer structure, there is no limitation thereto. The conductor 542a and the conductor 542b may have a structure in which two or more layers are stacked, for example.

For the conductor 542a and the conductor 542b, a structure in which a tantalum nitride film and a tungsten film are stacked, a structure in which a titanium film and an aluminum film are stacked, a structure in which an aluminum film is stacked over a tungsten film, a structure in which a copper film is stacked over a copper-magnesium-aluminum alloy film, a structure in which a copper film is stacked over a titanium film, or a structure in which a copper film is stacked over a tungsten film may be employed, for example.

For another example, the conductor 542a and the conductor 542b may each have a three-layer structure in which an aluminum film or a copper film is stacked over a titanium film or a titanium nitride film and a titanium film or a titanium nitride film is stacked thereover, a three-layer structure in which an aluminum film or a copper film is stacked over a molybdenum film or a molybdenum nitride film and a molybdenum film or a molybdenum nitride film is stacked thereover, or the like.

Note that a transparent conductive material including indium oxide, tin oxide, or zinc oxide may be used for the conductor 542a and the conductor 542b, for example.

Here, as illustrated in FIG. 14B, a region 543a is sometimes formed at and in the vicinity of the interface with the conductor 542a in the oxide 530, as a low-resistance region. In addition, a region 543b is sometimes formed at and in the vicinity of the interface with the conductor 542b in the oxide 530, as a low-resistance region. In that case, the region 543a functions as one of a source region and a drain region, and the region 543b functions as the other of the source region and the drain region. A channel formation region is formed in a region sandwiched between the region 543a and the region 543b.

When the conductor 542a and the conductor 542b are provided in contact with the oxide 530 in this manner, the oxygen concentration in each of the region 543a and the region 543b sometimes decreases. In addition, a metal compound layer that includes the metal included in the conductor 542a and the conductor 542b and the component of the oxide 530 is sometimes formed in the region 543a and the region 543b. In such a case, the carrier concentration in the region 543a and the region 543b increases, and the region 543a and the region 543b become low-resistance regions.

The insulator 544 is provided to cover the conductor 542a and the conductor 542b and inhibits oxidation of the conductor 542a and the conductor 542b. In that case, the insulator 544 may be provided to cover the side surface of the oxide 530 and the side surface of the insulator 524 and to be in contact with the insulator 522.

A metal oxide including one kind or two or more kinds selected from hafnium, aluminum, gallium, yttrium, zirconium, tungsten, titanium, tantalum, nickel, germanium, neodymium, lanthanum, magnesium, and the like can be used for the insulator 544, for example. It is also possible to use silicon nitride oxide, silicon nitride, or the like, for example.

Alternatively, an insulator including an oxide of one or both of aluminum and hafnium may be used. Aluminum oxide, hafnium oxide, an oxide including aluminum and hafnium (hafnium aluminate), or the like can be used, for example. For example, it is particularly preferable to use hafnium aluminate because it has high heat resistance and is unlikely to be crystallized by heat treatment in a later step.

Note that the insulator 544 is not necessarily provided when the conductor 542a and the conductor 542b are oxidation-resistant materials or materials that do not significantly lose their conductivity even after absorbing oxygen.

The insulator 544 can inhibit impurities such as water and hydrogen included in the insulator 580 from diffusing into the oxide 530b. In addition, oxidation of the conductor 542a and the conductor 542b due to excess oxygen included in the insulator 580 can be inhibited.

Like the above-described insulator 524, the insulator 545 is preferably formed using an insulator that includes excess oxygen and releases oxygen by heating. This allows oxygen to be effectively supplied to the channel formation region of the oxide 530b from the insulator 545.

Specifically, as the insulator 545, silicon oxide including excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used, for example. In particular, silicon oxide or silicon oxynitride having thermal stability is preferably used.

As the insulator 545, as in the above-described insulator 524, an insulator having a reduced concentration of impurities such as hydrogen and water in the insulator 545 is preferably used. Note that the thickness of the insulator 545 is preferably greater than or equal to 1 nm and less than or equal to 20 nm.

Here, in order that excess oxygen included in the insulator 545 can be efficiently supplied to the oxide 530, a metal oxide may be provided between the insulator 545 and the conductor 560. The metal oxide preferably has a barrier property against oxygen. Accordingly, diffusion of excess oxygen from the insulator 545 into the conductor 560 is inhibited. Thus, a reduction in the amount of excess oxygen supplied to the oxide 530 can be inhibited. Moreover, oxidation of the conductor 560 due to excess oxygen can be inhibited. As the metal oxide, a material that can be used for the insulator 544 may be used, for example.

Although the transistor 500 illustrated in FIG. 14B and FIG. 14C has a structure in which the insulator 545 is a single layer, there is no limitation thereto. For example, the insulator 545 functioning as the first gate insulating film may have a structure in which two or more layers are stacked, like the insulator 522 and the insulator 524 functioning as the second gate insulating film. For example, the insulator 545 may have a structure in which a high-k material and a thermally stable material are stacked. This can reduce the gate voltage during the operation of the transistor 500 while keeping the physical thickness of the insulator 545.

As the conductor 560a included in the conductor 560, a conductive material having a barrier property against impurities such as hydrogen, water, nitrogen, nitrogen oxide (e.g., N₂O, NO, and NO₂), and copper is preferably used, for example. Furthermore, a conductive material having a barrier property against oxygen is preferably used. When the conductor 560a has a barrier property against oxygen, it is possible to inhibit a reduction in conductivity of the conductor 560b due to oxidation caused by oxygen included in the insulator 545.

As a conductive material having a barrier property against oxygen, tantalum, tantalum nitride, ruthenium, ruthenium oxide, or the like is preferably used, for example.

As the conductor 560a, an oxide semiconductor that can be used as the oxide 530 can be used. In that case, by depositing the conductor 560b by a sputtering method, the conductor 560a can have a reduced electrical resistance value to become a conductor. Such a conductor can be referred to as an OC (Oxide Conductor) electrode.

The conductor 560 can also have a function of a wiring. Thus, as the conductor 560b, a conductive material having high conductivity, is preferably used as in the conductor 503b. For example, a conductive material including tungsten, copper, or aluminum as its main component can be used.

Note that the conductor 560b may have a structure in which different materials are stacked. For example, a structure in which titanium or titanium nitride and the above conductive material are stacked may be employed.

The insulator 580 is provided over the conductor 542a and the conductor 542b with the insulator 544 therebetween.

The insulator 580 preferably includes an excess-oxygen region.

For example, as the insulator 580, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like can be used. It is particularly preferably to use silicon oxide or silicon oxynitride in terms of thermal stability. Moreover, it is preferable to use silicon oxide or porous silicon oxide, in which case an excess-oxygen region can be easily formed in a later step.

In the case where the insulator 580 including an excess-oxygen region is provided, oxygen is released by heating, so that oxygen in the insulator 580 can be efficiently supplied to the oxide 530. The concentration of impurities such as hydrogen and water in the insulator 580 is preferably lowered.

The insulator 582 is preferably provided in contact with the top surface of the insulator 580, the top surface of the conductor 560, and the top surface of the insulator 545. When the insulator 582 is deposited by a sputtering method, excess-oxygen regions can be provided in the insulator 545 and the insulator 580. Accordingly, oxygen can be supplied from the excess-oxygen regions to the oxide 530.

A metal oxide including one kind or two or more kinds selected from hafnium, aluminum, gallium, yttrium, zirconium, tungsten, titanium, tantalum, nickel, germanium, magnesium, and the like can be used as the insulator 582, for example.

In particular, aluminum oxide has a high barrier property against impurities such as hydrogen, and even a thin aluminum oxide film having a thickness greater than or equal to 0.5 nm and less than or equal to 3.0 nm can inhibit diffusion of impurities such as hydrogen. Accordingly, aluminum oxide deposited by a sputtering method has a function of an oxygen supply source and can also have a function of an insulator having a barrier property against impurities such as hydrogen.

An insulator 584 functioning as an interlayer film is preferably provided over the insulator 582. As in the insulator 524 or the like, the insulator 584 preferably has a reduced concentration of impurities such as hydrogen and water, for example.

A conductor 540a and a conductor 540b are provided in openings formed in the insulator 584, the insulator 582, the insulator 580, and the insulator 544. In this case, the conductor 540a and the conductor 540b are provided to face each other with the conductor 560 therebetween. The conductor 540a and the conductor 540b each have a structure similar to that of a conductor 546 described later.

An insulator 586 is provided over the insulator 584.

The insulating material having a barrier property against oxygen, hydrogen, and the like is preferably used as the insulator 586. As the insulator 586, a material similar to that of the insulator 324, the insulator 514, or the like can be used, for example.

An insulator 588 is provided over the insulator 586.

When a material with a relatively low dielectric constant is used for the insulator 588, parasitic capacitance between wirings can be reduced, for example. As the insulator 588, a material similar to that of the insulator 320, the insulator 512, the insulator 516, or the like can be used, for example.

The conductor 546 and the like are embedded in the insulator 522, the insulator 524, the insulator 544, the insulator 580, the insulator 582, the insulator 584, and the insulator 586, for example. A conductor 548 and the like are embedded in the insulator 588, for example.

Each of the conductor 546 and the conductor 548 has a function of a plug or a wiring. As each of the conductor 546 and the conductor 548, a material similar to that of the conductor 328 and the conductor 330, the conductor 518, or the like can be used, for example.

Note that after the transistor 500 is formed, an opening may be formed to surround the transistor 500 and an insulator having a high barrier property against hydrogen and water may be formed to cover the opening. Surrounding the transistor 500 by the insulator having a high barrier property can prevent entry of hydrogen and water from the outside. Alternatively, a plurality of the transistors 500 may be collectively surrounded by the insulator having a high barrier property against hydrogen or water. When an opening is formed to surround the transistor 500, for example, an opening reaching the insulator 522 or the insulator 514 may be formed, and the insulator having a high barrier property may be formed to be in contact with the insulator 522 or the insulator 514. In this way, these formation steps can also serve as some of the manufacturing steps of the transistor 500. As the insulator having a high barrier property against hydrogen and water, a material similar to that of the insulator 522, the insulator 514, or the like may be used, for example.

Note that the transistor 500 illustrated in FIG. 13 and FIG. 14A to FIG. 14C is an example and the structure is not limited thereto.

Although not illustrated in FIG. 13, a CMOS circuit can also be formed by electrically connecting the gate of the p-channel transistor 550 and the gate of the n-channel transistor 500. In the case of such a structure, single crystal silicon can be used for the substrate 311 including the semiconductor region 313 of the p-channel transistor 550, and an oxide semiconductor can be used for a semiconductor film including the channel formation region of the n-channel transistor 500 (corresponding to the oxide 530), for example. With this structure, a semiconductor device that operates at high speed and has high reliability can be achieved.

### [Transistor 600 and Capacitor 690]

Next, the structures of the transistor 600 and the capacitor 690 that are provided over the insulator 588 are described with reference to FIG. 13 and FIG. 15A to FIG. 15C.

As illustrated in FIG. 13, an insulator 614 and an insulator 616 are sequentially stacked over the insulator 588.

An insulator having a barrier property against oxygen, hydrogen, or the like is preferably used for any of the insulator 614 and the insulator 616.

For example, for the insulator 614, it is preferable to use an insulator having a barrier property that prevents diffusion of impurities such as hydrogen from a region where the transistor 500 is provided, or the like into a region where the transistor 600 is provided. For the insulator 614, a material similar to that of the insulator 324, the insulator 514, or the like can be used, for example.

Furthermore, when a material with a comparatively low dielectric constant is used for the insulator 616, parasitic capacitance between wirings can be reduced. For the insulator 616, a material similar to that for the insulator 326, the insulator 516, or the like can be used, for example.

A conductor 618 and the like are embedded in the insulator 614, for example. A conductor 610 and the like are embedded in the insulator 616, for example.

Each of the conductor 618 and the conductor 610 has a function of a plug or a wiring. For each of the conductor 618 and the conductor 610, a material similar to that for the conductor 328 and the conductor 330, the conductor 518, or the like, for example.

FIG. 15A to FIG. 15C illustrate the insulator 614, the conductor 610 over the insulator 614, the transistor 600 and the capacitor 690 over the conductor 610, an insulator 620 over the conductor 610, an insulator 640 over the insulator 620, and an insulator 678 over the transistor 600 and the capacitor 690. The insulator 614, the insulator 620, the insulator 640, and the insulator 678 function as interlayer films. The conductor 610 functions as a wiring.

As illustrated in FIG. 15A to FIG. 15C, the transistor 600 is provided to overlap with the capacitor 690. An opening 648 where part of the structure of the transistor 600 is provided includes a region overlapping with an opening 628 where part of the structure of the capacitor 690 is provided. In particular, a conductor 630 has a function of one of a source electrode and a drain electrode of the transistor 600 and a function of one of a pair of electrodes of the capacitor 690; thus, the transistor 600 and the capacitor 690 share part of the structure. With such a structure, the transistor 600 and the capacitor 690 can be provided without a significant increase in the occupied area in the top view.

### [Capacitor 690]

The capacitor 690 includes a conductor 634 over the conductor 610, an insulator 632 over the conductor 634, and the conductor 630 over the insulator 632. The conductor 630 functions as one of a pair of electrodes (sometimes referred to as an upper electrode), the conductor 634 functions as the other of the pair of electrodes (sometimes referred to as a lower electrode), and the insulator 632 functions as a dielectric. That is, the capacitor 690 forms a MIM (Metal-Insulator-Metal) capacitor.

As illustrated in FIG. 15B and FIG. 15C, the opening 628 reaching the conductor 610 is provided in the insulator 620. At least part of the conductor 634 is placed in the opening 628. The conductor 634 includes a region in contact with the top surface of the conductor 610 in the opening 628, a region in contact with the side surface of the insulator 620 in the opening 628, and a region in contact with at least part of the top surface of the insulator 620. The insulator 632 is placed such that at least part of the insulator 632 is positioned in the opening 628. The conductor 630 is placed so that at least part of the conductor 630 is positioned in the opening 628. The conductor 630 is preferably provided to fill the opening 628 as illustrated in FIG. 15B and FIG. 15C.

The capacitor 690 has a structure in which the upper electrode and the lower electrode face each other with the dielectric therebetween on the side surface as well as on the bottom portion of the opening 628; thus, the electrostatic capacitance per unit area can be increased. Thus, the deeper the opening 628 is, the larger the electrostatic capacitance of the capacitor 690 can be.

The side surface of the opening 628 (sometimes referred to as the side surface of the insulator 620 in the opening 628) is preferably perpendicular to the top surface of the conductor 610. In other words, the insulator 620 has the opening 628 provided to extend in the direction perpendicular to the top surface of the conductor 610. At this time, the opening 628 has a cylindrical shape.

Although this embodiment describes an example in which the opening 628 is circular in the top view, one embodiment of the present invention is not limited thereto. For example, the opening 628 in the top view may have an almost circular shape such as an elliptical shape, a polygonal shape such as a quadrangular shape, or a polygonal shape with rounded corners such as a quadrangular shape with rounded corners. In that case, the maximum width of the opening 628 can be calculated as appropriate in accordance with the top-view shape of the uppermost portion of the opening 628.

For example, in the case where the opening 628 is quadrangular in the top view, the maximum width of the opening 628 may be the length of a diagonal line of the quadrangle. Alternatively, for example, in the case where the opening 628 has an almost circular shape such as an elliptical shape, a polygonal shape, or a polygonal shape with rounded corners in the top view, the maximum width of the opening 628 may be the maximum width of the shape of the opening 628 in the top view.

Portions of the conductor 634, the insulator 632, and the conductor 630 that are placed in the opening 628 reflect the shape of the opening 628. Thus, the conductor 634 is provided along the opening 628, the insulator 632 is provided to cover the conductor 634, and the conductor 630 is provided to fill a depressed portion of the insulator 632 that reflects the shape of the opening 628.

That is, part of the dielectric (corresponding to the insulator 632) of the capacitor 690 is provided along the side surface of the opening 628. That is, part of the dielectric of the capacitor 690 is provided in the direction perpendicular to the top surface of the conductor 610. In other words, a surface where the upper electrode and the dielectric of the capacitor 690 are in contact with each other and a surface where the lower electrode and the dielectric of the capacitor 690 are in contact with each other each include a component in the direction perpendicular to the top surface of the conductor 610.

Although the opening 628 is provided such that the side surface of the opening 628 is perpendicular to the top surface of the conductor 610 in FIG. 15B and FIG. 15C, one embodiment of the present invention is not limited thereto. The side surface of the opening 628 may have a tapered shape, for example.

Note that in this specification and the like, a tapered shape refers to a shape in which at least part of a side surface of a structure is inclined with respect to a substrate surface. An angle formed between an inclined side surface and a substrate surface is referred to as a taper angle. Specifically, in this specification and the like, a tapered shape having a taper angle greater than 0° and less than 90° may be referred to as a forward tapered shape, and a tapered shape having a taper angle greater than 90° and less than 180° may be referred to as an inverse tapered shape.

The conductor 634 and the insulator 632 are provided to be stacked along the side surface of the opening 628 and the top surface of the conductor 610. The conductor 630 is provided over the insulator 632 to fill the opening 628. In this specification and the like, the capacitor 690 having such a structure is sometimes referred to as a trench-type capacitor, a trench capacitor, a deep-trench stacked capacitor, or the like.

The insulator 640 is placed over the capacitor 690. That is, the insulator 640 is placed above the conductor 634, the insulator 632, and the conductor 630. In other words, the conductor 630 is placed below the insulator 640.

The conductor 610 is provided below the conductor 634. The conductor 634 includes a region in contact with the conductor 610.

The conductor 610 is provided over the insulator 614. The conductor 610 can be provided in a planar shape, for example.

As the conductor 610, a conductive material having high conductivity is preferably used. Note that the conductor 610 may have a single-layer structure or a structure in which different materials are stacked. As the conductor 610, any of the above-described materials that can be used as the conductor 503 or the conductor 560 may be used, for example. For example, tungsten can be used.

It is preferable to use, for the conductor 634, a single layer or stacked layers of a conductive material that is not easily oxidized, a conductive material having a function of inhibiting diffusion of oxygen, or the like. Thus, in the case where an oxide insulator is used as the insulator 632, oxidation of the conductor 634 by the insulator 632 can be inhibited. In the case where an oxide insulator is used as the insulator 620, the conductor 634 can be inhibited from being oxidized by the insulator 620.

As the conductor 634, a material that can be used as the conductor 503 or the conductor 560, which are described above, may be used, for example. For example, titanium nitride, indium tin oxide to which silicon is added, or the like may be used. For example, a structure in which titanium nitride is stacked over tungsten may be used. For another example, a structure in which tungsten is stacked over first titanium nitride and second titanium nitride is stacked over the tungsten may be used.

The insulator 632 is provided over the conductor 634. The insulator 632 is provided in contact with the top surface and the side surface of the conductor 634. That is, the insulator 632 preferably covers the side end portion of the conductor 634. This can prevent a short circuit between the conductor 634 and the conductor 630.

As illustrated in FIG. 15B and FIG. 15C, the insulator 632 may be provided to extend and be in contact with the top surface of the insulator 620.

The side end portion of the insulator 632 and the side end portion of the conductor 634 may be aligned with each other. With such a structure, the insulator 632 and the conductor 634 can be formed using the same mask, so that the manufacturing process can be simplified.

As the insulator 632, a material with a high relative permittivity, what is called a high-k material, is preferably used. Using a high-k material as the insulator 632 allows the insulator 632 to be thick enough to inhibit a gate leakage current and the capacitor 690 to have a sufficiently high electrostatic capacitance.

As the insulator of high dielectric constant material, an oxide, an oxynitride, a nitride oxide, or a nitride including one or more kinds of metal element selected from aluminum, hafnium, zirconium, gallium, and the like can be used, for example. These materials may include silicon. Stacked insulators formed of any of these materials can also be used.

As the insulator of a high permittivity material, aluminum oxide, hafnium oxide, zirconium oxide, an oxide including aluminum and hafnium, an oxynitride including aluminum and hafnium, an oxide including silicon and hafnium, an oxynitride including silicon and hafnium, an oxide including silicon and zirconium, an oxynitride including silicon and zirconium, an oxide including hafnium and zirconium, an oxynitride including hafnium and zirconium, or the like can be used, for example.

Stacked insulators formed of any of the above materials can also be used. In that case, a structure in which a high dielectric constant material and a material having a higher dielectric strength than the high dielectric constant material are stacked is preferably used.

For example, as the insulator, an insulator in which zirconium oxide, aluminum oxide, and zirconium oxide are stacked in this order can be used, for example. For another example, an insulator in which zirconium oxide, aluminum oxide, zirconium oxide, and aluminum oxide are stacked in this order can be used. Alternatively, an insulator in which hafnium zirconium oxide, aluminum oxide, hafnium zirconium oxide, and aluminum oxide are stacked in this order can be used, for example. The use of stacked insulators with relatively high dielectric strength, such as aluminum oxide, as the insulator can increase the dielectric strength and inhibit electrostatic breakdown of the capacitor including the insulator.

The conductor 630 is provided in contact with part of the top surface of the insulator 632. A side end portion of the conductor 630 is preferably positioned inward from the side end portion of the conductor 634 in both the X direction and the Y direction. In the structure in which the insulator 632 covers the side end portion of the conductor 634, the side end portion of the conductor 630 may be positioned outward from the side end portion of the conductor 634.

A single layer or stacked layers of a conductive material can be used as the conductor 630. For example, a conductive material that is not easily oxidized, a conductive material having a function of inhibiting diffusion of oxygen, or the like is preferably used for the conductor 630.

As the conductor 630, a material that can be used as the conductor 503, the conductor 560, or the conductor 542, which are described above, may be used, for example. For example, titanium nitride, tantalum nitride, or the like can be used.

The insulator 620, which functions as an interlayer film, preferably has a low relative permittivity. When a material with low relative permittivity is used for an interlayer film, parasitic capacitance generated between wirings can be reduced. As the insulator 620, a single layer or stacked layers of an insulator including a material with a low relative permittivity can be used.

As the insulator 620, any of the above-described materials that can be used for the insulator 516 may be used, for example. For example, silicon oxide or silicon oxynitride, which is thermally stable, is preferably used.

### [Transistor 600]

The transistor 600 includes the conductor 630, a conductor 660 over the insulator 640, an oxide 650, an insulator 672 over the oxide 650, and a conductor 670 over the insulator 672. The oxide 650 functions as a semiconductor film including a channel formation region, the conductor 670 functions as a gate electrode, the insulator 672 functions as a gate insulating film, the conductor 630 functions as one of a source electrode and a drain electrode, and the conductor 660 functions as the other of the source electrode and the drain electrode.

In the transistor 600, a metal oxide functioning as an oxide semiconductor is used as the oxide 650 including a channel formation region. As the oxide 650, a metal oxide that can be used as the above-described oxide 530 may be used, for example.

As illustrated in FIG. 15B and FIG. 15C, the opening 648 reaching the conductor 630 is provided in the insulator 640 and the conductor 660. At least part of the oxide 650 is placed in the opening 648. Note that the oxide 650 includes a region in contact with the top surface of the conductor 630 in the opening 648, a region in contact with the side surface of the conductor 660 in the opening 648, and a region in contact with at least part of the top surface of the conductor 660. The insulator 672 is placed such that at least part of the insulator 672 is positioned in the opening 648. The conductor 670 is placed such that at least part of the conductor 670 is positioned in the opening 648. In addition, the conductor 670 is preferably provided to fill the opening 648 as illustrated in FIG. 15B and FIG. 15C.

For example, the conductor 630 may have a structure in which tantalum nitride is stacked over titanium nitride. In that case, the titanium nitride may be in contact with the insulator 632 and the tantalum nitride may be in contact with the oxide 650. Such a structure can inhibit the conductor 630 from being excessively oxidized by the oxide 650. In the case where an oxide insulator is used as the insulator 632, such a structure can inhibit the conductor 630 from being excessively oxidized by the insulator 632. Note that the conductor 630 may have a structure in which tungsten is stacked over titanium nitride, for example.

The conductor 630 includes a region in contact with the oxide 650 and thus is preferably formed using a conductive material including oxygen. With such a structure, the conductivity can be maintained even when the conductor 630 absorbs oxygen. Also in the case where a material including oxygen is used as the insulator 632, the conductivity of the conductor 630 can be maintained.

As the conductor 630, a single layer or stacked layers of indium tin oxide (also referred to as ITO), indium tin oxide to which silicon is added (also referred to as ITSO), indium zinc oxide (also referred to as IZO (registered trademark)), or the like can be used, for example.

The oxide 650 includes the region in contact with the side surface of the conductor 660 in the opening 648 and the region in contact with part of the top surface of the conductor 660. When the oxide 650 is in contact with not only the side surface but also the top surface of the conductor 660 in this manner, the area where the oxide 650 and the conductor 660 are in contact with each other can be increased.

FIG. 15C illustrates a structure in which the side end portion of the oxide 650 is positioned inward from the side end portion of the conductor 660. Note that one embodiment of the present invention is not limited thereto. For example, the side end portion of the oxide 650 and the side end portion of the conductor 660 may be aligned with each other in the Y direction. Alternatively, the side end portion of the oxide 650 may be positioned outward from the side end portion of the conductor 660.

As illustrated in FIG. 15A to FIG. 15C, it is preferable that the conductor 670 be provided to extend in the Y direction and the conductor 660 be provided to extend in the X direction. With such a structure, the conductor 670 and the conductor 660 are provided to intersect with each other. Although the conductor 610 is provided in a planar shape in FIG. 15A, one embodiment of the present invention is not limited thereto. For example, the conductor 610 may be provided parallel to the conductor 670 or may be provided parallel to the conductor 660.

The side surface of the opening 648 (sometimes referred to as the side surface of the insulator 640 in the opening 648) is preferably perpendicular to the top surface of the conductor 610. In other words, the insulator 640 has the opening 648 provided to extend in the direction perpendicular to the top surface of the conductor 610. In that case, the opening 648 has a cylindrical shape.

Although this embodiment describes an example in which the opening 648 is circular in a plan view, one embodiment of the present invention is not limited thereto. For example, the opening 648 in a plan view may have an almost circular shape such as an elliptical shape, a polygonal shape such as a quadrangular shape, or a polygonal shape with rounded corners such as a quadrangular shape with rounded corners. In that case, the maximum width of the opening 648 can be calculated as appropriate in accordance with the top-view shape of the uppermost portion of the opening 648.

In the case where the opening 648 is quadrangular in the top view, for example, the maximum width of the opening 648 may be the length of a diagonal line of the quadrangle. Alternatively, for example, in the case where the opening 648 has an almost circular shape such as an elliptical shape, a polygonal shape, or a polygonal shape with rounded corners in the top view, the maximum width of the opening 648 may be the maximum width of the shape of the opening 648 in the top view.

Portions of the oxide 650, the insulator 672, and the conductor 670 that are placed in the opening 648 reflect the shape of the opening 648. Thus, the oxide 650 is provided along the opening 648, the insulator 672 is provided to cover the oxide 650, and the conductor 670 is provided to fill a depressed portion of the insulator 672 that reflects the shape of the opening 648.

That is, part of the semiconductor film (corresponding to the oxide 650) including a channel formation region of the transistor 600 is provided along the side surface of the opening 648. That is, part of the semiconductor film is provided in the direction perpendicular to the top surface of the conductor 610. In other words, the channel length direction of the transistor 600 includes a component in the direction perpendicular to the top surface of the conductor 610. That is, the channel length direction includes a component in the vertical direction (which is the Z direction in FIG. 15A to FIG. 15C and is also referred to as the height direction or the direction perpendicular to a formation surface). In other words, the source electrode and the drain electrode are positioned at different levels, and a drain current flows in the vertical direction. Thus, the transistor of one embodiment of the present invention is a transistor whose channel length direction includes a component in the vertical direction (i.e., a transistor in which a drain current flows in the vertical direction), and can be referred to as a VFET (Vertical Field Effect Transistor), a vertical transistor, a transistor of a vertical type, a vertical channel transistor, a transistor of a vertical channel type, or the like, for example.

Here, as the conductor 660, a material that can be used as the conductor 630 can be used, for example. As the conductor 670, a material that can be used as the conductor 630 may be used, for example. As the insulator 672, a material that can be used as the insulator 522, the insulator 524, or the insulator 545, which are described above, may be used, for example. As the insulator 640, a material that can be used for the insulator 620 may be used, for example. As the insulator 678, a material that can be used for the insulator 514 or the insulator 614, which are described above, may be used, for example.

Although the opening 648 is provided such that the side surface of the opening 648 is perpendicular to the top surface of the conductor 610 in FIG. 15B and FIG. 15C, one embodiment of the present invention is not limited thereto. For example, the side surface of the opening 648 may have a tapered shape.

Although the oxide 650 being a single layer is illustrated in FIG. 15B and FIG. 15C, one embodiment of the present invention is not limited thereto. The oxide 650 may have a stacked-layer structure of a plurality of oxide layers with different chemical compositions.

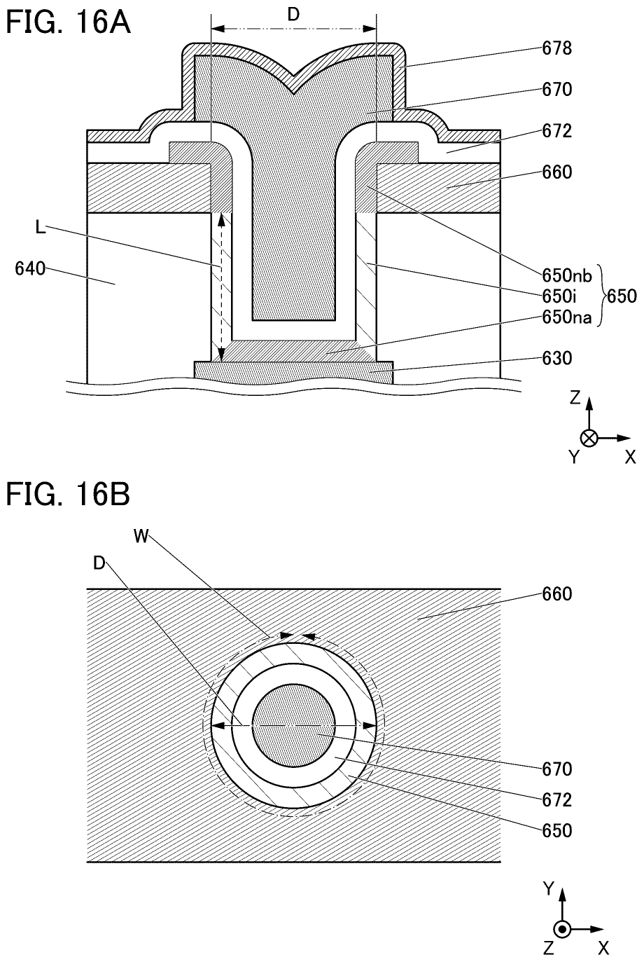

FIG. 16A is an enlarged view of the oxide 650 and its vicinity in FIG. 15B. FIG. 16B is a cross-sectional view taken along the XY plane including the conductor 660.

As illustrated in FIG. 16A, the oxide 650 includes a region 650i, and a region 650na and a region 650nb provided such that the region 650i is sandwiched therebetween.

The region 650na is a region in contact with the conductor 630 in the oxide 650. At least part of the region 650na functions as one of the source region and the drain region of the transistor 600. The region 650nb is a region of the oxide 650 that is in contact with the conductor 660. At least part of the region 650nb functions as the other of the source region and the drain region of the transistor 600. As illustrated in FIG. 16B, the conductor 660 is in contact with all the outer circumference of the oxide 650. Thus, the other of the source region and the drain region of the transistor 600 can be formed in all the outer circumference of a portion of the oxide 650 that is formed in the same layer as the conductor 660.

The region 650i is a region of the oxide 650 between the region 650na and the region 650nb. At least part of the region 650i functions as the channel formation region of the transistor 600. In other words, the channel formation region of the transistor 600 is positioned in a region of the oxide 650 that is between the conductor 630 and the conductor 660. It can also be said that the channel formation region of the transistor 600 is positioned in a region of the oxide 650 that is in contact with the insulator 640 or a region in the vicinity thereof.

The channel length of the transistor 600 is a distance between the source region and the drain region. In other words, the channel length of the transistor 600 is determined by the thickness of the insulator 640 over the conductor 630. In FIG. 16A, the channel length L of the transistor 600 is indicated by a dashed double-headed arrow. In a cross-sectional view, the channel length L is a distance between an end portion of a region where the oxide 650 and the conductor 630 are in contact with each other and an end portion of a region where the oxide 650 and the conductor 660 are in contact with each other. In other words, the channel length L corresponds to the length of the side surface of the insulator 640 on the opening 648 side in a cross-sectional view.

Here, in a planar transistor, the channel length is determined by the light exposure limit of photolithography; however, in one embodiment of the present invention, the channel length can be determined by the thickness of the insulator 640. Thus, the transistor 600 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 600 can have a higher on-state current and improved frequency characteristics.

As described above, the channel formation region, the source region, and the drain region can be formed in the opening 648. Thus, the area occupied by the transistor 600 can be smaller than the area occupied by a planar transistor in which a channel formation region, a source region, and a drain region are provided separately on the XY plane.

Furthermore, in the XY plane including the channel formation region of the oxide 650, as in FIG. 16B, the oxide 650, the insulator 672, and the conductor 670 are provided concentrically. Thus, the side surface of the conductor 670 provided at the center faces the side surface of the oxide 650 with the insulator 672 therebetween. That is, in the top view, all the perimeter of the oxide 650 serves as the channel formation region. In this case, for example, the channel width of the transistor 600 is determined by the length of the outer circumference of the oxide 650. In other words, it can be said that the channel width of the transistor 600 is determined by the maximum width of the opening 648 (the maximum diameter when the opening 648 is circular in the top view). In FIG. 16A and FIG. 16B, a maximum width D of the opening 648 is indicated by a dashed double-dotted double-headed arrow. In FIG. 16B, the channel width W of the transistor 600 is indicated by a dashed-dotted double-headed arrow. When the maximum width D of the opening 648 is increased, the channel width per unit area can be increased, so that the on-state current can be increased.

In the case where the opening 648 is formed by a photolithography method, the maximum width D of the opening 648 is set by the light exposure limit of photolithography. The maximum width D of the opening 648 is determined by the thicknesses of the oxide 650, the insulator 672, and the conductor 670 provided in the opening 648. The maximum width D of the opening 648 is preferably greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm, for example. Note that in the case where the opening 648 is circular in the top view, the maximum width D of the opening 648 corresponds to the diameter of the opening 648, and the channel width W can be calculated to be “D×π.”

The channel length L of the transistor 600 of one embodiment of the present invention is preferably shorter than at least the channel width W of the transistor 600. The channel length L of the transistor 600 of one embodiment of the present invention is greater than or equal to 0.1 times and less than or equal to 0.99 times, preferably greater than or equal to 0.5 times and less than or equal to 0.8 times the channel width W of the transistor 600. This structure enables a transistor with favorable electrical characteristics and high reliability.

In the case where the opening 648 is formed to be circular in a top view, the oxide 650, the insulator 672, and the conductor 670 are provided concentrically. This makes the distance between the conductor 670 and the oxide 650 uniform, so that a gate electric field can be uniformly applied to the oxide 650.

Note that the transistor 600 and the capacitor 690 illustrated in FIG. 15A to FIG. 15C are examples and the structures are not limited thereto.

### <Constituent Materials of Semiconductor Device>

Constituent materials that can be used for a semiconductor device including a transistor and a capacitor are not limited to those in the above-described structure examples. In addition to the above-described constituent materials, any of the following constituent materials can be used as appropriate in one embodiment of the present invention.

### [Substrate]

Examples of a substrate that can be used for the semiconductor device of one embodiment of the present invention include a glass substrate, a quartz substrate, a sapphire substrate, a ceramic substrate, a metal substrate (e.g., a stainless steel substrate, a substrate including stainless steel foil, a tungsten substrate, and a substrate including tungsten foil), a semiconductor substrate (e.g., a single crystal semiconductor substrate, a polycrystalline semiconductor substrate, and a compound semiconductor substrate), and an SOI (Silicon on Insulator) substrate. Alternatively, a plastic substrate having heat resistance may be used as the substrate. Examples of the glass substrate include barium borosilicate glass, aluminosilicate glass, aluminoborosilicate glass, and soda lime glass. Alternatively, crystallized glass or the like may be used for the glass substrate, for example.

Alternatively, a flexible substrate; an attachment film; paper or a base film including a fibrous material; or the like can be used as the substrate, for example. Examples of the flexible substrate, the attachment film, the base material film, and the like include plastics typified by polyethylene terephthalate (PET), polyethylene naphthalate (PEN), polyether sulfone (PES), and polytetrafluoroethylene (PTFE). Another example is a synthetic resin such as acrylic. Other examples include polypropylene, polyester, polyvinyl fluoride, and polyvinyl chloride. Other examples include polyamide, polyimide, an aramid resin, an epoxy resin, an inorganic vapor deposition film, and paper. Specifically, for example, the use of a semiconductor substrate, a single crystal substrate, an SOI substrate, or the like for the manufacture of transistors enables the manufacture of small-sized transistors with a small variation in characteristics, size, shape, or the like and with a high current capability. When a circuit is formed with such transistors, lower power consumption of the circuit or higher integration of the circuit can be achieved.

A flexible substrate may be used as the substrate, and one or more of a transistor, a resistor, a capacitor, and the like may be formed directly over the flexible substrate, for example. Alternatively, a separation layer may be provided between the substrate and one or more of the transistor, the resistor, the capacitor, and the like. After part or the whole of a semiconductor device is completed over the separation layer, the separation layer can be used for separation from the substrate and transfer to another substrate. In such a case, for example, one or more of the transistor, the resistor, the capacitor, and the like can be transferred to a substrate having low heat resistance, a flexible substrate, or the like. As the above-described separation layer, a stacked-layer structure of a tungsten film and a silicon oxide film that are inorganic films, a structure in which an organic resin film of polyimide or the like is formed over a substrate, a silicon film including hydrogen, or the like can be used, for example.

That is, a semiconductor device may be formed over one substrate and then transferred to another substrate. Examples of a substrate to which a semiconductor device is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), or the like), a leather substrate, and a rubber substrate. With the use of any of these substrates, a flexible semiconductor device or a highly durable semiconductor device can be manufactured. Provision of heat resistance to the semiconductor device can be achieved. A reduction in weight or thickness of the semiconductor device can be achieved.

Providing a semiconductor device over a flexible substrate can suppress an increase in weight and can produce a non-breakable semiconductor device.

### [Ferroelectric]

A material that can have ferroelectricity may be used as an insulator functioning as a dielectric (insulator 632 or the like) that can be used for the semiconductor device of one embodiment of the present invention. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like, for example) is added to hafnium oxide. Note that the atomic ratio of hafnium to the element J1 can be set as appropriate. For example, the atomic ratio of hafnium to the element J1 may be 1:1 or in the neighborhood thereof. Examples of the material that can have ferroelectricity also include a material in which an element J2 (the element J2 here is one or more selected from hafnium, silicon, aluminum, gadolinium, yttrium, lanthanum, strontium, and the like, for example) is added to zirconium oxide. Note that the atomic ratio of zirconium to the element J2 can be set as appropriate. For example, the atomic ratio of zirconium to the element J2 may be 1:1 or in the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used, for example.

Examples of the material that can have ferroelectricity also include a metal nitride including an element M1, an element M2, and nitrogen. Here, the element M1 is one or more selected from aluminum, gallium, indium, and the like, for example. The element M2 is one or more selected from boron, scandium, yttrium, lanthanum, cerium, neodymium, europium, titanium, zirconium, hafnium, vanadium, niobium, tantalum, chromium, and the like, for example. Note that the ratio of the number of atoms of the element M1 to the number of atoms of the element M2 can be set as appropriate. A metal nitride including the element M1 and nitrogen has ferroelectricity in some cases even though the metal nitride does not include the element M2. Examples of the material that can have ferroelectricity also include a material in which an element M3 is added to the above metal nitride. Here, the element M3 is one or more selected from magnesium, calcium, strontium, zinc, cadmium, and the like, for example. Note that the atomic ratio between the element M1, the element M2, and the element M3 can be set as appropriate.

Examples of the material that can have ferroelectricity also include perovskite-type oxynitrides such as SrTaO₂N and BaTaO₂N and GaFeO₃ with a κ-alumina-type structure.

Although metal oxides and metal nitrides are given as examples in the above description, there is not limitation thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound including a plurality of materials selected from the above-listed materials can be used, for example. Alternatively, the insulator including the material that can have ferroelectricity can have a stacked-layer structure of a plurality of materials selected from the above-listed materials. The above-listed materials and the like may change their crystal structures (characteristics) according to a variety of processes and the like as well as film formation conditions. Thus, in this specification and the like, not only a material that exhibits ferroelectricity but also a material that can have ferroelectricity may be referred to as a ferroelectric.

A metal oxide including one or both of hafnium and zirconium is preferable because the metal oxide can have ferroelectricity even when being processed into a thin film of several nanometers. Here, the thickness of the insulator including the material that can have ferroelectricity can be less than or equal to 100 nm, preferably less than or equal to 50 nm, further preferably less than or equal to 20 nm, still further preferably less than or equal to 10 nm (typically, greater than or equal to 2 nm and less than or equal to 9 nm). The thickness of the insulator is preferably greater than or equal to 8 nm and less than or equal to 12 nm, for example. When the insulator functioning as a dielectric of a capacitor is a ferroelectric layer that can be thin, for example, the capacitor can be combined with a semiconductor element such as a miniaturized transistor to form a semiconductor device. Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

A metal oxide including one or both of hafnium and zirconium is preferable because the metal oxide can have ferroelectricity even with a minute area. For example, a ferroelectric layer can have ferroelectricity even with an area (occupied area) in a top view of less than or equal to 100 μm², less than or equal to 10 μm², less than or equal to 1 μm², or less than or equal to 0.1 μm². Furthermore, even with an area less than or equal to 10000 nm² or less than or equal to 1000 nm², a ferroelectric layer has ferroelectricity in some cases. With a small-area ferroelectric layer, the area occupied by the capacitor can be reduced.

A ferroelectric is an insulator and has a property of causing internal polarization by application of an electric field from the outside and maintaining the polarization even after the electric field is made zero. Thus, with the use of a capacitor that uses this material as a dielectric (hereinafter, the capacitor may be referred to as a ferroelectric capacitor), a nonvolatile memory element can be formed. A nonvolatile memory element that includes a ferroelectric capacitor is sometimes referred to as an FeRAM (Ferroelectric Random Access Memory) or a ferroelectric memory, for example. A ferroelectric memory includes a transistor and a ferroelectric capacitor, and one of a source and a drain of the transistor is electrically connected to one terminal of the ferroelectric capacitor, for example.

Note that ferroelectricity is exhibited by displacement of oxygen or nitrogen of a crystal included in a ferroelectric layer due to an electric field applied from the outside. Ferroelectricity is presumably exhibited depending on the crystal structure of a crystal included in a ferroelectric layer. Thus, in order for the insulator including the material that can have ferroelectricity to exhibit ferroelectricity, the insulator needs to include a crystal. It is particularly preferable that the insulator include a crystal having an orthorhombic crystal structure to exhibit ferroelectricity. Incidentally, a crystal included in the insulator may have one or more selected from cubic, tetragonal, orthorhombic, monoclinic, hexagonal crystal structures. The insulator may have an amorphous structure. In that case, the insulator may have a composite structure including an amorphous structure and a crystal structure.

### Layout Example of Semiconductor Device

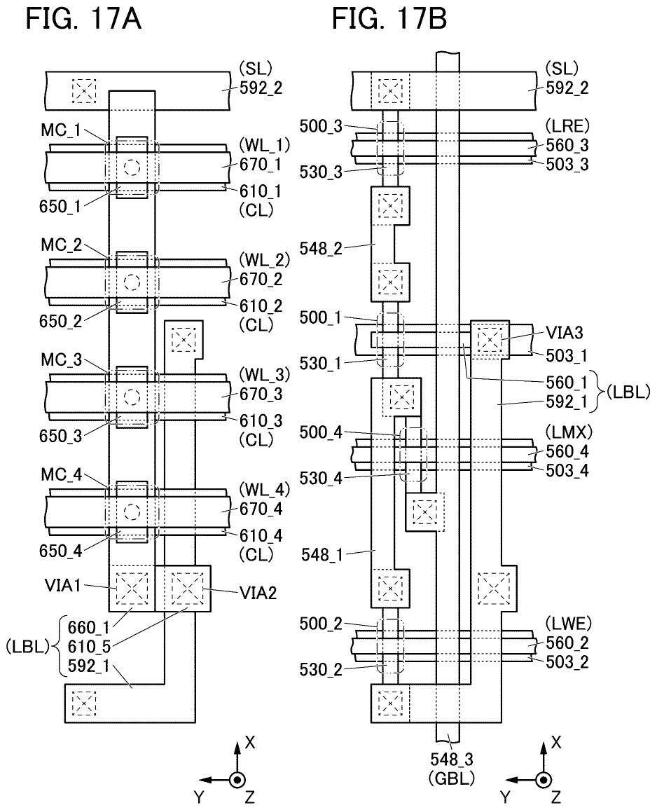

FIG. 17A and FIG. 17B are each a top view illustrating a layout example of the semiconductor device of one embodiment of the present invention.

FIG. 17A illustrates, as an example, a memory cell MC_1, a memory cell MC_2, a memory cell MC_3, a memory cell MC_4, and conductors connecting them. As each of the memory cell MC_1, the memory cell MC_2, the memory cell MC_3, and the memory cell MC_4, the above-described memory cell MC (the transistor 600 and the capacitor 690) can be used.

FIG. 17B illustrates, as an example, a transistor 500_1, a transistor 5002, a transistor 500_3, a transistor 500_4, and conductors that connect them. As each of the transistor 500_1, the transistor 500_2, the transistor 5003, and the transistor 5004, the above-described transistor 500 can be used.

Note that the layout illustrated in FIG. 17A is positioned to overlap with the layout illustrated in FIG. 17B.

As illustrated in FIG. 17A, the transistor 600 included in the memory cell MC_1 includes 5 an oxide 650_1. The memory cell MC_1 is connected to each of a conductor 6701, a conductor 610_1, and a conductor 660_1. The transistor 600 included in the memory cell MC_2 includes an oxide 650_2. The memory cell MC_2 is connected to each of a conductor 6702, a conductor 610_2, and the conductor 660_1. The transistor 600 included in the memory cell MC_3 includes an oxide 650_3. The memory cell MC_3 is connected to each of a conductor 6703, a conductor 610_3, and the conductor 660_1. The transistor 600 included in the memory cell MC_4 includes an oxide 650_4. The memory cell MC_4 is connected to each of a conductor 6704, a conductor 610_4, and the conductor 660_1. The conductor 660_1 is connected to a conductor 610_5 through a via VIA1 and is further connected to a conductor 5921 through a via VIA2.

The conductor 6701, the conductor 6702, the conductor 6703, and the conductor 670_4 are provided to extend in the Y direction and are parallel to each other. The conductor 610_1, the conductor 6102, the conductor 6103, and the conductor 610_4 are provided to extend in the Y direction and are parallel to each other. The conductor 660_1 is provided to extend in the X direction and is perpendicular to the conductor 6701, the conductor 6101, and the like.

Here, each of the oxide 6501, the oxide 6502, the oxide 650_3, and the oxide 650_4 correspond to the above-described oxide 650. Each of the conductor 670_1, the conductor 670_2, the conductor 6703, and the conductor 670_4 correspond to the above-described conductor 670. Each of the conductor 6101, the conductor 6102, the conductor 6103, the conductor 610_4, and the conductor 610_5 correspond to the above-described conductor 610. The conductor 660_1 corresponds to the above-described conductor 660. The via VIA1 corresponds to the above-described via 608 and via 698.

As illustrated in FIG. 17B, the transistor 500_1 includes an oxide 530_1. In the transistor 500_1, a gate is connected to a conductor 560_1, a back gate is connected to a conductor 503_1, one of a source and a drain is connected to a conductor 548_1, and the other of the source and the drain is connected to a conductor 548_2. The transistor 500_2 includes an oxide 530_2. In the transistor 500_2, a gate is connected to a conductor 5602, a back gate is connected to a conductor 503_2, one of a source and a drain is connected to a conductor 5921, and the other of the source and the drain is connected to a conductor 548_1. The transistor 500_3 includes an oxide 530_3. In the transistor 5003, a gate is connected to a conductor 560_3, a back gate is connected to a conductor 5033, one of a source and a drain is connected to a conductor 5482, and the other of the source and the drain is connected to a conductor 592_2. The transistor 500_4 includes an oxide 530_4. In the transistor 500_4, a gate is connected to a conductor 5604, a back gate is connected to a conductor 5034, one of a source and a drain is connected to a conductor 548_1, and the other of the source and the drain is connected to a conductor 548_3. The conductor 560_1 is connected to the conductor 592_1 through a via VIA3.

The conductor 560_1, the conductor 5602, the conductor 5603, and the conductor 560_4 are provided to extend in the Y direction and are parallel to each other. The conductor 503_1, the conductor 5032, the conductor 5033, and the conductor 503_4 are provided to extend in the Y direction and are parallel to each other. The conductor 548_3 is provided to extend in the X direction and is perpendicular to the conductor 560_1, the conductor 503_1, and the like.

Here, each of the oxide 5301, the oxide 5302, the oxide 530_3, and the oxide 530_4 corresponds to the above-described conductor oxide 530. Each of the conductor 5601, the conductor 5602, the conductor 5603, and the conductor 560_4 corresponds to the above-described conductor conductor 560. Each of the conductor 5031, the conductor 5032, the conductor 5033, and the conductor 503_4 corresponds to the above-described conductor 503. Each of the conductor 5481, the conductor 5482, and the conductor 548_3 corresponds to the above-described conductor 548. Each of the conductor 592_1 and the conductor 592_2 corresponds to a wiring layer provided between the conductor 548 and the conductor 610.

Note that each of the memory cell MC_1, the memory cell MC_2, the memory cell MC_3, and the memory cell MC_4 corresponds to the memory cell 111 (the transistor M111 and the capacitor C111) described in Embodiment 1, for example. The transistor 500_1, the transistor 500_2, the transistor 5003, and the transistor 500_4 respectively correspond to, for example, the transistor M121, the transistor M122, the transistor M123, and the transistor M124 included in the primary sensing circuit 112 or the like described in Embodiment 1.

That is, each of the conductor 670_1, the conductor 6702, the conductor 670_3, and the conductor 670_4 corresponds to the wiring WL (the wiring WL_1, the wiring WL_2, the wiring WL_3, and the wiring WL_4). The conductor 6101, the conductor 6102, the conductor 610_3, 5 and the conductor 610_4 correspond to the wiring CL. The conductor 660_1, the conductor 610_5, the conductor 5921, and the conductor 560_1 correspond to the wiring LBL. The conductor 592_2 corresponds to the wiring SL. The conductor 592_2 corresponds to the wiring LWE. The conductor 592_3 corresponds to the wiring LRE. The conductor 592_4 corresponds to the wiring LMX.

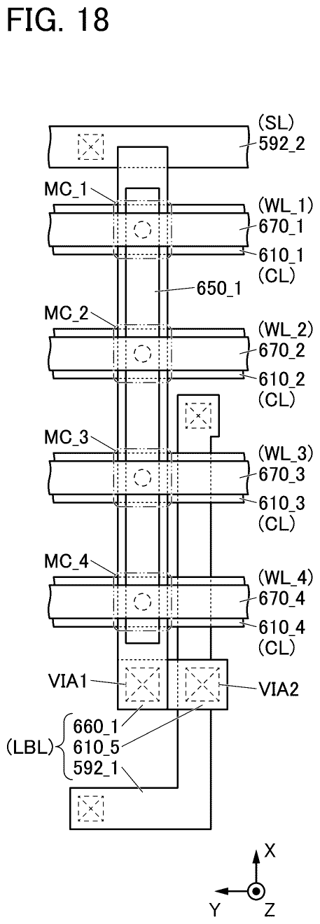

FIG. 18 is a top view illustrating a variation example of the layout illustrated in FIG. 17A. In FIG. 18, one oxide 650_1 is shared by four transistors included in the memory cell MC_1, the memory cell MC_2, the memory cell MC_3, and the memory cell MC_4.

Note that the above-described layout is an example and can be changed as appropriate.

In the top view, for example, the length and the width of each oxide can be changed as appropriate in the top view. The length and the width of each conductor can be changed as appropriate. Each conductors can be folded as appropriate. Furthermore, the conductors can overlap with each other as appropriate.

The semiconductor device according to one embodiment of the present invention is not limited to the semiconductor devices described in this embodiment. At least part of the structure examples, the operation examples, the drawings corresponding thereto, and the like described in this embodiment as an example can be combined as appropriate with the other structure examples, the other operation examples, the other drawings, the other embodiments, and the like described in this specification and the like.

DONE

### EMBODIMENT 3

In this embodiment, a transistor including an oxide semiconductor in a channel formation region (OS transistor) will be described. In the description of the OS transistor, comparison with a transistor including silicon in a channel formation region (also referred to as a Si transistor) is also described simply.

### [OS Transistor]

An oxide semiconductor having a low carrier concentration is preferably used in an OS transistor. For example, the carrier concentration of an oxide semiconductor in the channel formation region is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. In order to reduce the carrier concentration in an oxide semiconductor, the impurity concentration in the oxide semiconductor may be reduced so that the density of defect states in the oxide semiconductor can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

In addition, a highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of the impurity include hydrogen and nitrogen. Note that impurities in an oxide semiconductor refer to, for example, elements other than the main components of an oxide semiconductor. For example, an element with a concentration lower than 0.1 atomic % can be regarded as an impurity.

When impurities or oxygen vacancies are in a channel formation region of the oxide semiconductor included in an OS transistor, electrical characteristics of the OS transistor may vary easily and the reliability thereof may worsen. In some cases, a defect that is an oxygen vacancy into which hydrogen enters (hereinafter sometimes referred to as V_{O}H) is formed in the oxide semiconductor of the OS transistor, which generates an electron serving as a carrier. Formation of V_{O}H in the channel formation region may increase the donor concentration in the channel formation region of the OS transistor. An increase in the donor concentration in the channel formation region of the OS transistor may lead to a variation in threshold voltage. Thus, the oxygen vacancies in the channel formation region of the oxide semiconductor allow the OS transistor to easily have normally-on characteristics (to cause the drain current to flow at a gate voltage of 0 V). Therefore, impurities, oxygen vacancies, and V_{O}H are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current of the transistor (also referred to as Ioff) can be reduced.

In a Si transistor, a short-channel effect (SCE) appears as miniaturization of the transistor proceeds. This hinders miniaturization of a Si transistor. One factor in causing the short-channel effect is a narrow band gap of silicon. By contrast, the OS transistor includes an oxide semiconductor that is a semiconductor material having a wide band gap, and thus can suppress the short-channel effect. In other words, the OS transistor is a transistor in which the short-channel effect does not appear or hardly appears.

The short-channel effect refers to degradation of electrical characteristics that becomes obvious along with miniaturization of a transistor (a decrease in channel length). Specific examples of the short-channel effect include a decrease in threshold voltage, an increase in subthreshold swing value (sometimes referred to as an S value), and an increase in leakage current. Here, the S value means the amount of change in gate voltage in the subthreshold region when the drain voltage is constant and the drain current is changed by one order of magnitude.

The characteristic length is widely used as an indicator of resistance to the short-channel effect. The characteristic length is an indicator of curving of a potential in a channel formation region. The smaller the characteristic length is, the more sharply the potential rises; thus, a smaller characteristic length indicates higher resistance to the short-channel effect.

The OS transistor is an accumulation-type transistor and the Si transistor is an inversion-type transistor. Thus, the OS transistor has a shorter characteristic length between the source region and the channel formation region and a shorter characteristic length between the drain region and the channel formation region than the Si transistor has. Accordingly, the OS transistor has higher resistance to the short-channel effect than the Si transistor. That is, the OS transistor is more suitable than the Si transistor in the case where a short-channel transistor is to be formed.

Even in the case where the carrier concentration in the oxide semiconductor is reduced until the channel formation region becomes an i-type or substantially i-type region, the conduction band minimum of the channel formation region in a short-channel transistor decreases because of the conduction band lowering (CBL) effect; thus, there is a possibility that a difference in energy of the conduction band minimum between the channel formation region and the source region or the drain region is as small as 0.1 eV or more and 0.2 eV or less. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region each become an n⁺-type region in the OS transistor.

The above-described structure enables the OS transistor to have excellent electrical characteristics even when the OS transistors are scaled down or highly integrated. For example, excellent electrical characteristics can be obtained even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Thus, the OS transistor can be used as a short-channel transistor than the Si transistor. Note that the gate length refers to the length of a gate electrode in a direction in which carriers move inside a channel formation region during operation of the transistor and to the width of the bottom surface of the gate electrode in a top view of the transistor.

Miniaturization of the OS transistor can improve the high frequency characteristics of the transistor. Specifically, the cutoff frequency of the transistor can be improved. When the gate length of the OS transistor is within the above-described range, the cutoff frequency of the transistor can be greater than or equal to 50 GHz, preferably greater than or equal to 100 GHz, further preferably greater than or equal to 150 GHz at room temperature, for example.

The above-described comparison of the OS transistor with the Si transistor demonstrates that the OS transistor has an effect superior to the Si transistor, such as a low off-state current and capability of short-channel transistor formation.

The structures, configurations, methods, and the like described in this embodiment can be used in combination as appropriate with the structures, configurations, methods, and the like described in the other embodiments and the like.

### EMBODIMENT 4

In this embodiment, an arithmetic processing device (also referred to as an arithmetic device) of one embodiment of the present invention is described. Note that at least part of the semiconductor device and the memory device described above in Embodiment 1 can be used for the arithmetic processing device described in this embodiment.

### <Arithmetic Device>

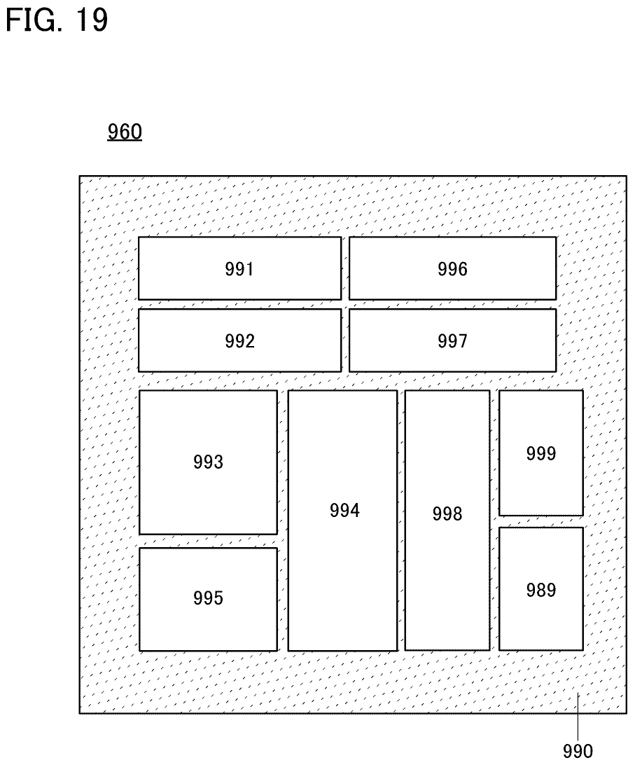

FIG. 19 illustrates a block diagram of an arithmetic device 960. The arithmetic device 960 illustrated in FIG. 19 can be used for a CPU (Central Processing Unit), for example. The arithmetic device 960 can also be used for a processor including a larger number of (several tens to several hundreds of) processor cores capable of parallel processing than a CPU, such as a GPU (Graphics Processing Unit), a TPU (Tensor Processing Unit), and a NPU (Neural Processing Unit).

The arithmetic device 960 illustrated in FIG. 19 includes, over a substrate 990, an ALU 991 (ALU: Arithmetic logic unit, arithmetic circuit), an ALU controller 992, an instruction decoder 993, an interrupt controller 994, a timing controller 995, a register 996, a register controller 997, a bus interface 998, a cache 999 (also referred to as a cache memory), and a cache interface 989. A semiconductor substrate, an SOI substrate, a glass substrate, or the like is used as the substrate 990. A rewritable ROM (Read Only Memory) and a ROM interface may be included. In addition, the cache 999 and the cache interface 989 may be provided in a separate chip.

The cache 999 can exchange data with a main memory provided in a separate chip through the cache interface 989. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array can be stacked over the arithmetic device 960. The memory array can be used as a cache. Here, the cache interface 989 may have a function of supplying data retained in the memory array to the cache 999. Moreover, in this case, the driver circuit is preferably included in part of the cache interface 989.

Note that it is also possible that the cache 999 is not provided and only the memory array is used as a cache.

The arithmetic device 960 illustrated in FIG. 19 is only an example with a simplified structure, and the actual arithmetic device 960 has a variety of structures depending on the application. For example, what is called a multicore structure is preferably employed in which a plurality of cores each including the arithmetic device 960 in FIG. 19 are included and operate in parallel. The larger number of cores can further enhance the arithmetic performance. The number of cores is preferably larger; for example, the number is preferably 2, further preferably 4, still further preferably 8, still further preferably 12, yet still further preferably 16 or larger. For application requiring extremely high arithmetic performance, e.g., a server, it is preferable to employ the multicore structure including 16 or more, preferably 32 or more, further preferably 64 or more cores. In addition, the number of bits that the arithmetic device 960 can process in an internal arithmetic circuit, a data bus, or the like can be 8 bits, 16 bits, 32 bits, 64 bits, or the like, for example.

An instruction that is input to the arithmetic device 960 through the bus interface 998 is input to the instruction decoder 993 and decoded therein, and then, input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction.

Specifically, the ALU controller 992 generates signals for controlling the operation of the ALU 991. While the arithmetic device 960 is executing a program, the interrupt controller 994 judges an interrupt request from an external input/output device, a peripheral circuit, or the like on the basis of its priority or a mask state, and processes the request. The register controller 997 generates an address of the register 996, and performs reading or writing from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above various circuits.

In the arithmetic device 960 illustrated in FIG. 19, the register controller 997 selects a retention operation in the register 996 in accordance with an instruction from the ALU 991. That is, the register controller 997 selects whether data is retained by a flip-flop or by a capacitor in the memory cell included in the register 996. When data retention by the flip-flop is selected, power is supplied to the memory cell in the register 996. When data retention by the capacitor is selected, the data is rewritten in the capacitor, and power supply to the memory cell in the register 996 can be stopped.

That is, in the case where power gating is performed in the arithmetic device 960, for example, in the memory cell included in the register 996, the data retained in the flip-flop can be backed up to the capacitor before the transition to the power-off state (the stop of power supply), and the data retained in the capacitor can be recovered to the flip-flop after the return to the power-on state (the restart of power supply). Thus, the time required for power gating can be shortened and power consumption can be reduced.

### <Electronic Computer>

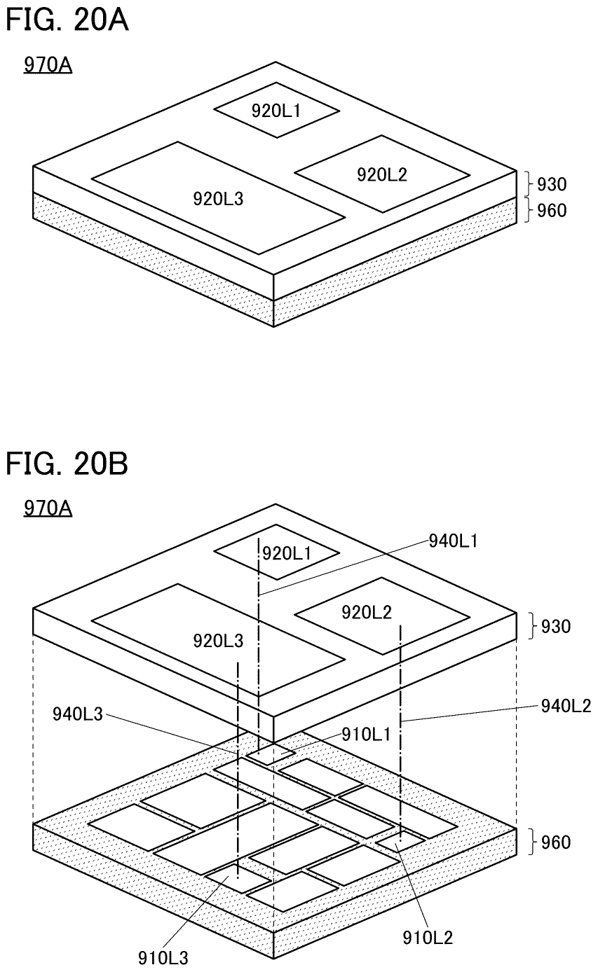

In one embodiment of the present invention, a memory array can be stacked over the arithmetic device 960. FIG. 20A and FIG. 20B are each a perspective view of an electronic computer 970A. The electronic computer 970A includes a layer 930 provided with memory arrays over the arithmetic device 960. A memory array 920L1, a memory array 920L2, and a memory array 920L3 are provided in the layer 930. The arithmetic device 960 and each of the memory arrays include overlapping regions. For easy understanding of the structure of the electronic computer 970A, the arithmetic device 960 and the layer 930 are separately illustrated in FIG. 20B.

Providing the arithmetic device 960 and the layer 930 including the memory arrays to overlap with each other can shorten the wiring distance therebetween. Accordingly, the communication speed therebetween can be increased. Moreover, power consumption can be reduced.

As a method for stacking the layer 930 including the memory arrays and the arithmetic device 960, either of the following methods may be employed: a method in which the layer 930 including the memory arrays is stacked directly on the arithmetic device 960 (also referred to as monolithic stacking method) and a method in which the arithmetic device 960 and the layer 930 are formed over two different substrates, the substrates are bonded to each other, and the arithmetic device 960 and the layer 930 are stacked with a technique for forming a through via (e.g., TSV (Through Silicon Via)) or by a technique for bonding (e.g., Cu—Cu bonding). The monolithic stacking method does not require consideration of misalignment in bonding; thus, not only the chip size but also the manufacturing cost can be reduced.

Here, it is possible that the arithmetic device 960 does not include the cache 999 and the memory array 920L1, the memory array 920L2, and the memory array 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 20B, a driver circuit 910L1, a driver circuit 910L2, and a driver circuit 910L3 are provided. The driver circuit 910L1 can exchange data, a signal, and the like with the memory array 920L1 through an electrode 940L1. Similarly, the driver circuit 910L2 can exchange data, a signal, and the like with the memory array 920L2 through an electrode 940L2, and the driver circuit 910L3 can exchange data, a signal, and the like with the memory array 920L3 through an electrode 940L3.

Although the case where three memory arrays function as caches is described here, the number of memory arrays may be one, two, or four or more.

In the case where the memory array 920L1 is used as a cache, the driver circuit 910L1 may function as part of the cache interface 989 or may have a structure that exchanges data, a signal, or the like with the cache interface 989. Similarly, the driver circuit 910L2 and the driver circuit 910L3 may also function as part of the cache interface 989 or may have a structure that exchanges data, a signal, or the like with the cache interface 989.

Whether the memory array functions as the cache or the main memory is determined by a control circuit or the like included in the arithmetic device 960. With the control circuit, part of the memory array can function as a RAM (Random Access Memory). In addition, some of the memory arrays can function as the cache and other memory arrays can function as the main memory. For example, the memory array can function as a universal memory.

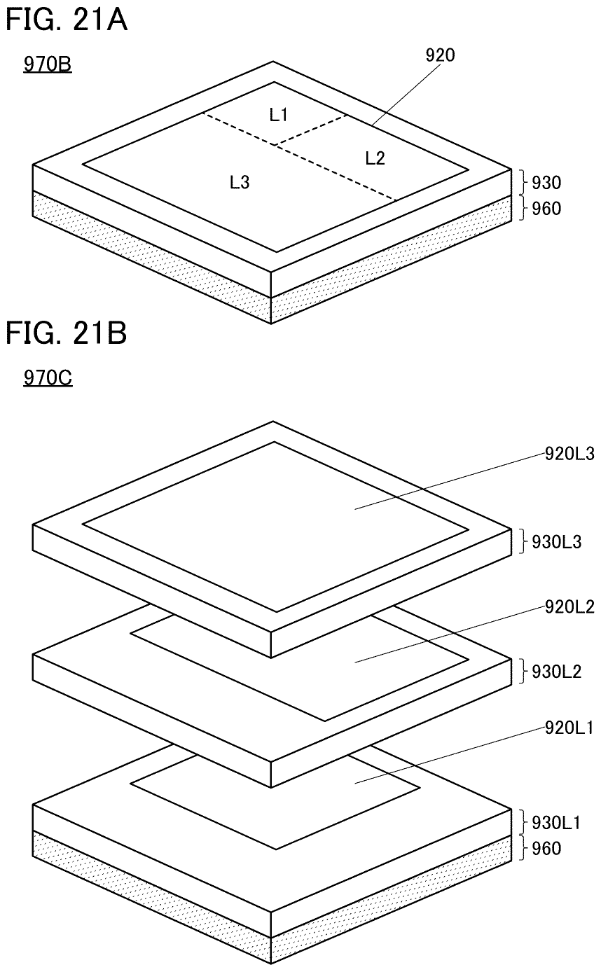

The layer 930 including one memory array may be provided to overlap with the arithmetic device 960. FIG. 21A is a perspective view of an electronic computer 970B.

In the electronic computer 970B, one memory array 920 can be divided into a plurality of areas having different functions. FIG. 21A illustrates an example in which a region L1, a region L2, and a region L3 are used as the L1 cache, the L2 cache, and the L3 cache, respectively.

In the electronic computer 970B, the capacity of each of the region L1 to the region L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 21B illustrates a perspective view of an electronic computer 970C.

In the electronic computer 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

### <Memory Cell>

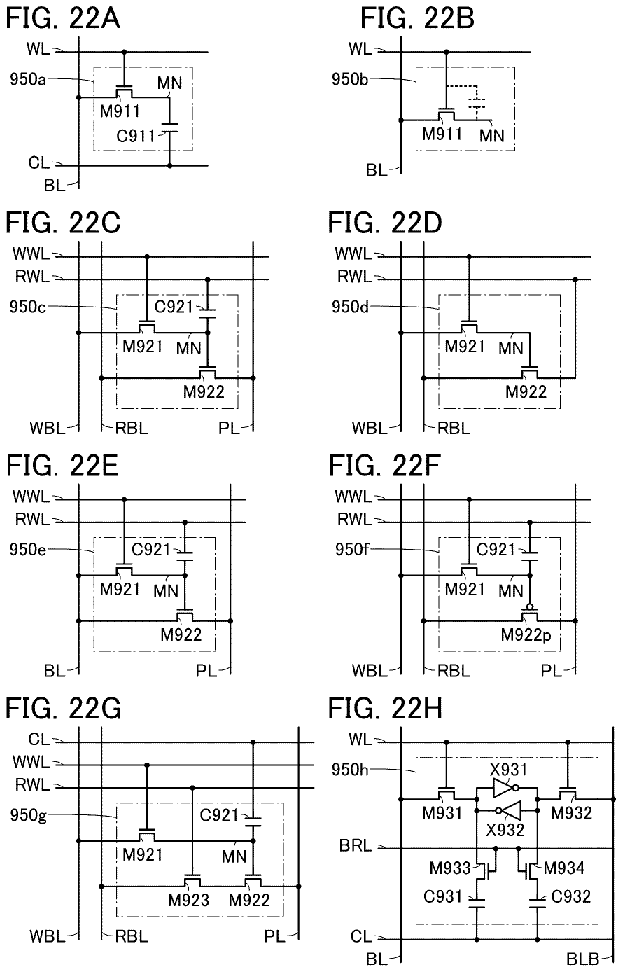

With FIG. 22A to FIG. 22H, structure examples of memory cells applicable to the memory array 920, the memory array 920L1, the memory array 920L2, the memory array 920L3, and the like are described.

A memory cell 950a illustrated in FIG. 22A includes a transistor M911 and a capacitor C911. One of a source and a drain of the transistor M911 is electrically connected to the one terminal of the capacitor C911. The other of the source and the drain of the transistor M911 is electrically connected to a wiring BL functioning as a bit line. A gate of the transistor M911 is electrically connected to a wiring WL functioning as word line. The other terminal of the capacitor C911 is electrically connected to a wiring CL. Note that a wiring where the one of the source and the drain of the transistor M911 and the one terminal of the capacitor C911 are electrically connected to each other is referred to as a wiring MN in some cases.

The memory cell 950a can store binary data when the level of the potential corresponding to the amount of charge accumulated in the capacitor C911, that is, the amount of charge retained in the wiring MN, is made to correspond to “1” or “0”. Note that ternary or higher-level data may be stored, for example. In the case where data is written to the memory cell 950a, the conduction state of the transistor M911 is controlled, whereby a potential corresponding to data can be supplied from the wiring BL to the wiring MN and charge corresponding to the potential can be retained. In the case where data is read from the memory cell 950a, the conduction state of the transistor M911 is controlled, so that charge retained in the wiring MN can be extracted to the wiring BL.

Note that reading of data from the memory cell 950a means extraction of the charge retained in the wiring MN to the wiring BL and thus changes the potential of the wiring MN. That is, by reading data from the memory cell 950a, stored data is destroyed. In other words, reading of data from the memory cell 950a is destructive reading. Thus, the memory cell 950a needs writing back (refresh) of data after data reading.

In one embodiment of the present invention, an n-channel OS transistor can be used as the transistor M911, for example.

Note that the memory cell 950a illustrated in FIG. 22A is a memory cell of a DRAM (Dynamic Random Access Memory), and a structure using an OS transistor as the transistor M911 is particularly referred to as a DOSRAM (registered trademark) in some cases. Since an OS transistor having an extremely low off-state current is used in the DOSRAM, data can be stored for a long time. In addition, multilevel data or analog data can be stored. Data once written can be stored for a long period, and thus the frequency of data refresh can be decreased. In addition, the electrostatic capacitance of the cell capacitor (the capacitor C911) can be reduced, so that the cell size can be reduced. Thus, the use of the DOSRAM can reduce power consumption of a semiconductor device and a memory device and increase the recording density thereof.

A memory cell 950b illustrated in FIG. 22B is a variation example of the memory cell 950a illustrated in FIG. 22A and is different from the memory cell 950a in not including the capacitor C911.

In the memory cell 950b illustrated in FIG. 22B, charge can be accumulated in a parasitic capacitor (capacitance between the gate and one of the source and the drain of the transistor M911) indicated by a dashed line or the like. With such a structure, for example, the cell size can be reduced, so that the recording density of a semiconductor device and a memory device can be increased.

A memory cell 950c illustrated in FIG. 22C includes a transistor M921, a transistor M922, and a capacitor C921. One of a source and a drain of the transistor M921 is electrically connected to a gate of the transistor M922 and one terminal of the capacitor C921. The other of the source and the drain of the transistor M921 is electrically connected to a wiring WBL functioning as a write bit line. A gate of the transistor M921 is electrically connected to a wiring WWL functioning as a write word line. One of a source and a drain of the transistor M922 is electrically connected to a wiring RBL functioning as a read bit line. The other of the source and the drain of the transistor M922 is electrically connected to a wiring PL. The other terminal of the capacitor C921 is electrically connected to a wiring RWL functioning as a read word line. Note that a wiring where the one of the source and the drain of the transistor M921, the gate of the transistor M922, and the one terminal of the capacitor C921 are electrically connected to one another is referred to as the wiring MN in some cases.

The memory cell 950c can store binary data when the level of the potential corresponding to the amount of charge accumulated in the capacitor C921, that is, the amount of charge retained in the wiring MN, is made to correspond to “1” or “0”. Note that ternary or higher-level data may be stored, for example. In the case where data is written to the memory cell 950c, the conduction state of the transistor M921 is controlled, whereby a potential corresponding to data can be supplied from the wiring WBL to the wiring MN and charge corresponding to the potential can be retained. In the case where data is read from the memory cell 950c, the transistor M922 is brought into the conduction state or the non-conduction state in accordance with the potential of the wiring MN, whereby a potential corresponding to the data can be extracted to the wiring RBL.

In one embodiment of the present invention, an n-channel OS transistor can be used as the transistor M921, for example. As the transistor M922, an n-channel transistor (e.g., an OS transistor or a Si transistor) can be used, for example.

Note that the memory cell 950c illustrated in FIG. 22C is a gain-cell memory cell; in particular, a structure in which an OS transistor is used as the transistor M921 is referred to as a NOSRAM (registered trademark) in some cases. The NOSRAM is an abbreviation for a Nonvolatile Oxide Semiconductor RAM. When an OS transistor having an extremely low off-state current is used in the NOSRAM, data can be stored for a long time. In addition, multilevel data or analog data can be stored. Since the transistor for writing (the transistor M921) and the transistor for reading (the transistor M922) are different from each other, non-destructive reading is performed in data reading. Thus, the memory cell can be used as a nonvolatile memory, for example.

A memory cell 950d illustrated in FIG. 22D is a variation example of the memory cell 950c illustrated in FIG. 22C and is different from the memory cell 950c in not including the capacitor C921 and in that the other of the source and the drain of the transistor M922 is electrically connected to the wiring RWL.

In the memory cell 950d illustrated in FIG. 22D, charge can be accumulated in a parasitic capacitor added to the wiring MN. With such a structure, for example, the cell size can be reduced, so that the recording density of a semiconductor device and a memory device can be increased.

A memory cell 950e illustrated in FIG. 22E is a variation example of the memory cell 950c illustrated in FIG. 22C and is different from the memory cell 950c in that the other of the source and the drain of the transistor M921 is electrically connected to the wiring BL and the one of the source and the drain of the transistor M922 is electrically connected to the wiring BL.

In the memory cell 950e illustrated in FIG. 22E, the wiring BL can function as a bit line for both writing and reading. With such a structure, for example, the cell size can be reduced, so that the recording density of a semiconductor device and a memory device can be increased.

A memory cell 950f illustrated in FIG. 22F is a variation example of the memory cell 950c illustrated in FIG. 22C and is different from the memory cell 950c in including a transistor M922p instead of the transistor M922. As the transistor M922p, a p-channel Si transistor can be used, for example.

In the memory cell 950f illustrated in FIG. 22F, data is read using the p-channel transistor; thus, the structure, operation, and the like of the sense amplifier can be simplified in some cases, for example. With such a structure, for example, the layout area of the driver circuit can be reduced, so that a semiconductor device and a memory device can be downsized.

A memory cell 950g illustrated in FIG. 22G is a variation example of the memory cell 950c illustrated in FIG. 22B and is different from the memory cell 950c in including a transistor M923. One of the source and the drain of the transistor M922 is electrically connected to one of a source and a drain of the transistor M923, the other of the source and the drain of the transistor M922 is electrically connected to the wiring PL, the other of the source and the drain of the transistor M923 is electrically connected to the wiring RBL, and a gate of the transistor M923 is electrically connected to the wiring RWL. As the transistor M923, an n-channel transistor (e.g., an OS transistor or a Si transistor) can be used, for example.

In the memory cell 950g illustrated in FIG. 22G, the parasitic capacitance between the wiring MN and the wiring RBL can be reduced. Such a structure can, for example, inhibit noise from being mixed into the wiring MN via the gate capacitance of the transistor M922 and improve the reliability of a semiconductor device and a memory device.

A memory cell 950h illustrated in FIG. 22H includes a transistor M931, a transistor M932, a transistor M933, a transistor M934, a capacitor C931, a capacitor C932, an inverter X931, and an inverter X932. One of a source and a drain of the transistor M931 is electrically connected to one of a source and a drain of the transistor M933, an input terminal of the inverter X931, and an output terminal of the inverter X932. One of a source and a drain of the transistor M932 is electrically connected to one of a source and a drain of the transistor M934, an output terminal of the inverter X931, and an input terminal of the inverter X932. The other of the source and the drain of the transistor M933 is electrically connected to the one terminal of the capacitor C931. The other of the source and the drain of the transistor M934 is electrically connected to the one terminal of the capacitor C932. The other of the source and the drain of the transistor M931 is electrically connected to the wiring BL functioning as one of a pair of bit lines. The other of the source and the drain of the transistor M932 is electrically connected to a wiring BLB functioning as the other of the pair of bit lines. A gate of the transistor M931 and a gate of the transistor M932 are electrically connected to the wiring WL functioning as a word line. A gate of the transistor M933 and a gate of the transistor M934 are electrically connected to a wiring BRL. The other terminal of the capacitor C931 and the other terminal of the capacitor C932 are electrically connected to the wiring CL.

In the memory cell 950h, binary data of “1” or “0” can be stored in an inverter loop composed of the inverter X931 and the inverter X932. In writing data to the memory cell 950h, the conduction states of the transistor M931 and the transistor M932 are controlled, so that a potential corresponding to data can be supplied from each of the wiring BL and the wiring BLB to the inverter loop. In reading data from the memory cell 950h, the conduction states of the transistor M931 and the transistor M932 are controlled, so that a potential corresponding to the data stored in the inverter loop can be extracted to each of the wiring BL and the wiring BLB.

In the memory cell 950h, by controlling the conduction states of the transistor M933 and the transistor M934, a potential corresponding to the data stored in the inverter loop can be supplied to each of the one terminal of the capacitor C931 and the one terminal of the capacitor C932 and charge corresponding to the potential can be retained. That is, data backup can be performed. Furthermore, in the memory cell 950h, charge retained in the one terminal of the capacitor C931 and the one terminal of the capacitor C932 can be extracted to the inverter loop by controlling the conduction states of the transistor M933 and the transistor M934. That is, data recovery can be performed.

In one embodiment of the present invention, n-channel OS transistors can be used as the transistor M931, the transistor M932, the transistor M933, and the transistor M934, for example. As each of the inverter X931 and the inverter X932, an inverter circuit prepared in a standard circuit library can be used. That is, as transistors included in the inverter X931 and the inverter X932, n-channel and p-channel Si transistors can be used, for example.

Note that the memory cell 950h illustrated in FIG. 22H is a memory cell of an SRAM (Static Random Access Memory) capable of backup operation; in particular, a structure in which OS transistors are used as the transistor M931, the transistor M932, the transistor M933, and the transistor M934 is referred to as an OS-SRAM (Oxide Semiconductor-SRAM) in some cases.

In one embodiment of the present invention, there is no limitation to the memory cell 950a to the memory cell 950h, and a memory cell in which the structures of the memory cells are combined as appropriate can be formed.

Note that this embodiment can be combined with any of the other embodiments in this specification and the like as appropriate.

### EMBODIMENT 5

In this embodiment, application examples of the memory device of one embodiment of the present invention are described.

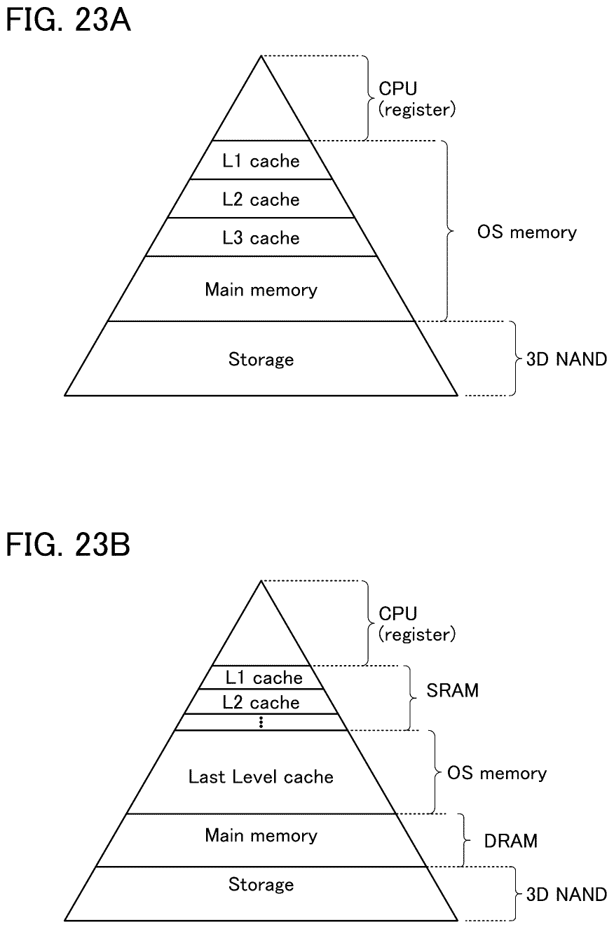

In general, a variety of memory devices are used in semiconductor devices such as computers in accordance with the intended use. FIG. 23A illustrates the hierarchy of various memory devices used in a semiconductor device. The memory devices at the upper levels require higher operating speeds, whereas the memory devices at the lower levels require larger storage capacities and higher recording densities. FIG. 23A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may be further included.

The memory included as the register in the arithmetic processing device such as a CPU is used for temporary storage of arithmetic operation results, for example, and thus is very frequently accessed by the arithmetic processing device. Accordingly, rapid operation is more important than the storage capacity of the memory. The register also has a function of retaining setting information or the like of the arithmetic processing device.

The cache has a function of duplicating and retaining part of data retained in the main memory. Duplicating frequently used data and retaining the duplicated data in the cache facilitates rapid data access. The cache requires a smaller storage capacity than the main memory but a higher operating speed than the main memory. Data that is rewritten in the cache is duplicated, and the duplicated data is supplied to the main memory.

The main memory has a function of retaining a program, data, and the like that are read from the storage.

The storage has a function of retaining data that needs to be retained for a long time and a variety of programs used in the arithmetic processing device, for example. Therefore, the storage is required to have a large storage capacity and a high recording density rather than operating speed. For example, a high-capacity nonvolatile memory device such as a 3D NAND memory device can be used.

The memory device including an oxide semiconductor (the OS memory) of one embodiment of the present invention operates at high speed and can retain data for a long time. Thus, as illustrated in FIG. 23A, the memory device of one embodiment of the present invention can be used at both the level including the cache and the level including the main memory. The memory device of one embodiment of the present invention can also be used at the level including the storage.

FIG. 23B illustrates an example in which an SRAM is used as some of the caches and the OS memory of one embodiment of the present invention is used as another one of the caches.

The lowest-level cache can be referred to as an LLC (Last Level cache). The LLC does not require a higher operation speed than a higher-level cache, but desirably has large storage capacity. The OS memories of one embodiment of the present invention can have a large storage capacity and a high recording density by being stacked in the three-dimensional direction, and thus can be used as the LLC. Note that the OS memory of one embodiment of the present invention can also be used as an FLC (Final Level cache).

For example, as illustrated in FIG. 23B, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 23B.

Note that this embodiment can be combined with any of the other embodiments in this specification and the like as appropriate.

DONE

### EMBODIMENT 6

This embodiment will describe an electronic component, an electronic device, a large computer, a device for space, and a data center (also referred to as a DC) that can use the semiconductor device described in the above embodiment. An electronic component, an electronic device, a large computer, a device for space, and a data center each using the semiconductor device of one embodiment of the present invention are effective in achieving high performance, e.g., reducing power consumption.

### [Electronic Component]

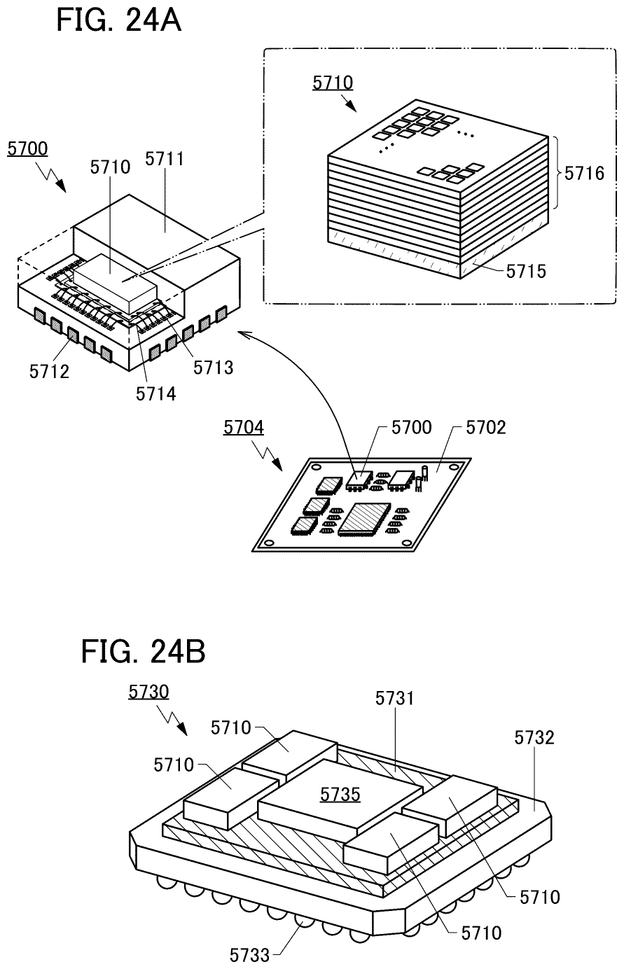

FIG. 24A is a perspective view of an electronic component 5700 and a substrate (a circuit board 5704) on which the electronic component 5700 is mounted. The electronic component 5700 illustrated in FIG. 24A includes a semiconductor device 5710 in a mold 5711. FIG. 24A omits illustrations of some parts to show the inside of the electronic component 5700. The electronic component 5700 includes a land 5712 outside the mold 5711. The land 5712 is electrically connected to an electrode pad 5713. The electrode pad 5713 is electrically connected to the semiconductor device 5710 through a wire 5714. The electronic component 5700 is mounted on a printed circuit board 5702, for example. A plurality of such electronic components are combined and electrically connected to each other on the printed circuit board 5702, whereby the circuit board 5704 is completed.

The semiconductor device 5710 includes a driver circuit layer 5715 and a memory layer 5716. Note that the memory layer 5716 has a structure in which a plurality of memory cell arrays are stacked. A stacked-layer structure of the driver circuit layer 5715 and the memory layer 5716 can be a monolithic stacked-layer structure. In the monolithic stacked-layer structure, layers can be connected without using a through electrode technique such as a TSV (Through Silicon Via) and a bonding technique such as Cu—Cu direct bonding, for example. The monolithic stacked-layer structure of the driver circuit layer 5715 and the memory layer 5716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as a TSV is employed, for example; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 5716 be formed using OS transistors and be monolithically stacked. The monolithic stacked-layer structure of the plurality of memory cell arrays can improve the bandwidth of the memory and/or the access latency of the memory. Note that the bandwidth refers to the data transfer volume per unit time. The access latency refers to a period of time from data access to the start of data transmission. In the case where the memory layer 5716 is formed using Si transistors, it is difficult to obtain the monolithic stacked-layer structure as compared with the case where the memory layer 5716 is formed using OS transistors. Thus, an OS transistor is superior to a Si transistor in the monolithic stacked-layer structure.

That is, an OS transistor has an excellent effect of achieving a wide memory bandwidth as compared with a Si transistor.

The semiconductor device 5710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of semiconductor materials that can be used for the die include silicon, silicon carbide, and gallium nitride. A die obtained from a silicon substrate (also referred to as a silicon wafer) may be referred to as a silicon die, for example.

FIG. 24B is a perspective view of an electronic component 5730. The electronic component 5730 is an example of a SiP (System in Package) or an MCM (Multi Chip Module). In the electronic component 5730, an interposer 5731 is provided on a package substrate 5732 (a printed circuit board), and a semiconductor device 5735 and a plurality of semiconductor devices 5710 are provided on the interposer 5731.

In the electronic component 5730, the semiconductor device 5710 can be used as a memory device such as a high bandwidth memory (HBM), for example. The semiconductor device 5735 can be used for an integrated circuit (e.g., an arithmetic device, a control device, or a signal processing device) such as a CPU (Central Processing Unit), a GPU (Graphics Processing Unit), or an FPGA (Field Programmable Gate Array), for example.

As the package substrate 5732, a ceramic substrate, a plastic substrate, or a glass epoxy substrate can be used, for example. As the interposer 5731, a silicon interposer or a resin interposer can be used, for example.

The interposer 5731 includes a plurality of wirings and has a function of electrically connecting a plurality of integrated circuits with different terminal pitches through the plurality of wirings. The plurality of wirings are provided in a single layer or multiple layers. The interposer 5731 has a function of electrically connecting an integrated circuit provided on the interposer 5731 to an electrode provided on the package substrate 5732. Accordingly, the interposer 5731 is sometimes referred to as a “redistribution substrate” or an “intermediate substrate”. A through electrode may be provided in the interposer 5731 to be used for electrically connecting the integrated circuit and the package substrate 5732. Moreover, in the case of using a silicon interposer as the interposer 5731, a TSV can also be used as the through electrode.

A silicon interposer is preferably used as the interposer 5731. The silicon interposer can be formed at lower cost than an integrated circuit because it is not necessary to provide an active element. Furthermore, since wirings of a silicon interposer can be formed through a semiconductor process, formation of minute wirings, which is difficult for a resin interposer, is easy.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

For example, in a SiP, an MCM, or the like using a silicon interposer, a decrease in reliability due to a difference in the coefficient of expansion between an integrated circuit and the interposer is less likely to occur. Furthermore, the surface of a silicon interposer has high planarity, so that a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected with use of a silicon interposer, a TSV, and the like, a space for a width of the terminal pitch and the like is needed. Thus, in the case where the size of the electronic component 5730 is to be reduced, the width of the terminal pitches causes a problem, which sometimes makes it difficult to provide a large number of wirings for obtaining a wide memory bandwidth. For this reason, the above-described monolithic stacked-layer structure using OS transistors is suitable. Furthermore, a composite structure combining memory cell arrays stacked using a TSV and monolithically stacked memory cell arrays may be employed.

The substrate on which the electronic component 5730 is mounted may be provided with a heat sink (a radiator plate) overlapping with the electronic component 5730. In the case of providing a heat sink, the heights of integrated circuits provided on the interposer 5731 are preferably equal to each other. For example, in the electronic component 5730, the heights of the semiconductor device 5710 and the semiconductor device 5735 are preferably equal to each other.

An electrode 5733 may be provided on the bottom portion of the package substrate 5732 to mount the electronic component 5730 on another substrate. FIG. 24B illustrates an example in which the electrode 5733 is formed of a solder ball. Solder balls are provided in a matrix on the bottom portion of the package substrate 5732, whereby BGA (Ball Grid Array) mounting can be achieved in the electronic component 5730. Note that the electrode 5733 may be formed of a conductive pin. When conductive pins are provided in a matrix on the bottom portion of the package substrate 5732, PGA (Pin Grid Array) mounting can be achieved in the electronic component 5730.

The electronic component 5730 can be mounted on another substrate by various mounting methods not limited to BGA or PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

### [Electronic Device]

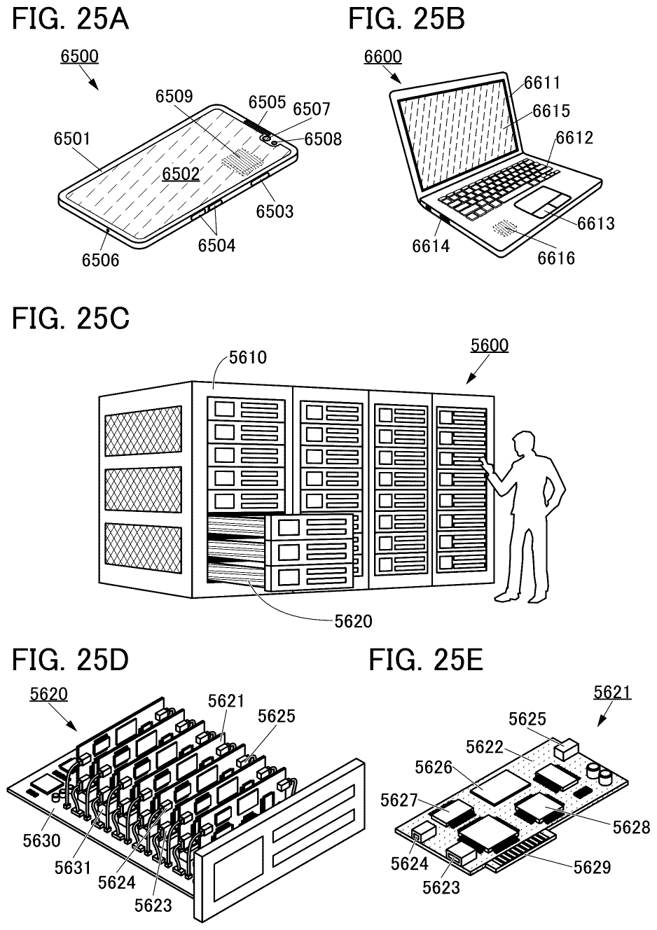

FIG. 25A is a perspective view of an electronic device 6500. The electronic device 6500 illustrated in FIG. 25A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, and a control device 6509, for example. Note that the control device 6509 includes one or more selected from a CPU, a GPU, and a memory device, for example. The semiconductor device of one embodiment of the present invention can be used for the display portion 6502 or the control device 6509, for example. The semiconductor device of one embodiment of the present invention is preferably used for the control device 6509, in which case power consumption can be reduced.

FIG. 25B is a perspective view of an electronic device 6600. The electronic device 6600 illustrated in FIG. 25B is an information terminal that can be used as a notebook personal computer. The electronic device 6600 includes a housing 6611, a keyboard 6612, a pointing device 6613, an external connection port 6614, a display portion 6615, and a control device 6616, for example. Note that the control device 6616 includes one or more selected from a CPU, a GPU, and a memory device, for example. The semiconductor device of one embodiment of the present invention can be employed for the control device 6509 or the control device 6616, for example. The semiconductor device of one embodiment of the present invention is preferably used as the control device 6616, in which case power consumption can be reduced.

FIG. 25C is a perspective view of a large computer 5600. In the large computer 5600 illustrated in FIG. 25C, a plurality of rack mount computers 5620 are stored in a rack 5610. Note that the large computer 5600 may be referred to as a supercomputer.

FIG. 25D is a perspective view illustrating a structure example of the computer 5620. In FIG. 25D, the computer 5620 includes a motherboard 5630. The motherboard 5630 includes a plurality of slots 5631 and a plurality of connection terminals (not illustrated). A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 25E is an example of a processing board provided with a CPU, a GPU, and a memory device, for example. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 25E illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe (Peripheral Component Interconnect Express).

Each of the connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), SCSI (Small Computer System Interface), and the like. In the case where video signals are output from the connection terminal 5623, the connection terminal 5624, and the connection terminal 5625, an example of the standard therefor is HDMI (registered trademark) (High-Definition Multimedia Interface).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the above-described electronic component 5730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the above-described electronic component 5700 can be used, for example.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention can be used as a device for space such as devices processing and storing information, for example.

The semiconductor device of one embodiment of the present invention can include an OS transistor. A change in electrical characteristics of the OS transistor due to radiation irradiation is small. That is, the OS transistor is highly resistant to radiation, and thus can be suitably used in an environment where radiation can enter. For example, the OS transistor is suitably used in outer space.

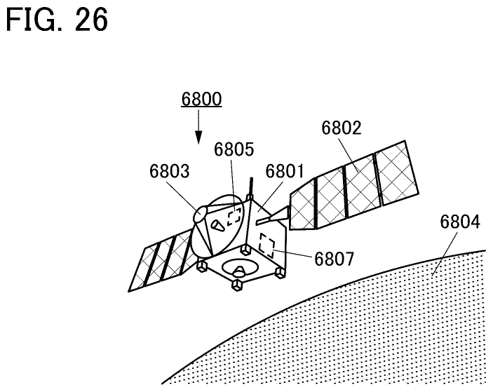

FIG. 26 illustrates an artificial satellite 6800 as an example of a device for space. The artificial satellite 6800 includes a body 6801, a solar panel 6802, an antenna 6803, a secondary battery 6805, and a control device 6807. In FIG. 26, a planet 6804 in outer space is illustrated as an example. Note that outer space refers to, for example, space at an altitude greater than or equal to 100 km, and outer space described in this specification and the like may include thermosphere, mesosphere, and stratosphere.

Although not illustrated in FIG. 26, the secondary battery 6805 may be provided with a battery management system (also referred to as a BMS) or a battery control circuit. The battery management system or the battery control circuit preferably uses the OS transistor, in which case power consumption is low and high reliability is achieved even in outer space.

The amount of radiation in outer space is 100 or more times that on the ground. Note that examples of radiation include electromagnetic waves (electromagnetic radiation) typified by X-rays or gamma rays and particle radiation typified by alpha rays, beta rays, neutron beams, proton beams, heavy-ion beams, and meson beams.

When the solar panel 6802 is irradiated with sunlight, power required for the operation of the artificial satellite 6800 is generated. However, for example, in the situation where the solar panel 6802 is not irradiated with sunlight or the amount of sunlight with which the solar panel 6802 is irradiated is small, the amount of power generated by the solar panel 6802 is small. Accordingly, a sufficient amount of power required for the operation of the artificial satellite 6800 might not be generated. In order to operate the artificial satellite 6800 even with a small amount of power generated by the solar panel 6802, the artificial satellite 6800 may be provided with the secondary battery 6805. Note that the solar panel 6802 is referred to as a solar cell module in some cases.

The artificial satellite 6800 can generate a signal. The signal is transmitted through the antenna 6803. The signal can be received by a ground-based receiver or another artificial satellite, for example. When the receiver receives the signal transmitted by the artificial satellite 6800, the position of the receiver can be measured. Thus, the artificial satellite 6800 can constitute a satellite positioning system.

The control device 6807 has a function of controlling the artificial satellite 6800. The control device 6807 is formed with one or more selected from a CPU, a GPU, and a memory device, for example. Note that the semiconductor device including the OS transistor, which is one embodiment of the present invention, is suitably used for the control device 6807. A change in electrical characteristics due to radiation irradiation is smaller in an OS transistor than in a Si transistor. Accordingly, the OS transistor has high reliability even in an environment where radiation can enter and thus is preferable.

That is, an OS transistor has an excellent effect of being highly resistant to radiation as compared with a Si transistor.

The artificial satellite 6800 can include a sensor. For example, with a structure including a visible light sensor, the artificial satellite 6800 can have a function of sensing sunlight reflected by a ground-based object. With a structure including a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be used for a device for space such as a spacecraft, a space capsule, or a space probe, for example.

The semiconductor device of one embodiment of the present invention can be used for a storage system in a data center, for example. Long-term management of data, such as guarantee of data immutability, is required for the data center, for example. In the case where data is managed for a long term, installation of storages and servers for storing an enormous amount of data, ensuring stable electric power for data retention, ensuring cooling equipment for data retention, or the like is necessary, for example. Therefore, for example, an increase in the scale of data center facility is necessary.

With use of the semiconductor device of one embodiment of the present invention for a storage system used in a data center, power used for retaining data can be reduced and the semiconductor device for retaining data can be downsized. Accordingly, downsizing of the storage system, downsizing of the power supply for retaining data, downscaling of the cooling equipment, and the like can be achieved, for example. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a peripheral module. Furthermore, the use of the semiconductor device of one embodiment of the present invention enables a data center that operates stably even in a high-temperature environment. Thus, the reliability of the data center can be increased.

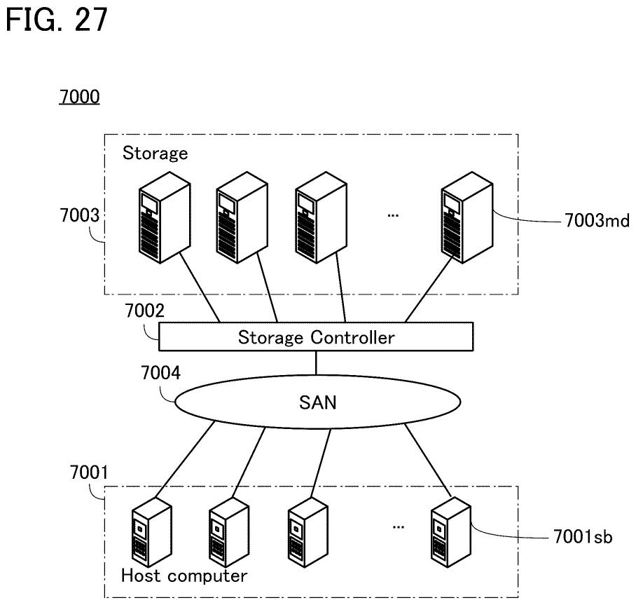

FIG. 27 illustrates a storage system that can be used in a data center. A storage system 7000 illustrated in FIG. 27 includes a plurality of servers 7001sb as a host 7001 (indicated as “Host Computer” in the diagram). The storage system 7000 includes a plurality of memory devices 7003md as a storage 7003 (indicated as “Storage” in the diagram). Furthermore, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for writing or reading data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for writing or reading data.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the above-described cache memory to retain a potential based on data can reduce the refresh frequency of the above-described cache memory, so that power consumption of the above-described cache memory can be reduced. Furthermore, with a structure in which memory cell arrays are stacked, the cache memory can be downsized.

Note that with the use of the semiconductor device of one embodiment of the present invention for one or more selected from an electronic component, an electronic device, a large computer, a device for space, and a data center, power consumption can be reduced. While the demand for energy is expected to increase with higher performance or higher integration of semiconductor devices, the emission amount of greenhouse effect gases typified by carbon dioxide (CO₂) can be reduced with the use of the semiconductor device of one embodiment of the present invention. Furthermore, the semiconductor device of one embodiment of the present invention has low power consumption and thus is effective as a global warming countermeasure.

The structures, configurations, methods, and the like described in this embodiment can be used in combination as appropriate with the structures, configurations, methods, and the like described in the other embodiments and the like.

### Supplementary Notes on Description in this Specification and the Like

The following are notes on the description of the foregoing embodiments and the structures in the embodiments.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, e.g., a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

Here, the expression “X and Y are electrically connected” means the case where electric signals can be transmitted and received between X and Y when an object having any electric action is present between X and Y. For example, in the case where X and Y are electrically connected, one or more elements that allow electrical connection between X and Y (e.g., a switch, a transistor, a capacitor, an inductor, a resistor, a diode, a display device, a light-emitting device, or a load) can be connected between X and Y.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit (e.g., a step-up circuit or a step-down circuit) or a level shifter circuit for changing the potential level of a signal); a voltage source; a current source; a switch circuit; an amplifier circuit (e.g., a circuit that can increase signal amplitude, the current amount, or the like, an operational amplifier, a differential amplifier circuit, a source follower circuit, or a buffer circuit); a signal generation circuit; a memory circuit; or a control circuit) can be connected between X and Y. For instance, even if another circuit is interposed between X and Y, X and Y are regarded as being functionally connected when a signal output from X is transmitted to Y.

Note that an explicit description that X and Y are electrically connected includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

It can be expressed as, for example, “X, Y, a source (sometimes called one of a first terminal and a second terminal in this specification and the like) of a transistor, and a drain (sometimes called the other of the first terminal and the second terminal in this specification and the like) of the transistor are electrically connected to each other, and X, the source of the transistor, the drain of the transistor, and Y are electrically connected to each other in this order”. Alternatively, it can be expressed as “a source of a transistor is electrically connected to X; a drain of the transistor is electrically connected to Y; and X, the source of the transistor, the drain of the transistor, and Y are electrically connected to each other in this order”. Alternatively, it can be expressed as “X is electrically connected to Y through a source and a drain of a transistor, and X, the source of the transistor, the drain of the transistor, and Y are provided in this connection order”. When the connection order in a circuit structure is defined by an expression like the above examples, a source and a drain of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: the wiring and the electrode. Thus, electrical connection in this specification and the like includes, in its category, such a case where one conductive film has functions of a plurality of components.

In this specification and the like, as a “resistor”, a circuit element, a wiring, or the like having a resistance value higher than 0Ω can be used, for example. Accordingly, in this specification and the like, examples of the “resistor” include a wiring having a resistance value, a transistor in which a current flows from a drain to a source, a diode, and a coil. Thus, the term “resistor” can be replaced with the term “resistance”, “load”, “region having a resistance value”, or the like. Conversely, the terms “resistance”, “load”, and “region having a resistance value” can be replaced with the term “resistor”, or the like. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. As another example, the resistance value may be higher than or equal to 1Ω and lower than or equal to 1×10⁹Ω.

In the case where a wiring is used as a resistor, the resistance value of the resistor is sometimes determined depending on the length of the wiring. Alternatively, a conductor with resistivity different from that of a conductor used as a wiring is sometimes used as a resistor. Alternatively, in the case where a semiconductor is used as a resistor, the resistance value of the resistor is sometimes determined by doping the semiconductor with an impurity.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. Thus, in this specification and the like, a “capacitor” is not limited to only a circuit element that has a pair of electrodes and a dielectric between the electrodes. A “capacitor” includes, for example, parasitic capacitance generated between wirings, gate capacitance generated between a gate and one of a source and a drain of a transistor, and the like. The term “capacitor”, “parasitic capacitance”, “gate capacitance”, or the like can be replaced with the term “capacitance” and the like, for example. Conversely, the term “capacitance” can be replaced with the term “capacitor”, “parasitic capacitance”, “gate capacitance”, or the like, for example. The term “a pair of electrodes” of a “capacitor” can be replaced with “a pair of conductors”, “a pair of conductive regions”, “a pair of regions”, or the like, for example. Note that the electrostatic capacitance value can be higher than or equal to 0.05 fF and lower than or equal to 10 pF, for example. As another example, the electrostatic capacitance value may be higher than or equal to 1 pF and lower than or equal to 10 μF.

A transistor in this specification and the like has three terminals called a gate (also referred to as a gate terminal, a gate region, or a gate electrode), a source (also referred to as a source terminal, a source region, or a source electrode), and a drain (also referred to as a drain terminal, a drain region, or a drain electrode). The transistor has a region where a channel is formed (also referred to as a channel formation region) between the drain and the source. In the transistor, a current can flow through the channel formation region between the source and the drain. The channel formation region refers to a region through which a current mainly flows. The gate is a control terminal for controlling the amount of current flowing through the channel formation region between the source and the drain. Two terminals functioning as the source and the drain are input/output terminals of the transistor.

Note that one of the two input/output terminals serves as the source and the other serves as the drain depending on the conductivity type (n-channel type or p-channel type) of the transistor and the levels of potentials supplied to the three terminals of the transistor. In some cases, the function of the source and the function of the drain are replaced with each other when the direction of current flow is changed in circuit operation, for example. Thus, the terms “source” and “drain” can be replaced with each other in this specification and the like. Furthermore, in this specification and the like, expressions “one of a source and a drain” (or a first electrode or a first terminal) and “the other of the source and the drain” (or a second electrode or a second terminal) are used in the description of the connection relationship of a transistor.

Depending on the structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, each of the gates may be referred to as a first gate, a second gate, or a third gate, for example, in this specification and the like.

In this specification and the like, a transistor having a multi-gate structure having two or more gate electrodes can be used as the transistor. In the transistor having the multi-gate structure, channel formation regions are connected in series; accordingly, a plurality of transistors are connected in series. Thus, in the transistor having the multi-gate structure, the amount of off-state current can be reduced, and the withstand voltage of the transistor can be increased (the reliability can be improved). Alternatively, in the transistor having the multi-gate structure, a drain-source current does not change very much even if a drain-source voltage changes at the time of operation in a saturation region, so that a flat slope of voltage-current characteristics can be obtained. The transistor having the flat slope of the voltage-current characteristics enables an ideal current source circuit or an active load having an extremely high resistance value. As a result, the transistor having the flat slope of the voltage-current characteristics enables, for example, a differential circuit, a current mirror circuit, or the like having high characteristics.

In this specification and the like, the case where a single circuit element is illustrated in a circuit diagram may indicate a case where the circuit element includes a plurality of circuit elements. For example, the case where a single resistor is illustrated in a circuit diagram may indicate a case where two or more resistors are electrically connected to each other in series. As another example, the case where a single capacitor is illustrated in a circuit diagram may indicate a case where two or more capacitors are electrically connected to each other in parallel. As another example, the case where a single transistor is illustrated in a circuit diagram may indicate a case where two or more transistors are electrically connected to each other in series and their gates are electrically connected to each other. Similarly, as another example, the case where a single switch is illustrated in a circuit diagram may indicate a case where the switch includes two or more transistors which are electrically connected to each other in series or in parallel and whose gates are electrically connected to each other.

In this specification and the like, a “node” can be referred to as a “terminal”, a “wiring”, an “electrode”, a “conductive layer”, a “conductor”, an “impurity region”, or the like depending on the circuit structure, the device structure, or the like, for example. Furthermore, a “terminal”, a “wiring”, or the like can be referred to as a “node”, for example.

In this specification and the like, “voltage” and “potential” can be replaced with each other as appropriate. The term “voltage” refers to a potential difference from a reference potential. When the reference potential is a ground potential, for example, “voltage” can be replaced with “potential”. Note that the ground potential does not necessarily mean 0 V. Moreover, potentials are relative values. That is, a potential supplied to a wiring, a potential applied to a circuit and the like, or a potential output from a circuit and the like, are changed with a change of the reference potential.

In this specification and the like, the terms “high-level potential” (also referred to as “H potential” or “H”) and “low-level potential” (also referred to as “L potential” or “L”) do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

In this specification and the like, a “current” means a charge transfer (electrical conduction). For example, the description “electrical conduction of positively charged particles occurs” can be rephrased as “electrical conduction of negatively charged particles occurs in the opposite direction”. Thus, unless otherwise specified, a “current” in this specification and the like refers to a charge transfer (electrical conduction) accompanied by carrier movement. Examples of a carrier here include an electron, a hole, an anion, a cation, and a complex ion. The type of carrier differs depending on current-flowing systems (e.g., a semiconductor, a metal, an electrolyte solution, or a vacuum). For example, the “direction of current” in a wiring or the like refers to the direction in which a positive carrier moves, and the amount of current is expressed as a positive value. In other words, the direction in which a negative carrier moves is opposite to the direction of current, and the amount of current is expressed as a negative value. Thus, in the case where the polarity of current (or the direction of current) is not specified in this specification and the like, the description “a current flows from element A to element B” can be rephrased as “a current flows from element B to element A” and the like, for example. The description “a current is input to element A” and the like can be rephrased as “a current is output from element A” and the like, for example.

Ordinal numbers such as “first”, “second”, and “third” in this specification and the like are used to avoid confusion among components. Thus, the ordinal numbers do not limit the number of components. In addition, the ordinal numbers do not limit the order of components. For example, a “first” component in one embodiment in this specification and the like can be referred to as a “second” component in other embodiments, the scope of claims, or the like. Furthermore, for example, a “first” component in one embodiment in this specification and the like can be omitted in other embodiments, the scope of claims, or the like.

In this specification and the like, for example, terms for describing arrangement, such as “over”, “under”, “above”, and “below” are sometimes used for convenience to describe the positional relationship between components with reference to drawings. The positional relationship between components is changed as appropriate in accordance with a direction in which each component is described. Thus, the terms for describing arrangement in this specification and the like are not limited to those and can be replaced with another term as appropriate depending on the situation. For example, the expression “an insulator positioned over (on) a top surface of a conductor” can be replaced with the expression “an insulator positioned under (on) a bottom surface of a conductor” when the direction of a drawing illustrating these components is rotated by 180°. Moreover, the expression “an insulator positioned over (on) a top surface of a conductor” can be replaced with the expression “an insulator positioned on a left surface (or a right surface) of a conductor” when the direction of a drawing illustrating these components is rotated by 90°.

The term “over” or “under” does not necessarily mean that a component is placed directly over or directly under and directly in contact with another component. For example, the expression “electrode B over insulating layer A” does not necessarily mean that the electrode B is formed over and in direct contact with the insulating layer A, and does not exclude the case where another component is provided between the insulating layer A and the electrode B.

In this specification and the like, components arranged in a matrix and their positional relationship are sometimes described using a term such as “row” or “column”, for example. The positional relationship between components is changed as appropriate in accordance with a direction in which each component is described. Thus, for example, the terms such as “row” and “column” are not limited to those described in this specification and the like and can be replaced with another term as appropriate depending on the situation. For example, the term “row direction” can be replaced with the term “column direction” when the direction of the diagram is rotated by 90°.

Furthermore, the term “overlap”, for example, in this specification and the like does not limit a state such as the stacking order of components. For example, the expression “electrode B overlapping with insulating layer A” does not necessarily mean the state where the electrode B is formed over the insulating layer A. The expression “electrode B overlapping with insulating layer A”, for example, does not exclude the state where the electrode B is formed under the insulating layer A and the state where the electrode B is formed on the right side (or the left side) of the insulating layer A.

The term “adjacent” or “proximity” in this specification and the like does not necessarily mean that a component is directly in contact with another component. For example, the expression “electrode B adjacent to insulating layer A” does not necessarily mean that the electrode B is formed in direct contact with the insulating layer A and does not exclude the case where another component is placed between the insulating layer A and the electrode B.

In this specification and the like, the term “film”, “layer”, or the like can be, for example, interchanged with each other depending on the situation, in some cases. For example, the term “conductive layer” can be changed into the term “conductive film” in some cases. For another example, the term “insulating film” can be changed into the term “insulating layer” in some cases. Alternatively, for example, the term “film”, “layer”, or the like is not used and can be interchanged with another term depending on the situation, in some cases. For example, the term “conductive layer” or “conductive film” can be changed into the term “conductor” in some cases. Furthermore, the term “conductor” can be changed into the term “conductive layer” or “conductive film” in some cases. For example, the term “insulating layer” or “insulating film” can be changed into the term “insulator” in some cases. Furthermore, the term “insulator” can be changed into the term “insulating layer” or “insulating film” in some cases.

In addition, in this specification and the like, for example, the term such as “electrode”, “wiring”, or “terminal” does not limit the function of a component. For example, an “electrode” is used as part of a “wiring” in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Thus, for example, an “electrode” can be part of a “wiring” or a “terminal”. Furthermore, a “terminal” can be part of a “wiring” or an “electrode”. Moreover, the term “electrode”, “wiring”, “terminal”, or the like is sometimes replaced with the term “region”, for example.

In addition, in this specification and the like, for example, the terms such as “wiring”, “signal line”, and “power supply line” can be interchanged with each other depending on the situation, in some cases. For example, the term “wiring” can be changed into the term “signal line” in some cases. For another example, the term “wiring” can be changed into the term “power supply line” or the like in some cases. Conversely, for example, the term “signal line”, “power supply line”, or the like can be changed into the term “wiring” in some cases. Furthermore, for example, the term “power supply line” or the like can be changed into the term “signal line” or the like in some cases. Conversely, for example, the term “signal line” or the like can be changed into the term “power supply line” or the like in some cases. Moreover, the term “potential” that is applied to a wiring can be changed into the term “signal” or the like depending on the situation, for example. Conversely, for example, the term “signal” or the like can be changed into the term “potential” in some cases.

In this specification and the like, a “switch” includes a plurality of terminals and has a function of switching (selecting) electrical continuity and discontinuity between the terminals. For example, in the case where a switch includes two terminals and electrical continuity is established between the two terminals, the switch is in a “conduction state” or an “on state”. In the case where electrical continuity is not established between the two terminals, the switch is in a “non-conduction state” or an “off state”. Note that switching to one of a conduction state and a non-conduction state or maintaining one of a conduction state and a non-conduction state is sometimes referred to as “controlling a conduction state”.

That is, a switch has a function of controlling whether a current flows therethrough or not. Alternatively, a switch has a function of selecting and changing a current path. For example, an electrical switch or a mechanical switch can be used as the switch. That is, a switch is not limited to a particular element.

Note that as a kind of a switch, there is a switch which is normally in a non-conduction state and brought into a conduction state by controlling a conduction state; such a switch is referred to as an “A contact” in some cases. Furthermore, as another kind of a switch, there is a switch which is normally in a conduction state and brought into a non-conduction state by controlling a conduction state; such a switch is referred to as a “B contact” in some cases.

Examples of an electrical switch include a transistor (e.g., a bipolar transistor or a MOS transistor), a diode (e.g., a PN diode, a PIN diode, a Schottky diode, a MIM (Metal Insulator Metal) diode, a MIS (Metal Insulator Semiconductor) diode, or a diode-connected transistor), and a logic circuit in which such elements are combined. Note that in the case where a transistor operates just as a switch, there is no particular limitation on the polarity (conductivity type) of the transistor.

An example of a mechanical switch is a switch using a MEMS (micro electro mechanical systems) technology. Such a switch includes an electrode that can be moved mechanically, and selects a conduction or non-conduction state with the movement of the electrode.

In this specification and the like, the “channel length” of the transistor sometimes refers to, for example, the distance between a source and a drain in a region where a semiconductor (or a portion where a current flows in a semiconductor when a transistor is in an on state) and a gate overlap with each other or the distance between the source and the drain of a region where a channel is formed.

In this specification and the like, the “channel width” of the transistor sometimes refers to, for example, the length of a portion where a source and a drain face each other in a region where a semiconductor (or a portion where a current flows in a semiconductor when a transistor is an on state) and a gate overlap with each other or the length of a portion where a source and a drain face each other in a region where a channel is formed.

In this specification and the like, for example, the terms such as “substrate”, “wafer”, and “die” do not functionally limit these components. For example, the terms such as “substrate,” “wafer,” and “die” can be interchanged with each other depending on the situation in some cases.

In this specification and the like, the term “parallel” does not necessarily mean a state being exactly parallel. Hence, for example, the term “parallel” can be replaced with the term “approximately parallel,” “substantially parallel,” “practically parallel,” or the like as appropriate. In addition, the term “parallel”, “approximately parallel,” “substantially parallel,” or “practically parallel,” may be applied to the case where the angle between two straight lines or planes is greater than or equal to −5° and less than or equal to 5°. Alternatively, these terms may be applied to the case where the angle between two straight lines or planes is greater than or equal to −10° and less than or equal to 10°. Alternatively, these terms may be applied to the case where the angle between two straight lines or planes is greater than or equal to −30° and less than or equal to 30°. Accordingly, the term “parallel” sometimes means a state being “parallel or substantially parallel,” for example. Moreover, the term “perpendicular” does not necessarily mean a state being exactly perpendicular. Hence, for example, the term “perpendicular” can be replaced with the term “approximately perpendicular,” “substantially perpendicular,” “practically perpendicular,” or the like as appropriate. The term “perpendicular”, “approximately perpendicular,” “substantially perpendicular,” or “practically perpendicular,” may be applied to the case where the angle between two straight lines or planes is greater than or equal to 85° and less than or equal to 95°. Alternatively, these terms may be applied to the case where the angle between two straight lines or planes is greater than or equal to 80° and less than or equal to 100°. Alternatively, these terms may be applied to the case where the angle between two straight lines or planes is greater than or equal to 60° and less than or equal to 120°. Accordingly, the term “perpendicular” sometimes means a state being “perpendicular or substantially perpendicular,” for example.

Note that in this specification and the like, the expression “level with” indicates having the same level from a reference surface (e.g., a flat surface such as a substrate surface) in a cross-sectional view. For example, in a manufacturing process of the semiconductor device, planarization treatment is performed, whereby the surface(s) of a single layer or a plurality of layers are exposed in some cases. In this case, the surfaces on which the planarization treatment has been performed are at the same level as a reference surface. Note that a plurality of layers having the surfaces on which the planarization treatment has been performed are not level with each other in the strict sense in some cases, depending on a treatment apparatus, a treatment method, or a material of the treated surfaces on which the planarization treatment is performed. This case is also regarded as being “level with” in this specification and the like. For example, the expression “level” also includes the case where two layers (here, given as a first layer and a second layer) whose levels with respect to the reference surface are different from each other are provided to have a difference between the top-surface level of the first layer and the top-surface level of the second layer of less than or equal to 20 nm. Accordingly, “level with” sometimes means “level with or substantially level with”, for example.

Note that in this specification and the like, the expression “end portions are aligned” means that at least outlines of stacked layers partly overlap with each other in a top view. For example, the case of processing the upper layer and the lower layer with use of the same mask pattern or mask patterns that are partly the same in a manufacturing process of a semiconductor device is included. However, in some cases, the outlines do not exactly overlap with each other and the outline of the upper layer is positioned inward from the outline of the lower layer or the outline of the upper layer is positioned outward from the outline of the lower layer. This case is also described with the expression “end portions are aligned” in this specification and the like. Accordingly, “end portion are aligned” sometimes means “an end portion is aligned or substantially aligned with each other”, for example.

Note that in this specification and the like, for example, the terms “identical”, “the same”, “equal”, “concurrent”, “aligned”, “uniform”, and the like (including synonyms of these words) used in describing calculation values and measurement values or in describing objects, methods, events, and the like that can be converted into calculation values or measurement values, allow for a margin of error of ±20% unless otherwise specified. Therefore, for example, “identical” means “identical” or “substantially identical”, “the same” means “the same or substantially the same”, “equal” means “equal or substantially equal”, “concurrent” means “concurrent or substantially concurrent”, “aligned” means “aligned or substantially aligned”, and “uniform” means “uniform or substantially uniform” in some cases.

In this specification and the like, an impurity in a semiconductor refers to a component other than a main component of a semiconductor, for example. For example, an element with a concentration of lower than 0.1 atomic % is an impurity. When an impurity is included in a semiconductor, for example, the density of defect states in a semiconductor is increased, carrier mobility is decreased, or crystallinity is decreased in some cases. In the case where the semiconductor is an oxide semiconductor, examples of an impurity that changes the characteristics of the semiconductor include Group 1 elements, Group 2 elements, Group 13 elements, Group 14 elements, Group 15 elements, or transition metals other than the main components of the oxide semiconductor. Specific examples include hydrogen (included also in water), lithium, sodium, silicon, boron, phosphorus, carbon, and nitrogen. In addition, oxygen vacancies are formed in an oxide semiconductor in some cases by entry of impurities, for example.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like, for example. For example, in the case where a metal oxide is used in a semiconductor including a channel formation region of a transistor, the metal oxide is referred to as an oxide semiconductor in some cases. That is, when a metal oxide is used as a material that can be used for a channel formation region of a transistor that has at least one of an amplifying function, a rectifying function, and a switching function, the metal oxide can be referred to as a metal oxide semiconductor. In addition, the term “OS transistor” can also be referred to as a transistor including a metal oxide or an oxide semiconductor.

In this specification and the like, a metal oxide including nitrogen is also collectively referred to as a metal oxide in some cases. A metal oxide including nitrogen may be referred to as a metal oxynitride.

In the drawings and the like in this specification, arrows indicating the X direction, the Y direction, and the Z direction are illustrated in some cases. In this specification and the like, the “X direction” is a direction along the X-axis, and the forward direction and the reverse direction are not distinguished in some cases, unless otherwise specified. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

### REFERENCE NUMERALS

100: semiconductor device, 101: memory cell, 102: primary sensing circuit, 103: secondary sensing circuit, 104: input/output circuit, 105: memory circuit, 110: semiconductor device, 111: memory cell, 111B: memory cell, 112: primary sensing circuit, 112B: primary sensing circuit, 113: secondary sensing circuit, 114: input/output circuit, 115: memory circuit, 131: amplifier circuit, 132: precharge circuit, 133: precharge circuit, 134: switch circuit, M111: transistor, M121: transistor, M122: transistor, M123: transistor, M124: transistor, M131a: transistor, M131b: transistor, M131c: transistor, M131d: transistor, M132a: transistor, M132b: transistor, M132c: transistor, M133a: transistor, M133b: transistor, M133c: transistor, M134a: transistor, M134b: transistor, M141: transistor, C111: capacitor, X141: AND circuit, X142: XOR circuit, X143: XOR circuit, X151: D-FF circuit, X152: NOT circuit, MN: wiring, WL: wiring, WLB: wiring, CL: wiring, LBL: wiring, LBLB: wiring, LWE: wiring, LRE: wiring, LMX: wiring, SL: wiring, GBL: wiring, GBLB: wiring, SAP: wiring, SAN: wiring, VPRE: wiring, EQ: wiring, EQB: wiring, CSEL: wiring, DBL: wiring, DBLB: wiring, FLG: wiring, WL_EN: wiring, DRE: wiring, DWE: wiring, RDL: wiring, WDL: wiring, 116: data sensing circuit, 161: amplifier circuit, 162: precharge circuit, M161a: transistor, M161b: transistor, M161c: transistor, M161d: transistor, M161e: transistor, M162a: transistor, M162b: transistor, M162c: transistor, DSAP: wiring, DSAN: wiring, VPRE2: wiring, DSA_EN: wiring, DEQB: wiring, 100A: semiconductor device, 101A: memory cell, 102A: primary sensing circuit, 103A: secondary sensing circuit, 105A: memory circuit, 110A: semiconductor device, 115A: memory circuit, M111A: transistor, M121A: transistor, M122A: transistor, C111A: capacitor, MNA: wiring, LBLA: wiring, GBLA: wiring, X134: AND circuit, 700: memory device, 711: memory block, 712: memory unit, 721: memory array, 722: driver circuit, 723: memory subarray, 724: word line driver, 725: column driver, 726: sense amplifier driver, 727: data driver, 728: memory controller, 731: primary sensing circuit, 741: memory cell, 751: secondary sensing circuit, 761: power switch, 762: power switch, 771: peripheral circuit, 772: control circuit, 773: voltage generation circuit, 781: peripheral circuit, 782: row decoder, 783: row driver, 784: column decoder, 785: column driver, 786: data driver, 787: input circuit, 788: output circuit, 792: layer, 793: layer, 794: layer, 795: layer, BW: terminal, CE: terminal, GW: terminal, MCK: terminal, WAKE: terminal, ADDR: terminal, RDA: terminal, WDA: terminal, PON1: terminal, PON2: terminal, VMD: terminal, VMS: terminal, VMH: terminal

1. A semiconductor device comprising:
a memory cell, a first sensing circuit, a second sensing circuit, an input/output circuit, and a memory circuit,
wherein the memory cell comprises a first transistor and a first capacitor,
wherein the first sensing circuit comprises a second transistor and a third transistor,
wherein a gate of the first transistor is electrically connected to a word line,
wherein one of a source and a drain of the first transistor is electrically connected to one terminal of the first capacitor,
wherein the other of the source and the drain of the first transistor is electrically connected to a gate of the second transistor and one of a source and a drain of the third transistor,
wherein one of a source and a drain of the second transistor and the other of the source and the drain of the third transistor are electrically connected to the second sensing circuit through a bit line,
wherein the second sensing circuit is configured to output first data corresponding to a potential of the bit line,
wherein the memory circuit is configured to retain second data corresponding to the number of times the memory cell is accessed, and
wherein the input/output circuit is configured to, in accordance with the second data, determine whether to invert or not to invert the first data and output the first data.

2. The semiconductor device according to claim 1,
wherein the memory circuit is configured to invert the second data every time the memory cell is accessed, and
wherein the input/output circuit is configured to output an exclusive disjunction of the first data and the second data.

3. The semiconductor device according to claim 1,
wherein the second sensing circuit comprises a fourth transistor,
wherein the input/output circuit comprises a fifth transistor,
wherein the memory circuit comprises a sixth transistor,
wherein each of the first transistor to the third transistor comprises an oxide semiconductor in a channel formation region, and
wherein each of the fourth transistor to the sixth transistor comprises silicon in a channel formation region.

4. The semiconductor device according to claim 1,
wherein the memory cell is positioned over the first sensing circuit, and
wherein the first sensing circuit is positioned over the second sensing circuit.

5. A semiconductor device comprising:
a first memory cell, a second memory cell, a first sensing circuit, a second sensing circuit, a third sensing circuit, a fourth sensing circuit, and an input/output circuit,
wherein the first memory cell comprises a first transistor and a first capacitor,
wherein the second memory cell comprises a seventh transistor and a second capacitor,
wherein the first sensing circuit comprises a second transistor and a third transistor,
wherein the third sensing circuit comprises an eighth transistor and a ninth transistor,
wherein a gate of the first transistor and a gate of the seventh transistor are electrically connected to a word line,
wherein one of a source and a drain of the first transistor is electrically connected to one terminal of the first capacitor,
wherein the other of the source and the drain of the first transistor is electrically connected to a gate of the second transistor and one of a source and a drain of the third transistor,
wherein one of a source and a drain of the second transistor and the other of the source and the drain of the third transistor are electrically connected to the second sensing circuit through a first bit line,
wherein one of a source and a drain of the seventh transistor is electrically connected to one terminal of the second capacitor,
wherein the other of the source and the drain of the seventh transistor is electrically connected to a gate of the eighth transistor and one of a source and a drain of the ninth transistor,
wherein one of a source and a drain of the eighth transistor and the other of the source and the drain of the ninth transistor are electrically connected to the fourth sensing circuit through a second bit line,
wherein the second sensing circuit u is configured to output first data corresponding to a potential of the first bit line,
wherein the fourth sensing circuit is configured to output second data corresponding to a potential of the second bit line, and
wherein the input/output circuit is configured to, in accordance with the second data, determine whether to invert or not to invert the first data and output the first data.

6. The semiconductor device according to claim 5,
wherein the input/output circuit is configured to output an exclusive disjunction of the first data and the second data.

7. The semiconductor device according to claim 5,
wherein the second sensing circuit comprises a fourth transistor,
wherein the input/output circuit comprises a fifth transistor,
wherein the fourth sensing circuit comprises a tenth transistor,
wherein the first transistor to the third transistor and the seventh transistor to the ninth transistor each comprise an oxide semiconductor in a channel formation region, and
wherein each of the fourth transistor, the fifth transistor, and the tenth transistor comprises silicon in a channel formation region.

8. The semiconductor device according to claim 5,
wherein the first memory cell is positioned over the first sensing circuit,
wherein the first sensing circuit is positioned over the second sensing circuit,
wherein the second memory cell is positioned over the third sensing circuit, and
wherein the third sensing circuit is positioned over the fourth sensing circuit.

9. A semiconductor device comprising:
a memory cell and a memory circuit,
wherein the memory circuit is configured to retain data corresponding to the number of times the memory cell is accessed.
